(19) United States
(12) Patent Application Publication
(10) Pub. No.: US 2026/0330159 A1
(43) Pub. Date: Oct. 22, 2026

(54) Thermodynamic Computing System for Sampling High-Dimensional Probability Distributions

(71) Applicant: Normal Computing Corporation, Chicago, IL (US)

(72) Inventors: Patrick Coles, Rio Rancho, NM (US); Collin Szczepanski, Princeton, NJ (US); Kaelan Donatella, Paris (FR); Denis Melanson, Hamilton (CA); Max Hunter Gordon, London (GB); Faris Sbahi, New York, NY (US); Antonio Martinez, Chicago, IL (US); Maxwell Aifer, New York, NY (US); Mohammad Abu Khater, Savoy, IL (US)

(73) Assignee: Normal Computing Corporation, Chicago, IL (US)

(21) Appl. No.: 19/120,566

(22) PCT Filed: Oct. 13, 2023
(86) PCT No.: PCT/US2023/076759

§ 371 Date: Apr. 11, 2025

Related U.S. Application Data
(60) Provisional application No. 63/379,561, filed on Oct. 14, 2022.
(60) Provisional application No. 63/492,832, filed on Mar. 29, 2023.
(60) Provisional application No. 63/518,545, filed on Aug. 9, 2023.

(51) Int. Cl. G06G 7/12

(52) U.S. Cl. CPC G06G 7/12

(57) ABSTRACT

A thermodynamic computing platform uses an network of coupled analog unit cells controlled by a digital processor to sample multivariate distribution, such as a multivariate Gaussian distribution. The analog unit cells are capacitively, resistively, and/or inductively coupled to each other. Each analog unit cell includes a tunable resistor, capacitor, inductor, current source, and/or voltage source. The digital processor sets the initial values of these components. These values, or input parameters, represent the multivariate distribution. Then the network of coupled analog unit cells evolves until over a series of time steps it reaches thermal equilibrium. While the network evolves, the digital processor samples voltages at nodes in the network at each time step. These voltages represent samples of the multivariate distribution.

### CROSS-REFERENCE TO RELATED APPLICATIONS

This application is a U.S. national-stage application, under 35 U.S.C. 371, of International Application No. PCT/US2023/076759, filed Oct. 13, 2023, which in turn claims the priority benefit, under 35 U.S.C. 119 (e), of U.S. Application No. 63/518,545, filed Aug. 9, 2023; U.S. Application No. 63/492,832, filed Mar. 29, 2023; and U.S. Application No. 63/379,561, filed Oct. 14, 2022. Each of these applications is incorporated herein by reference in its entirety for all purposes.

### BACKGROUND

Conventional artificial intelligence (AI) and machine learning (ML) work best when uncertainty is irrelevant. But in practice, uncertainty is often prevalent. Noisy data adds uncertainty in AI and ML predictions, causing these predictions to become untrustworthy. This impairs an AI's ability to determine when it should defer to human input. This is particularly salient in the context of high-stakes applications for AI, such as criminal justice, healthcare, energy, finance, national defense, manufacturing, robotics, and beyond. For example, consider an assistive model tasked with diagnosing melanomas. Ideally, such a model should defer to a medical practitioner when uncertain. Similarly, an AI in an autonomous vehicle should pass control to a human driver if it is unsure whether a pedestrian is on the road. But if uncertainty degrades an AI's ability to make predictions, then the AI may not defer effectively to human judgment.

Uncertainties can be bucketed into two principal categories. First, there is ambiguity that commonly results from noisy data or missing features (“aleatoric ambiguity”). Aleatoric ambiguity persists independent of exposing an AI or ML system to more data. For example, the perception system of an autonomous vehicle includes noisy sensors and imaging. Second, there is uncertainty due to finite training data (“epistemic uncertainty”). A model input may look different from, or only have few supporting examples within, the training data. Epistemic uncertainty goes down as the model is trained on more data.

Conventional AI addresses uncertainty by assigning a confidence level to its decisions (e.g., 90% confidence that an image shows a particular person or object). By assigning confidence to a decision, the AI quantifies uncertainty associated with the decision. Unfortunately, conventional AI and ML generally lack a meaningful form of assigning correctly quantified uncertainty.

FIG. 1 illustrates how uncertainty affects a mainstream deep neural network's ability to assign a meaningful confidence level to its predictions under real-world conditions. It shows idealized and real plots of uncertainty (confidence) in the deep neural network's predictions, with darker shading indicating higher confidence. The deep neural network was trained on the training data (dots) distributed along the semicircles shown in both plots in FIG. 1. The trained deep neural network was then presented with the “out-of-distribution” input data (dots) clustered from x≈0 to x≈1.5 at y≈1.5 in both plots. Ideally, the deep neural network should recognize that its predictions about the input data are highly uncertain/low confidence (light shading), as shown in the left plot. In reality, however, the deep neural network assigns high confidence (dark shading) to its prediction as shown in the right plot even though the input data is far from the training data. Unfortunately, common AI and ML models tend to be especially overconfident in their predictions when operating on unfamiliar input data.

Fortunately, probabilistic AI and ML can quantify and account for uncertainty in predictions. Probabilistic AI and ML combine AI and ML with probabilistic reasoning, which is the mathematical process of determining uncertainties as a function of prior beliefs, biases, and data. For any level of stakes, probabilistic reasoning should be optimal so long as there exists uncertainty. Probabilistic AI and probabilistic reasoning naturally involve continuous distributions, such as Gaussian distributions, to reflect one's state of knowledge. Unfortunately, performing probabilistic reasoning with these continuous distributions scales poorly in computational difficulty as a function of model complexity, when using standard digital computers.

### SUMMARY

Nature performs probabilistic reasoning through the physical principle of thermodynamic equilibration. Probabilistic AI models are trained and inferred via probabilistic reasoning, usually working in terms of continuous random variables. A thermodynamic computing platform can exploit thermodynamic equilibration to perform probabilistic reasoning for probabilistic artificial intelligence and machine learning. Thermodynamic equilibration of a system describes dynamics which evolve a physical system until the system can be described by a steady probability distribution over possible states; the inventive technology uses such thermodynamic equilibration for computation with dynamics engineered so that the final probability distribution over states matches the target probability distribution that is being computed. Moreover, utilizing physical systems that are continuous in nature naturally matches the mathematical framework of continuous distributions used in probabilistic reasoning.

The inventive technology can be implemented as a thermodynamic system for sampling a multivariate distribution, such as a multivariate Gaussian probability distribution. This system may include a network of coupled harmonic oscillators that is operably coupled to a digital controller. The network of coupled harmonic oscillators is characterized by a Hamiltonian that maps to the multivariate distribution. Each coupled harmonic oscillator in the network of coupled harmonic oscillators includes a digitally tunable inductor, a digitally tunable capacitor, a digitally tunable voltage source, and a digitally 10 tunable current source. The digital controller initializes the digitally tunable inductors, the digitally tunable capacitors, the digitally tunable voltage sources, and the digitally tunable current sources. It iteratively reads voltages and currents at nodes in the network of coupled harmonic oscillators and updates the digitally tunable voltage sources and the digitally tunable current sources based on the voltages and currents. These voltages and currents correspond to positions and momenta of the Hamiltonian. The digital controller also translates the voltages and the currents into samples of the multivariate distribution.

The network of coupled harmonic oscillators may include one harmonic oscillator for each dimension of the multivariate distribution. The harmonic oscillators can be capacitively, inductively, and/or resistively coupled to each other.

Another implementation of the inventive technology is a thermodynamic system for sampling a target probability distribution. This thermodynamic system includes both an analog dynamical system and a digital controller. The analog dynamical system is configured to evolve via Hamilton's equations over a series of time steps to provide samples of the target probability distribution. The digital controller is operably coupled to the analog dynamical system and is configured, at each of the time steps, to receive a proposed sample of the target probability distribution and to accept or reject the proposed sample.

Yet another implementation of the inventive technology is a thermodynamic system for sampling a multivariate distribution, such as a multivariate Gaussian probability distribution. This system may include a network of analog electrical circuits (e.g., coupled harmonic oscillators) that is operably coupled to a digital controller. Each of the analog electrical circuits includes at least one tunable passive electrical component (e.g., a digitally tunable inductor, digitally tunable capacitor, and/or digitally tunable resistor). In operation, the digital controller tunes the tunable passive electrical components according to the multivariate distribution and samples voltages at points within the network of analog electrical circuits.

Such a thermodynamic system may also include a voltage-controlled voltage source, operably coupled to the network of analog electrical circuits, to modify the multivariate distribution. The voltage-controlled voltage source can employ an artificial neural network to relate an input voltage to the voltage-controlled voltage source to an output voltage of the voltage-controlled voltage source. In this case, the input voltage can be based on the voltages sampled by the digital controller and the voltage-controlled voltage source can be configured to apply the output voltage to the network of analog electrical circuits so as to change a distribution of potential energy across the network of analog electrical circuits.

The the multivariate distribution can have a nonzero cumulant of at least third order, in which case the system includes a multi-port device, operably coupled to at least three of the analog electrical circuits in the network of analog electrical circuits. This multi-port device can generate a k-body term in a potential energy distribution over the network of analog electrical circuits, where k is an integer greater than or equal to 3. For example, the multi-port device can include a transistor, a voltage-controlled capacitor, or both.

Each analog electrical circuit in the thermodynamic system can also include a stochastic noise source, such as a thermal noise source, a shot noise source, or a digital pseudorandom noise source. And the analog electrical circuits in the network of analog electrical circuits can be coupled to each other via capacitive and/or resistive coupling.

The thermodynamic system can generate samples from the multivariate distribution via a Langevin Monte Carlo algorithm and/or a Metropolis Adjusted Langevin Algorithm.

The multivariate distribution's covariance matrix can be encoded in at least some of the parameters of the network of analog electrical circuits.

Still another inventive system for sampling a multivariate distribution (e.g., a multivariate Gaussian distribution or distribution with a non-zero cumulant higher than second order) includes a network of coupled analog unit cells operably coupled to a digital controller. The network of coupled analog unit cells is characterized by a total energy function that maps to the multivariate distribution. Each of the coupled analog unit cells includes a digitally tunable capacitor and either a digitally tunable voltage source, a digitally tunable current source, or both a digitally tunable voltage source and a digitally tunable current source. In operation, the digital controller initializes the digitally tunable capacitors, voltage sources, and/or current sources. The digital controller iteratively reads voltages and currents at nodes in the network of coupled analog unit cells and updates the digitally tunable voltage sources and/or the digitally tunable current sources. The voltages and the currents correspond to positions and momenta of the total energy function, and the digital controller translates the voltages and the currents into samples of the multivariate distribution.

The total energy function can be a Hamiltonian in which case the network of coupled analog unit cells have dynamics used to run a Hamiltonian Monte Carlo protocol. Alternatively, the network of coupled analog unit cells can have dynamics used to run a Langevin Monte Carlo protocol.

The network of coupled analog unit cells can include one analog unit cell for each dimension of the multivariate distribution. Each of the analog unit cells may also include a digitally tunable inductor. The analog unit cells can be coupled to each other capacitively, resistively, and/or inductively.

Yet another inventive system for sampling a multivariate distribution includes a gradient calculator (e.g., an analog neural network or a network of resistive circuit elements), a momentum integrator device operably coupled to the gradient calculator, and a position integrator device operably coupled to the momentum integrator device.

Still another inventive thermodynamic system for sampling a target probability distribution includes an analog dynamical system operably coupled to a digital controller. The analog dynamical system is configured to evolve via a Langevin equation and/or Hamilton's equations of motion. And the digital controller is configured, at each of time step of the Langevin equation and/or Hamilton's equations of motion, to receive a proposed sample of the target probability distribution from the analog dynamical system and to accept or reject the proposed sample.

Inventive methods include a method of inverting a matrix. This method involves uploading elements of the matrix to respective values of tunable circuit elements of a network of analog unit cells, allowing the network of analog unit cells to come to thermal equilibrium, and computing a covariance matrix based on dynamical variables of the network of analog unit cells. This covariance matrix is an inverse of the matrix. Computing the covariance matrix may include drawing samples from a thermal equilibrium distribution of the dynamical variables of the network of analog unit cells and computing the covariance matrix of the samples. Computing the covariance matrix can also include integrating the dynamical variables over time with a plurality of analog integrators.

Other inventive methods include a method of solving a system of linear equations represented by a matrix and a vector. This the method involves uploading elements of a matrix to respective values of tunable circuit elements of a network of analog unit cells, uploading elements of a vector to respective current sources or voltage sources in the analog unit cells, allowing the network of analog unit cells to come to thermal equilibrium, and computing mean values of dynamical variables of the network of analog unit cells. The mean values representing a solution to the system of linear equations. Computing the mean values can include integrating the dynamical variables over time with a plurality of analog integrators.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar components).

FIG. 1 shows plots of uncertainty for deep neural networks in the idealized and real cases.

FIG. 2 shows an overview of the thermodynamic computing system. A digital controller draws samples from a temporally evolving analog system, also called an analog dynamical system, to perform the Hamiltonian Monte Carlo (HMC) method of sampling a target probability distribution.

FIG. 3 is a circuit diagram for a basic LC oscillator that maps to a one-dimensional normal (i.e., Gaussian) probability distribution.

FIG. 4 is a circuit diagram for a pair of capacitively coupled oscillators in a network of capacitively coupled harmonic oscillators that maps to a multivariate normal probability distribution.

FIG. 5 shows a a U-Turn that appears while running HMC on a 2D Gaussian.

FIG. 6 shows a system level view of the UL hardware implementation. The PC downloads the setup information to the on-board controller, and consequently reads the sampled data from the cells.

FIG. 7 depicts two coupled LC resonators that form a simple two-cell system. The resonant frequency of each resonator can be independently tuned, and the capacitive coupling can be controlled. The cells are excited with a Gaussian noise current source.

FIG. 8 shows generic all-to-all coupling in a UL hardware setup.

FIG. 9a shows a tunable cell where the resonant frequency can be digitally controlled with a current noise source implemented using a digital controller followed by a LPF.

FIG. 9b shows a tunable cell with an initial condition implemented by adding an extra switch separating the inductor from the capacitors.

FIG. 10 shows the capacitor can be initialized while disconnected instead of initializing the capacitor and inductor in each cell. At a given time after connecting it with the inductor, the sought initial condition is achieved. This way, one component is initialized.

FIG. 11 shows a coupling unit between two cells. The cells are connected at nodes A and B. The coupling can be enabled or disabled, and the polarity is also dictated, using control signals.

FIG. 12 illustrates an FPGA implementation of the controller: (a) The high level control, where the download and upload operation occur, in addition to setting up each cell and a coupling unit within the FPGA. (b) The cell interface reads the voltages from the ADC, and subsequently stores that data. It also controls the switches of the tunable resonator and controls the noise amplitude. (c) The coupling unit interface turns the proper switches to control the coupling and its polarity. (d) The format of the downloaded data to the FPGA.

FIG. 13A shows the current noise source in FIG. 7 can be implemented with a since-bit PN generator with a series resistance to emulate a current source. The RC circuit also acts as a LPF.

FIG. 13B shows an example of a linear feedback shift register (LFSR) used for a single-bit pseudonoise (PN) generator.

FIG. 14 is a visualization of the overall process. Shaded boxes are procedures which happen on the digital device, while white boxes are procedures that happen on the analog device.

FIG. 15 illustrates coupling between HMC unit cells via a mutual inductance.

FIG. 16 illustrates direct inductive coupling between HMC unit cells.

FIG. 17A shows a circuit diagram of a possible physical realization of a single unit cell, consisting of a noisy resistor and a capacitor illustrates direct inductive coupling between HMC unit cells.

FIG. 17B shows a circuit diagram of a possible means to couple two unit cells, using a coupling resistor.

FIG. 18 shows an example of a switching capacitor bank controlled by digital logic, where each physical capacitor adds an additional bit of precision for the overall capacitance.

FIG. 19 illustrates two varicaps in opposite directions in a back-to-back configuration. A third port in the middle acts as a tuning voltage to tune the capacitance of the system.

FIG. 20 is a circuit diagram of the digital-analog scheme for implementing bi-polar coupling.

FIG. 21 shows an active inductor based on a gyrator (top) and an equivalent circuit with an inductor (bottom).

FIG. 22 shows a circuit diagram of a basic symmetric RC unit-cell used for over damped Langevin sampling of one-dimensional normal (i.e. Gaussian) probability distribution.

FIG. 23 shows a circuit diagram of the basic coupling-cell used to achieve negative coupling between two RC unit-cells, without inductors.

FIG. 24 shows a circuit diagram of the basic coupling-cell used to achieve positive coupling between two RC unit-cells, without inductors.

FIG. 25 illustrates different strategies for achieving local connectivity, including a square lattice, hexagonal lattice, and King's graph, with boxes representing unit cells.

FIG. 26 illustrates additional strategies for achieving local connectivity based on cluster graphs, including square clusters and hexagonal clusters, with boxes representing unit cells.

FIG. 27 illustrates a semi-local approach to connecting unit cells (represented by boxes). Here, unit cells within a row are fully connected, while the connections between rows are more sparse. For D=9, the number of nearest neighbors is n=3 or n=4 depending on the row. For D=16, we have either n=4 or n=5 depending on the row. In general, n scales as \sqrt{D} with this connectivity scheme.

FIG. 28 shows a circuit schematic of a possible fully-connected architecture.

FIG. 29 is a plot of the success rate of the accept/reject step with increasing number of bits of precision in the switching capacitor bank capacitors (error bars represents standard deviation error). Results of simulating the process and hardware with fully-connected capacitance matrix of dimension 8.

FIG. 30 is a plot of the success rate of the accept/reject step with increasing capacitor imperfections (shaded region represents standard deviation error). Results of simulating the process and hardware with fully-connected capacitance matrix of dimension 200. Capacitors have many levels of tolerances, but one can select capacitors with a tolerance of, say 2.5%, which leads a success rate of approximately 80% according to the plot.

FIG. 31 shows plots illustrating the effect of hardware with limited k-banded connectivity on the acceptance rate of the accept/reject step (error bars represent the standard deviation). Results from simulating the process and hardware with k-banded capacitance matrix of increasing dimension. When (A) the target distribution has a sparse covariance matrix with elements decaying with distance from the diagonal, and (B) the target distribution covariance matrix is arbitrarily dense.

FIG. 32 is a plot of a target distribution ƒₜ whose variance is

$${σ}_{t}^{2} = 1.5 ε$$

is approximated by the interpolation between two distributions ƒ₁ and ƒ₂ whose variances are respectively ε and 2ε. While ƒₜ, ƒ₁, and ƒ₂ are Gaussian, ƒₐ is a Gaussian mixture.

FIG. 33 is a plot showing the L₁ distance between the approximating probability density function ƒₐ and the target ƒₜ as a function of ε. The target distribution is a univariate normal distribution with mean zero and variance 20. With error mitigation (green) the first derivative of the error goes to zero as ε goes to zero, but without error mitigation (blue) the first derivative does not vanish as ε goes to zero.

FIG. 34 illustrates Maxwell's demon, which is a concept in thermodynamics whereby an intelligent observer can reduce the entropy of a system by watching the system and appropriately applying forces to the system. The classic example is separating a gaseous mixture, as shown here.

FIG. 35 shows how the potential energy landscape U(x) can be altered by adding a Maxwell's demon. The bottom panel shows schematically how this alters the probability distribution P(x) that one draws samples from. The left panel shows a harmonic oscillator potential corresponding to sampling a Gaussian probability distribution. The right panel shows that adding in a Maxwell's demon system leads to a more complicated potential, allowing one to sample other distributions such as multi-modal distributions.

FIG. 36 illustrates how the Maxwell's demon device can be viewed as a voltage-controlled voltage source.

FIG. 37 illustrates how a digital Maxwell's demon system (e.g., processed on a CPU or on a Field Programmable Gate Array (FPGA)) could interact with the analog HMC hardware.

FIG. 38 illustrates a non-correlating approach to constructing an analog Maxwell's demon. The primary unit cell (on the left) is coupled to an auxiliary unit cell (on the right). Specifically, the voltage across the capacitor in the primary unit cell is applied as a voltage source in the auxiliary unit cell. This voltage source drives current through a non-linear element (NLE), and the current is read off via the voltage across a resistor. The latter voltage difference is passed through an inverter, after which it acts as a voltage source in the primary unit cell, corresponding to the output of the Maxwell's demon.

FIG. 39 shows an alternative construction for the analog Maxwell's demon without a voltage inverter. Namely, by allowing the resistor in the auxiliary unit cell to be ungrounded on both terminals, then one can pick off its voltage difference and invert the wires before applying it as a voltage source in the primary unit cell

FIG. 40 illustrates the characteristics of a diode-based Maxwell's demon. Here we assume that the NLE is a diode under forward bias. The first panel shows the current-voltage characteristic of the diode, denoted I(x). The second panel shows the force ƒ(x) outputted by the Maxwell's demon, which we assume applies a negative sign to the I(x) curve. The third and fourth panels respectively are the potential energy U(x) and the probability distribution P(x) being sampled.

FIG. 41 illustrates the characteristics of a Maxwell's demon based on a tunnel diode. Here we assume that the NLE is a tunnel diode under forward bias. The first panel shows the current-voltage characteristic of the tunnel diode, denoted I(x). The second panel shows the force ƒ(x) outputted by the Maxwell's demon, which we assume applies a negative sign to the I(x) curve and then shifts the voltage by a constant, negative amount (as discussed in the text). The third and fourth panels respectively are the potential energy U(x) and the probability distribution P(x) being sampled.

FIG. 42 illustrates an analog Maxwell's demon for generating correlations amongst the unit cells. An analog coupling operation, which could, for example, be an affine transformation, is applied to the vector of voltages associated with the capacitors of each unit cell. After the analog coupling operation, the resulting vector is applied component-wise as a voltage source in each auxiliary unit cell, which contains a non-linear element (NLE). The current through each NLE is read off as a voltage, which is then inverted in sign and finally applied as a voltage source in the corresponding primary unit cell.

FIG. 43 shows an analog circuit for implementing the matrix-vector multiplication Av. This provides a possible implementation for the analog coupling operation shown in FIG. 42. Here, there are d resistors associated with each row of the matrix A. This gives a total of d² resistors for the entire matrix A, assuming A is dense.

FIG. 44 shows an analog circuit for implementing the function h(v) using transistors. Here we show the i^{th} component of the circuit for implementing hᵢ(v), as a representative example for other components. Here, there are d transistors associated with hᵢ, giving a total of d² transistors for the entire transformation h(v). Each component vⱼ of v acts as the gate voltage for the transistor associated with some other component uₖ, leading to a higher-order coupling. (For simplicity, only 3 components of v are shown, even though there are d components.)

FIG. 45 illustrates a device that performs analog HMC when the probability distribution a user wishes to sample from is represented by a neural network.

FIG. 46 shows a device that performs analog HMC for Gaussian distributions, where one specifies a precision matrix Q=Σ⁻¹ instead of the covariance matrix Σ.

FIG. 47 shows three unit cells coupled via the three ports of a voltage-controlled capacitor.

FIG. 48 shows four unit cells, coupled via a voltage multiplier (i.e., voltage mixer) and a voltage-controlled capacitor. The voltage multiplier can either be implemented on a digital device or with an analog device.

FIG. 49 illustrates a scheme for achieving local connectivity with 3-body coupling via voltage-controlled capacitors and a square lattice.

FIG. 50 illustrates a scheme for achieving local connectivity with 3-body coupling via voltage-controlled capacitors (VCCs) and a hexagonal lattice.

FIG. 51 shows an LMC Hardware unit cell with a capacitor, an ideal resistor, and a stochastic voltage source.

FIG. 52 shows two unit cells of LMC hardware coupled with either (A) a resistive bridge or (B) a capacitive bridge.

FIG. 53 shows two coupled unit cells of LMC hardware for Gaussian sampling. The covariance matrix of the Gaussian is encoded into the values of the circuit elements, particularly the resistances of the resistors.

FIG. 54 shows an alternative analog device based on integrators for implementing LMC. The user interfaces through compilation of the gradient of the log-probability as well as through sample collection.

FIG. 55 illustrates a possible circuit diagram for two coupled unit cells, which would form the building block of the hardware. In each unit cell, current noise is injected in parallel with the LC oscillator circuit.

FIG. 56 is a schematic diagram of our Thermodynamic process for solving linear systems of equations.

### DETAILED DESCRIPTION

### 1 System Overview

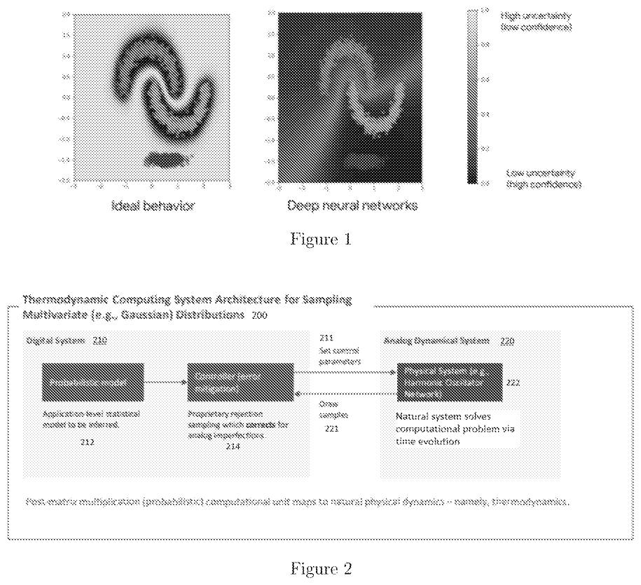

FIG. 2 shows a thermodynamic computing system 200, also called a thermodynamic computing platform, thermodynamic system, or thermodynamic platform, that can sample multivariate Gaussian distributions using the Hamiltonian Monte Carlo (HMC) method, which is a state-of-the-art Markov chain Monte Carlo (MCMC) method. The HMC sampling method is a Markov chain Monte Carlo (MCMC) method, which samples from the Gibbs distribution. The HMC sampling method reduces the problem of sampling from the Gibbs distribution of f to simulating the trajectory of a particle according to the laws of Hamiltonian dynamics where f plays the role of a potential energy function. The samples produced by the thermodynamic computing system can be used in probabilistic AI, for example, to weight connections between neurons in different layers of a probabilistic neural network.

The thermodynamic computing system 200 in FIG. 2 is a hybrid digital-analog system that includes a digital system 210 that interfaces with an analog system 220, also called an analog dynamical system or temporally evolving analog system. The digital system 210 can be implemented in appropriately programmed digital hardware (e.g., a processor, application-specific integrated circuit, field-programmable gate array, etc.) and executes both a probabilistic model 212, which is an application-level statistical model being inferred by the thermodynamic system, and a controller 214 for interfacing with the analog system. The controller can be implemented in firmware. In operation, the controller 214 initializes control parameters 211 of the analog dynamical system 220 and accepts and rejects samples 221 of the target multivariate distribution from the analog system 220. In addition, the digital system 210 interfaces with the user directly or via another digital computing device (e.g., a personal computer (PC)).

The analog system 220 includes a dynamical physical system 222 that evolves via Hamilton's equations over a series of time steps to provide samples of a target multivariate distribution, such as a multivariate Gaussian distribution, Bernoulli distribution, binomial distribution, Poisson distribution, or other exponential distribution. More generally, the analog system 220 can sample any distribution that can be defined in terms of an energy function that can be realized in (analog) electronics. The target multivariate distribution can be a high dimensional distribution (e.g., a distribution with 10, 100, 1000, 10000, or more dimensions) that represents probability, heat, population, or any other suitable quantity.

At each time step in the series of time steps, the analog system 220 proposes a sample 221 of the target probability distribution to the controller 214, which accepts the proposed sample or rejects it if it is an outlier. The natural time evolution of the analog system 220 maps to Hamiltonian dynamics, meaning that the analog system naturally implements the integration step of the HMC sampling method. In other words, the natural physical dynamics of the analog system replace the numerical integration traditionally performed on digital hardware. As a result, the joint digital-analog thermodynamic system solves these computations via time evolution.

The controller 214 in the digital system 210 sets the analog system's input parameters 211, which represent the multivariate distribution, for example, a normal (Gaussian) distribution or other distribution that the analog dynamical system 220 is sampling. The input parameters 211 may include the inductances, capacitances, voltages, and currents of adjustable inductors, capacitors, voltage sources, and current sources, respectively, that make up the analog system 220 as described below. The controller 214 sets these input parameters 211 via a serial bus or other suitable interface, then allows the analog system 220 to evolve for a predetermined period of time, also called a time step, integration period, or sampling period. Once that time has elapsed, the controller 214 reads the analog system's output parameters, which may include voltages, currents, and/or other analog values representing the analog system's final state, via the serial bus. These output parameters represent samples 221 of the multivariate Gaussian probability distribution. The controller 214 rejects errant or outlying parameter readings to correct for analog imperfections in the analog system 220.

The analog component 220 of the thermodynamic system 200 simulates physical (Hamiltonian) dynamics to sample the multivariate Gaussian distribution or other target probability distribution. The Hamiltonian H of the physical system 222 specifies the total energy of the physical system, including both kinetic energy and potential energy. In the sampling context, the Hamiltonian represents the target probability distribution, with q sample space variables in D dimensions. The HMC method traditionally involves taking the derivatives of the Hamiltonian with respect to sample space variables and with respect to the generalized momenta, p, then integrating trajectories with respect to time t over a series of time steps of duration ϵ. In this hybrid digital-analog approach, the dynamics of a physical system replace both the taking of derivatives and the trajectory integration.

One such physical system 222 is an analog electronic system-specifically, a network of coupled harmonic oscillators. As explained in greater detail below, the kinetic energy of a network of coupled harmonic oscillators maps to the energy function (Hamiltonian) of a multivariate Gaussian probability distribution up to a normalization constant. The oscillators' voltages and currents represent the position coordinates of the Hamiltonian of the multivariate Gaussian probability distribution, so they can be sampled to provide samples of the distribution.

### 2 Sampling a One-Dimensional Normal Probability Distribution

A single lumped circuit element, such as a basic LC oscillator, can be mapped to a one-dimensional (1D) normal (i.e., Gaussian) probability distribution as follows. As a result, an LC oscillator can be used as the analog dynamical system for sampling a 1D normal probability distribution in a thermodynamic computing platform that performs HMC calculations.

### 2.1 Hamiltonian Monte Carlo (HMC) on the 1D Normal Probability Distribution

Consider a normal distribution with mean μ and variance σ², such that the probability distribution can be written

$$𝒩 ( x , μ , {σ}^{2} ) = \frac{1}{\sqrt{2 π {σ}^{2}}} {e}^{- \frac{1}{2 {σ}^{2}} {( x - μ )}^{2}} .$$

An energy function corresponding to this system is

$$U ( x ) = \frac{1}{2 {σ}^{2}} {( x - μ )}^{2} .$$

Let p be the canonical momentum corresponding to x, and choose some kinetic energy function independent of x. The standard choice is

$$K ( p ) = \frac{{p}^{2}}{2 m} ,$$

where m represents the mass of the fictitious particle with position x. Then the total energy, or Hamiltonian, of the system is

$$H ( x , p ) = U ( x ) + K ( p ) = \frac{1}{2 {σ}^{2}} {( x - μ )}^{2} + \frac{{p}^{2}}{2 m} . \qquad ( 1 )$$

After specifying a Hamiltonian, HMC relies on two main ingredients to sample from the target distribution:
Hamiltonian dynamics
Given a Hamiltonian H and initial conditions x₀ and p₀ for x and p, HMC integrates Hamilton's equations,

$$\frac{dx}{dt} = \frac{\partial H}{\partial p}$$

$$and$$

$$\frac{dp}{dt} = - \frac{\partial H}{\partial x} ,$$

for some time. The new value for x and p at the end of integration are the next proposal in the MCMC chain.
Canonical distribution
Separately from the question of dynamics, given a Hamiltonian H and temperature T, there is a corresponding canonical probability distribution over x and p,

$$P ( x , p ) ∝ {e}^{- \frac{H ( x , p )}{{k}_{B} T}} ,$$

where k_{B} is Boltzmann's constant.
The structure of HMC is influence by the property that x and p are independent random variables. This property follows from the fact that U(x) and K(p) have non overlapping support:

$${e}^{- \frac{H ( x , p )}{{k}_{B} T}} = {e}^{- \frac{U ( x )}{{k}_{B} T}} {e}^{- \frac{K ( p )}{{k}_{B} T}} .$$

Connecting the two ingredients is the choice of initial conditions for the integration. The initial values x₀ and p₀ set the surface of constant probability density on which the Hamiltonian dynamics travel. Up to normalization, the probability density along the trajectory is

$${e}^{- \frac{U ( x )}{{k}_{B} T}} {e}^{- \frac{K ( p )}{{k}_{B} T}} . \qquad ( 2 )$$

The independence of the marginals lets us use resampling of p to choose a new constant value for the joint probability density; then, the Hamiltonian dynamics exchange this resampling of momentum into a resampling of position. To quote Neal et al., “MCMC using Hamiltonian dynamics,” in: Handbook of Markov Chain Monte Carlo, 2.11 (2011), “[s]ince [x] isn't changed, and p is drawn from its correct conditional distribution given [x] (the same as its marginal distribution, due to independence), this step obviously leaves the canonical joint distribution invariant.”

### 2.2 Hamiltonians and Electrical Circuits

The next subsections outline three steps to derive a Hamiltonian from a lumped element circuit.

### 2.2.1 Choose Coordinates

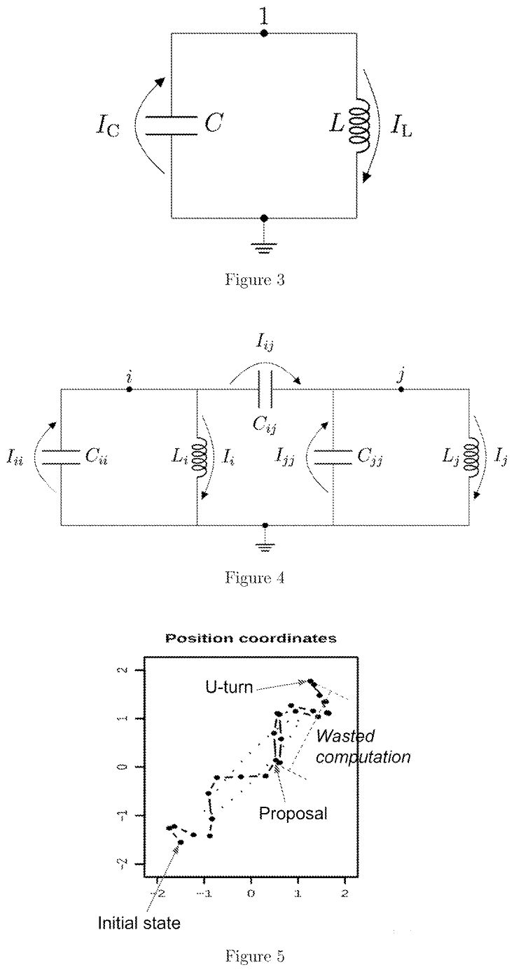

Suppose we start with an LC oscillator as in FIG. 3. The LC oscillator has an inductor with inductance L and a capacitor with capacitance C. We wish to write down a Lagrangian for this circuit, which will enable us to derive the corresponding Hamiltonian.

The method begins by choosing a coordinate for every branch and node in the circuit. Here, we have chosen branch coordinates I_{L} and I_{C} to be the currents in the inductor and capacitor; we have marked one node as the reference (ground) and the other with coordinate V, the voltage difference from that node to ground.

### 2.2.2 Derive the Lagrangian

Next, we write the total energy of the circuit in terms of these chosen coordinates. For a circuit, the total energy is the sum of the energies of the branches. From Kirchoff's laws, we have I_{L}=−I_{C}. From the definition of the capacitor, we have I_{C}=C(dV/dt). Thus we can write the energy of the capacitor and the inductor in terms of the voltage V and its time derivative:

$${E}_{C} = \frac{1}{2} {CV}^{2} and {E}_{L} = \frac{1}{2} {LI}_{L}^{2} = \frac{1}{2} {L ( - {I}_{C} )}^{2} = \frac{1}{2} {LC}^{2} {\dot{V}}^{2} .$$

Since we are treating the voltage as our position coordinate, the capacitor energy is our potential energy U and the inductor energy is our kinetic energy K.

Now we can write down the Lagrangian for our system:

$$ℒ ( V , \dot{V} ) = T - U = \frac{1}{2} {LC}^{2} {\dot{V}}^{2} - \frac{1}{2} {CV}^{2} .$$

Given this Lagrangian, the momentum conjugate p to our position coordinate V is

$$p = \frac{\partial ℒ}{\partial \dot{V}} = L {C}^{2} \dot{V}$$

and thus we can rewrite our Lagrangian in terms of position and momentum as

$$ℒ ( V , p ) = \frac{1}{2} \frac{1}{{LC}^{2}} {p}^{2} - \frac{1}{2} {CV}^{2} .$$

### 2.2.3 Legendre Transform to Obtain the Hamiltonian

Since we are trying to do Hamiltonian Monte Carlo, the Hamiltonian of our physical system should match the Hamiltonian corresponding to our probability distribution. To that end, we can now derive the Hamiltonian of our LC oscillator.

The Hamiltonian function for our 1D system is defined as

H(V,p)=p\dot{V}− [symbol] (V,p)

which yields

$$H ( V , p ) = \frac{1}{2} \frac{1}{{LC}^{2}} {p}^{2} + \frac{1}{2} {CV}^{2} .$$

The momentum conjugate p can be written in terms of the current through the capacitor as p=LCI_{C}.

### 2.3 Connecting the Gaussian to the LC Oscillator

Recall the two Hamiltonians we now have. One is an abstract Hamiltonian corresponding to the Gaussian with fictitious mass m,

$$H ( x , p ) = \frac{1}{2 {σ}^{2}} {( x - μ )}^{2} + \frac{{p}^{2}}{2 m} ,$$

and the other is the Hamiltonian of an electrical system,

$$H ( V , p ) = \frac{1}{2} {LI}_{C}^{2} + \frac{1}{2} {CV}^{2} .$$

Given these two Hamiltonians, we want to solve for values of L and C in the physical Hamiltonian in terms of the variance and mass of the Gaussian Hamiltonian.

First, see that the capacitance C is equal to the inverse variance. The mean can be implemented in hardware with a constant voltage offset, or in software by simply adding the mean to the otherwise zero-mean samples. The mass is equal to LC². Thus, after choosing a mean and variance, the inductance L is the free parameter allowing us to choose the mass.

This is one example of how to map a probability distribution to an equivalent electrical circuit.

### 3 Capacitively Coupled Harmonic Oscillators and Multivariate Normal Probability Distributions

### 3.1 Distribution Definition

An N-dimensional multivariate normal distribution is defined in terms of an N-dimensional mean vector \vec{μ} and an N×N covariance matrix Σ.

For now, assume \vec{μ}=0. With this, a multivariate normal distribution with covariance matrix Σ can be written

$$𝒩 ( \vec{x} \vert \sum ) = \frac{1}{\sqrt{{( 2 π )}^{N} \vert \sum \vert}} exp ( - \frac{1}{2} {\vec{x}}^{T} {\sum }^{- 1} \vec{x} ) . \qquad ( 3 )$$

Taking the logarithm, we arrive at an “energy function” corresponding to this distribution:

$${E}_{\sum } ( \vec{x} ) = \frac{1}{2} {\vec{x}}^{T} {\sum }^{- 1} \vec{x} - log ( Z ) ,$$

where Z=\sqrt{(2π)^{N}|Σ|} is a constant. Just like for the one-dimensional Gaussian, we can implement an electrical circuit to match this energy function.

### 3.2 Capacitively Coupled Oscillators

### 3.2.1 Circuit Lagrangian

Consider a set of N harmonic oscillators, each capacitively coupled to all the others. Any pair i, j of harmonic oscillators can be represented by the subcircuit shown in FIG. 4.

The total inductive energy of the circuit is

$${E}_{L} = \frac{1}{2} {\sum }_{i = 1}^{N} {L}_{i} {I}_{i}^{2} .$$

If we define the inductive matrix as

$${L}_{kl} = \{ \begin{matrix}{L}_{k} & if k = l \\ 0 & if k \neq l\end{matrix} ,$$

then we can write the total inductive energy as

$${E}_{L} = \frac{1}{2} {\vec{I}}^{T} L \vec{I} .$$

The total capacitive energy is

$${E}_{C} = \frac{1}{2} {\sum }_{i = 1}^{N} [ {C}_{i i} {V}_{i}^{2} + {\sum }_{j = i + 1}^{N} {{C}_{i j} ( {V}_{i} - {V}_{j} )}^{2} ] .$$

To simplify the subsequent calculus, define the Maxwell capacitance matrix C as

$${C}_{kl} = \{ \begin{matrix}{\sum }_{j} {C}_{kj} & if k = l \\ - {C}_{kl} & if k \neq l\end{matrix} .$$

Then we can rewrite the capacitive energy as

$${E}_{C} = \frac{1}{2} {\sum }_{ij} {V}_{i} {C}_{ij} {V}_{j} .$$

Suppose we want to treat the currents through the inductors as our position coordinates. To write down a Lagrangian, we rewrite the voltages in terms of the time derivatives of these position coordinates. For each voltage, we have the relation Vᵢ=Lᵢİᵢ. Thus we can write the capacitive energy as

$${E}_{C} = \frac{1}{2} {\sum }_{ij} {\dot{I}}_{i} {L}_{i} {C}_{ij} {L}_{j} {\dot{I}}_{j} .$$

Now the Lagrangian for the system can be written as

$$ℒ ( {\{ {I}_{i} , {\dot{I}}_{i} \}}_{1}^{N} ) = \frac{1}{2} {\sum }_{i j} {\dot{I}}_{i} {L}_{i} {C}_{ij} {L}_{j} {\dot{I}}_{j} \frac{1}{2} {\sum }_{i = 1}^{N} {L}_{i} {I}_{i}^{2} .$$

### 3.2.2 Circuit Hamiltonian

Hamiltonians are defined in terms of N positions qᵢ, N momenta pᵢ, and Lagrangian [symbol] as

$$ℋ = {\sum }_{i} {p}_{i} {\dot{q}}_{i} - ℒ ,$$

where the momenta are defined as

$${p}_{i} = \frac{\partial ℒ ( {\{ {q}_{j ,} {\dot{q}}_{j} \}}_{1}^{N} )}{\partial {\dot{q}}_{i}} .$$

In our case the momentum is

$$\begin{matrix}{p}_{k} = \frac{\partial ℒ ( {\{ {I}_{j} , {\dot{I}}_{j} \}}_{1}^{N} )}{\partial {\dot{I}}_{k}} \\ = \frac{1}{2} {\sum }_{i j} ( {δ}_{ik} {L}_{k} {C}_{kj} {L}_{j} {\dot{I}}_{j} + {δ}_{j k} {\dot{I}}_{i} {L}_{i} {C}_{i k} {L}_{k} ) \\ = \frac{1}{2} {\sum }_{j} {L}_{k} {C}_{kj} {L}_{j} {\dot{I}}_{j} + {\sum }_{j} {\dot{I}}_{j} {L}_{j} {C}_{jk} {L}_{k} \\ = {\sum }_{j} {L}_{k} {C}_{kj} {L}_{j} {\dot{I}}_{j} ,\end{matrix}$$

where, going line by line, we used: the definition of conjugate momentum; the product rule for derivatives; a contraction of the Kronecker delta and relabeled indices; and the fact that C is a symmetric matrix. We can summarize this in a matrix equation:

\vec{p}=LCL\dot{\vec{I}}

implying

\dot{\vec{I}}=L⁻¹C⁻¹L⁻¹\vec{p}.

Then the Lagrangian can be rewritten as

$$\begin{matrix}ℒ ( {\{ {I}_{i} , {p}_{i} \}}_{1}^{N} ) = \frac{1}{2} {\vec{\dot{I}}}^{T} LCL \dot{I} - \frac{1}{2} {\vec{I}}^{T} L \vec{I} \\ = \frac{1}{2} {\vec{p}}^{T} {L}^{- 1} {C}^{- 1} {L}^{- 1} L C L {L}^{- 1} {C}^{- 1} {L}^{- 1} \vec{p} - \frac{1}{2} {\vec{I}}^{T} L \vec{I} \\ = \frac{1}{2} {\vec{p}}^{T} {L}^{- 1} {C}^{- 1} {L}^{- 1} \vec{p} - \frac{1}{2} {\vec{I}}^{T} L \vec{I} .\end{matrix}$$

This implies the Hamiltonian of the system is

$$ℋ = \frac{1}{2} {\vec{p}}^{T} {L}^{- 1} {C}^{- 1} {L}^{- 1} \vec{p} + \frac{1}{2} {\vec{I}}^{T} L \vec{I} .$$

In terms of circuit parameters, we have the voltage across the inductor as

\vec{V}_{ind}=L\dot{\vec{I}},

so the momentum is

\vec{p}=LC\vec{V}_{ind}

and so the voltage in terms of the momentum is

\vec{V}_{ind}=C⁻¹L⁻¹\vec{p}.

Then, the Hamiltonian can also be calculated as

$$ℋ = \frac{1}{2} {\vec{V}}_{ind}^{T} C {\vec{V}}_{ind} + \frac{1}{2} {\vec{I}}^{T} L \vec{I} .$$

### 3.3 Change Coordinates

Existing codebases for HMC and its extensions assume the target distribution is encoded by the potential energy. Therefore we can greatly reduce our engineering workload if we can similarly encode our distribution in the potential energy. This involves changing the coordinates used to describe our analog electrical system. What changes can we make to the original coordinates (\vec{p}, \vec{q}) and Hamiltonian H such that the resulting stationary paths of the new Hamiltonian K in the new coordinate system (\vec{P}, \vec{Q}) are equal to those for the original Hamiltonian?

### 3.3.1 General Theory

To start, consider whether our original Hamiltonian system satisfies:

$$δ {\int }_{{t}_{0}}^{{t}_{1}} ( \vec{q} \cdot \vec{p} - H ( \vec{p} , \vec{q} ) ) = 0 , \qquad ( 4 )$$

where the integrand is the Lagrangian expressed in terms of the Hamiltonian. Consider a arbitrary transformation to the system, such that the old and new Hamiltonians are related by:

$$λ [ \vec{p} \cdot \vec{\dot{q}} - H ] = \vec{P} \cdot \vec{\dot{Q}} - K + \frac{dF}{d t} \qquad ( 5 )$$

for some scalar λ and some function of the phase space coordinates F with continuous second derivatives. We now show explicitly that the new Hamiltonian K has the same stationary paths as H.

Since K=H(\vec{P}, \vec{Q}) is also a Hamiltonian, we have

$$\begin{matrix}δ {\int }_{{t}_{0}}^{{t}_{1}} ( \vec{\dot{Q}} \cdot \vec{P} - K ) = δ {\int }_{t 0}^{{t}_{1}} ( λ [ \vec{p} \cdot \vec{\dot{q}} - H ] - \frac{dF}{d t} ) \\ = λ δ {\int }_{t 0}^{{t}_{1}} ( \vec{p} \cdot \vec{\dot{q}} - H ) - δ {\int }_{t 0}^{{t}_{1}} ( \frac{dF}{d t} ) \\ = λ δ {\int }_{{t}_{0}}^{{t}_{1}} ( \vec{p} \cdot \vec{\dot{q}} - H ) - δ ( F ( {t}_{1} ) - F ( {t}_{0} ) ) \\ = λ δ {\int }_{t 0}^{{t}_{1}} ( \vec{p} \cdot \vec{\dot{q}} - H )\end{matrix}$$

where, going line by line, we apply: the definition of Hamiltonian dynamics for K and substitution in terms of H; the linearity of integration and differentiation; the fundamental theorem of line integrals; the independence of the difference in endpoint values from variations in the path of integration. The stationary paths of both sides of the equation are identical: the location of the stationary paths does not depend on the multiplicative constant A.

### 3.3.2 Prove New Coordinates

With the result of the previous section in hand we have a procedure to check that our transformations are canonical. Given any new Hamiltonian K in terms of coordinates (\vec{P}, \vec{Q}), we can check that it yields the same dynamics as some other Hamiltonian H(\vec{p}, \vec{q}) by demonstrating a scalar λ and a function G such that equation (5) is satisfied.

For our system, consider the original Hamiltonian

$$H = \frac{1}{2} {\vec{p}}^{T} {L}^{- 1} {C}^{- 1} {L}^{- 1} \vec{p} + \frac{1}{2} {\vec{p}}^{T} L \vec{q} . \qquad ( 6 )$$

Posit new coordinates,

\vec{Q}=−L⁻¹\vec{p} and \vec{P}=L\vec{q}, (7)

which yield the transformed Hamiltonian

$$K = \frac{1}{2} {\vec{Q}}^{T} {C}^{- 1} \vec{Q} + \frac{1}{2} {\vec{P}}^{T} {L}^{- 1} \vec{P} \qquad ( 8 )$$

since we assume L is symmetric.

Let F=\vec{p}·\vec{q} and λ=1. Then we have

$$\frac{dF}{d t} = \vec{\dot{p}} \cdot \vec{q} + \vec{p} \cdot \vec{\dot{q}} . \qquad ( 9 )$$

with these definitions, check that equation (5) is satisfied:

$$\begin{matrix}\vec{P} \cdot \vec{\dot{Q}} − K + \frac{dF}{dt} = \vec{P} \cdot \vec{\dot{Q}} − \frac{1}{2} {\vec{Q}}^{T} {C}^{− 1} \vec{Q} − \frac{1}{2} {\vec{P}}^{T} {L}^{− 1} \vec{P} + \frac{dF}{dt} \\ = − {\vec{\dot{p}}}^{T} {L}^{− 1} L \vec{q} − \frac{1}{2} {\vec{p}}^{T} {L}^{− 1} {C}^{− 1} {L}^{− 1} \vec{p} − \frac{1}{2} {\vec{q}}^{T} L \vec{q} + \vec{\dot{p}} \cdot \vec{q} + \vec{p} \cdot \vec{\dot{q}} \\ = − \frac{1}{2} {\vec{p}}^{T} {L}^{− 1} {C}^{− 1} {L}^{− 1} \vec{p} − \frac{1}{2} {\vec{q}}^{T} L \vec{q} + \vec{p} \cdot \vec{\dot{q}} \\ = λ [ \vec{p} \cdot \vec{\dot{q}} − H ]\end{matrix}$$

where, going line by line, we applied: the definition of K; the definitions of the coordinate transform and F; the cancellation of opposite terms; and the definitions of H and λ. Therefore this transformation is valid.

### 3.3.3 Final Physical and Abstract Relationships

We summarize definitions below. We have the abstract Hamiltonian

$$H = \frac{1}{2} {\vec{Q}}^{T} {C}^{- 1} \vec{Q} + \frac{1}{2} {\vec{P}}^{T} {L}^{- 1} \vec{P} \qquad ( 10 )$$

where the coordinates are related to circuit quantities by

\vec{Q}=−L⁻¹\vec{p}=−C\vec{V}_{ind} (11)

and

\vec{P}=L\vec{q}=L\vec{I}_{ind}⇔\vec{I}_{ind}=L⁻¹\vec{P}. (12)

### 3.3.4 Solve for Inductor Currents in Terms of Capacitor Currents

Consider again the circuit in FIG. 4. The current at node i is

$$0 = {\sum }_{j \leq i} {I}_{ij} - {I}_{i} - {\sum }_{j > i} {I}_{ij}$$

$${I}_{i} = {\sum }_{j \leq i} {I}_{ij} - {\sum }_{j > i} {I}_{ij} .$$

Current through a capacitor is I_{C}=C\dot{V}, so

$${I}_{i} = {\sum }_{j \leq i} {C}_{ij} {\dot{V}}_{ij} - {\sum }_{j > i} {C}_{ij} {\dot{V}}_{ij}$$

Define a sign matrix

$${S}_{k l} = \{ \begin{matrix}1 & if k \leq l \\ - 1 & if k > l\end{matrix} .$$

Thus we can combine the sums by writing

$${I}_{i} = {\sum }_{j} {C}_{ij} {S}_{ij} {\dot{V}}_{ij} .$$

Going to a matrix form, we then have

I=C⊙S\vec{\dot{V}}.

### 3.4 Connection to Multivariate Normal

If we set values in the circuit such that C=Σ, then the potential energy of the electrical system in our transformed coordinate system equals the energy of the target multivariate normal.

Recall that the Maxwell capacitance matrix is defined as:

$${C}_{k l} = \{ \begin{matrix}{\sum }_{j} {C}_{kj} & if k \leq l \\ - {C}_{kl} & if k \neq l\end{matrix} .$$

This means that in terms of the discrete capacitors, we equivalently have the relationship

$${\sum }_{k l} = \{ \begin{matrix}{\sum }_{j} {C}_{kj} & if k \leq l \\ - {C}_{kl} & if k \neq l\end{matrix} .$$

Inverting the relations, given a covariance matrix Σ, we set the individual capacitances by first setting the coupling capacitors as

Cₖₗ=−Σₖₗ.

Then the capacitances to ground can be set as

$${C}_{i i} = {\sum }_{i i} - {\sum }_{j \neq i} {C}_{ij} = {\sum }_{i i} + {\sum }_{j \neq i} {\sum }_{ij} = {\sum }_{j} {\sum }_{ij} .$$

### 3.5 Normal Modes

Consider an instance of the HMC process running on a 2D Gaussian, shown in FIG. 5. This figure demonstrates the importance of choosing the integration time carefully: integrate too long, and you return to locations already visited, which means computation has been wasted.

Typically, this is addressed by upgrading HMC to the No U-Turn Sampler (NUTS), which adaptively sets the integration time to avoid such U-Turns. However, because the Gaussian is a particularly simple distribution, we can imagine calculating directly a reasonable integration time.

To that end, suppose we have a system of coupled oscillators with mass matrix M and spring constant matrix K. In terms of a physical mass spring system, we have

K=C⁻¹=Σ⁻¹ (13)

and

M=L. (14)

Then, in terms of the vector of oscillator positions \vec{q}, the equation of motion can be written as

M\vec{\ddot{q}}=−K\vec{q}

Solving the equation of motion yields a generalized eigenvalue equation for the normal angular frequencies ω, in terms of the unknown eigenvector \vec{a}:

(K−ω²M)\vec{a}=0 (15)

We can rearrange this as

K\vec{a}=ω²M\vec{a}

ω⁻²K\vec{a}=M\vec{a}

Kω⁻²\vec{a}=M\vec{a}

ω⁻²\vec{a}=K⁻¹M\vec{a}.

Defining A=K⁻¹M and λ=ω⁻², we have the standard eigenvalue equation

A\vec{a}=λ\vec{a}. (16)

The normal frequencies are then found by setting ƒ=ω/(2π)=λ^{-1/2}/(2π) for each eigenvalue λ.

Given these normal frequencies, we can tell how long to integrate for before we start to make a U turn in the slowest moving (lowest frequency) direction. Let ƒₘᵢₙ be the minimum normal mode frequency. Then, we are back where we started after one period,

$${τ}_{max} = \frac{1}{{f}_{min}} ,$$

so that τₘₐₓ is an upper bound on the integration time. So we choose a smaller value for the integration time, say,

$$τ = \frac{1}{4 {f}_{min}} ,$$

or one-fourth of the longest period.

### 3.6 Scaling the Frequency

To have control over the frequencies of the oscillators, we can scale down both the capacitance and the inductance, since the frequency of an oscillator goes as ω∝1/\sqrt{LC}. We can modify the proof of the Cholesky decomposition process to sample from a scaled down version of the desired Gaussian, giving us a scale parameter n with which to tune the oscillator frequencies.

### 3.6.1 General Theory

Define a target Gaussian probability density g on [symbol] ^{d} with mean \vec{μ} and covariance matrix Σ,

$$g ( \vec{x} ) = \frac{1}{{( 2 π )}^{d / 2} {\vert det \sum \vert}^{1 / 2}} exp ( - \frac{1}{2} {( \vec{x} - \vec{μ} )}^{T} {\sum }^{- 1} ( \vec{x} - \vec{μ} ) ) .$$

Define a bijective and continuously differentiable transformation φ as

φ(\vec{x})=η\vec{x}+\vec{μ}. (17)

Suppose we define a new function ƒ as

ƒ(\vec{x})=g(φ(\vec{x}))|det Dφ(\vec{x})|.

If X is some random variable with density ƒ, then φ(X) has density g. So let's see if it is convenient to sample from the density ƒ.

We have

Dφ(\vec{x})=η [symbol] ,

that is, η times the identity matrix. Thus we have

|det Dφ(\vec{x})|=η^{d}.

For the composition, we have

$$g ( φ ( \vec{x} ) ) = \frac{1}{{( 2 π )}^{d / 2} {\vert det \sum \vert}^{1 / 2}} exp ( - \frac{1}{2} η {\vec{x}}^{T} {\sum }^{- 1} η \vec{x} ) .$$

Let \tilde{Σ}=η⁻²Σ. Then

$$\begin{matrix}g ( φ ( \vec{x} ) ) = \frac{1}{{( 2 π )}^{d / 2} {\vert det {η}^{2} \tilde{\sum } \vert}^{1 / 2}} exp ( - \frac{1}{2} {\vec{x}}^{T} {\tilde{\sum }}^{- 1} \vec{x} ) \\ = \frac{{η}^{- d}}{{( 2 π )}^{d / 2} {\vert det \tilde{\sum } \vert}^{1 / 2} -} exp ( - \frac{1}{2} {\vec{x}}^{T} {\tilde{\sum }}^{- 1} \vec{x} ) .\end{matrix}$$

Multiplying g(φ(\vec{x})) and |det Dφ(\vec{x})| yields

$$f ( \vec{x} ) = \frac{1}{{( 2 π )}^{d / 2} {\vert det \sum \vert}^{1 / 2}} exp ( - \frac{1}{2} {\vec{x}}^{T} {\tilde{\sum }}^{- 1} \vec{x} ) ,$$

which is the probability density of a centered Gaussian with covariance matrix \tilde{Σ}.

### 3.6.2 Circuit Parameter Perspective

Thus we have a scaling procedure. Consider that increasing the frequency of the physical oscillators occurs by decreasing either or both of inductance or capacitance. Since we set Σ_{physical}=C for the capacitively coupled oscillators, for fixed inductance L we will have higher frequencies if we set Σ_{physical}<Σ.

In other words, the frequencies will be higher if η>1 and

Σ_{physical}=η⁻²Σ. (18)

By the derivation above: samples drawn from the system will be distributed according to [symbol] (0, Σ_{physical}); and mapping each sample \vec{x} to φ(\vec{x}) yields samples distributed according to [symbol] (\vec{μ}, Σ).

### 3.6.3 Frequency Scaling Quantified

How much is the frequency changed? Recall that the eigenvalue equation for a system of coupled oscillators is

ω⁻²\vec{a}=K⁻¹M\vec{a}. (19)

In terms of the system covariance matrix, this becomes

$${ω}_{physical}^{- 2} \vec{a} = {\sum }_{physical} L \vec{a} .$$

Substituting the target covariance Σ and the scaling factor η yields

$${ω}_{physical}^{- 2} \tilde{a} = {η}^{- 2} \sum L \vec{a} .$$

If ω represents the normal mode frequencies of the original target distribution,

ω⁻²\vec{a}=ΣL\vec{a},

then

ω_{physical}=ηω.

Thus the factor η used in the definition of φ is exactly the amount by which the normal mode frequencies are multiplied.

### 4 Physical Implementation

FIG. 6 shows a hardware implementation that primarily achieves the sampling part of the overall computational process. This hardware implementation includes a digital system, implemented here as an FPGA controller 610, operably coupled an analog system, show here as an LC resonator 620 coupled to an analog-to-digital converter (ADC), digital-to-analog converter (DAC), noise source, and switches 630. The samples are voltage levels across the LC resonators 620 (also called unit cells or cells, detailed in section 4.1) when excited with the noise source 630. A user can interact with the hardware implementation via a personal computer (PC) 602 that is operably coupled to the FPGA controller 610.

The PC 602 downloads three different types of information from the FPGA controller 610: (1) cells resonant frequency, (2) coupling sections and their respective polarities, and (3) noise level. The FPGA controller 610 (detailed in section 4.3) sets up the circuits according to the downloaded data. An ADC samples the voltages and stores the data in the FPGA's on-chip memory. Once the FPGA controller 610 has collected a predetermined amount of data, it sends the data back to the PC 602.

The interface between the FPGA controller 610 and the PC 602 shown in FIG. 6 is a virtual COM port over USB. Other interface protocols are also possible (e.g., PCIe, or CXL).

### 4.1 Coupled Resonators

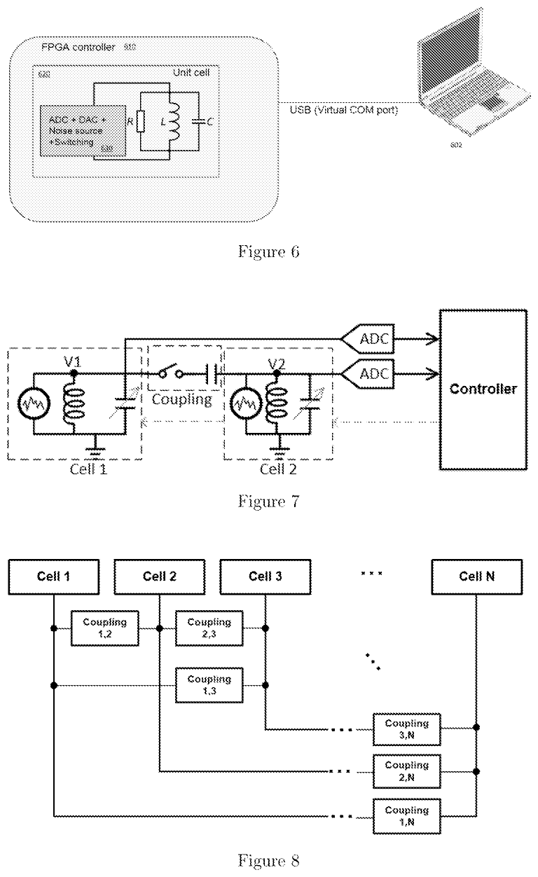

FIG. 7 shows coupled resonators in the form of two capacitively coupled, parallel LC circuits. The coupling and the cell capacitance are dictated by the controller. The capacitors can be tuned in an analog or digital fashion, while the inductances can remain constant.

Coupling a larger number of resonators improves system performance. The nature of coupling (e.g., all-to-all, linear, etc.) is dictated by the desired processing and the hardware limitations. FIG. 8 shows a conceptual all-to-all coupling between N cells.

The exact implementation of the cells and the coupling sections are technology dependent. Sections 4.1.1 and 4.1.2 show examples of how to implement cells in technologies compatible with printed circuit boards (PCBs).

### 4.1.1 Tunable Resonators

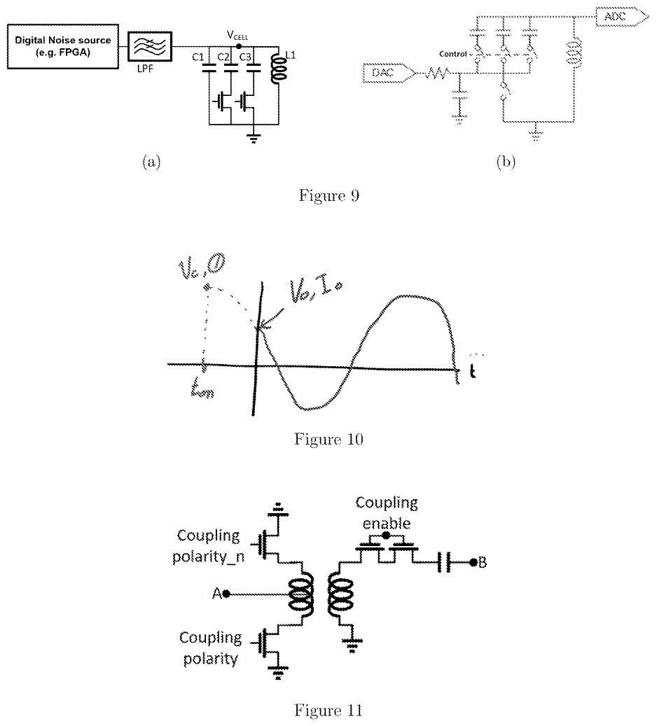

FIG. 9a (a) shows a structure for a switch-tunable resonator. The capacitors can change their values using a shunt switch (e.g., transistor). The minimum capacitance value (C1) does not require a switch. The top plate of the capacitors represent the voltage that is sampled and coupled to other cells.

The noise source can be implemented with a digital controller to reduce or minimize the dependence on analog circuits. Consequently, a Lowpass Filter (LPF) filters out the unnecessary and/or undesired high-frequency components of the output signal. This is detailed in Section 4.4.

### 4.1.2 Controlled Coupling

The coupling units between cells can be implemented as shown in FIG. 11. The series switch (controlled by Coupling enable signal) can turn the coupling ON or OFF. The polarity of the coupling is controlled by the signal Coupling polarity. The negative and positive polarity is achieved by using the transformer setup as shown in the figure.

### 4.2 Analog to Digital Converter (ADC)

The voltage reading from each cell is done using an ADC. The configuration uses a single ADC channel for each cell. Alternatively, multiple cells can share a single ADC if they are sampled simultaneously. The input impedance of the ADC should be taken into consideration with respect to the resonant frequency of the cells.

### 4.3 Controller (FPGA)

The controller in the PCB handles the following functions:
Download and upload interface with the PC
Interface with the ADC (read and store data, initializations, etc.)
Control the cell switches to tune the resonators.
Control the coupling switches to turn them ON or OFF with the proper polarity
Generate a Pseudorandom noise (Section 4.4)

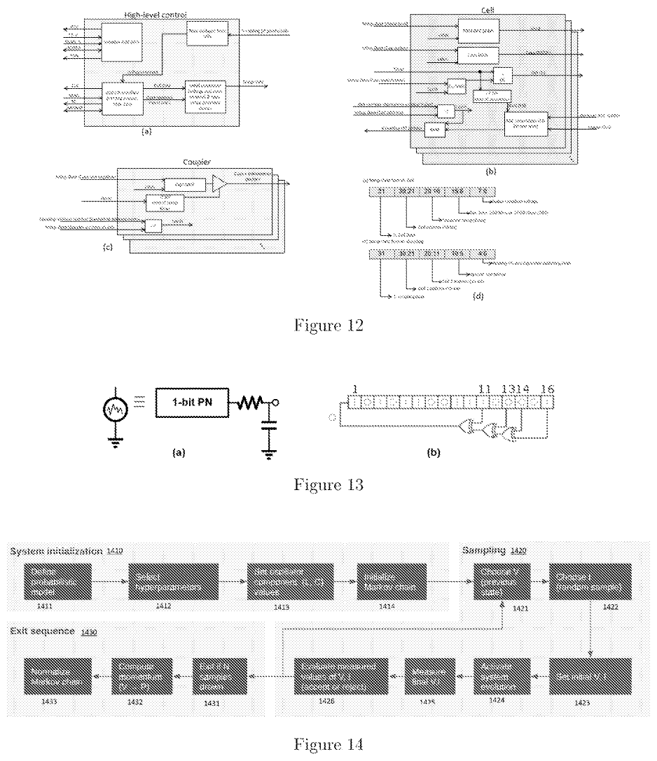

FIG. 12 shows the block diagrams for the functionality of the FPGA, along with the protocol of the setup data from the PC.

### 4.4 Noise Injection

Each unit cell has an independent noise source. Since the cells are set up as a parallel LC circuit, the noise sources in FIG. 7 are current sources. One way to implement this is to generate a single-bit pseudo-random noise (PN) and filter the output using an RC circuit as shown in FIG. 13A. The presence of the resistor also makes the PRN voltage source appear as a current source (Thevenin to Norton conversion).

The amplitude of the noise can be controlled using a Pulse Density Modulation (PDM) for the single-but noise source.

### 4.4.1 PN Polynomials

The single-bit pseudo-random sequence is implemented with a Linear Feedback Shift Register (LFSR) configuration, representing a primitive polynomial. Each cell starts at a different initial condition so that the cells generate uncorrelated pseudo noise sequences. The length of the shift register should be large enough to ensure that the noise of each unit cell is far enough from the other sequences. A typical shift LFSR is shown in FIG. 13B.

### 5 how it Works

### 5.0.1 Initialize System

In this stage, the device is prepared to sample from a particular multivariate normal distribution according to the process shown in FIG. 14, starting with system initialization 1410:
1. Define the probabilistic model 1411 (digital device): Target covariance matrix Σ and target mean vector \vec{μ} define a d dimensional normal distribution [symbol] (\vec{μ}, Σ)
2. Select hyperparameters 1412 (digital device): Use the Lanczos process to compute the highest and lowest normal mode frequencies of Σ, λₘₐₓ and λₘᵢₙ. Choose a scaling factor η such that ηλₘₐₓ is approximately equal to the frequency λ_{threshold}, ηλₘₐₓ≈λ_{threshold}, which is the highest feasible frequency given the characteristics of the tunable components and the measurement circuits of the oscillator block implementation.
   Why η? This lets us choose the speed of our device independently of the target covariance matrix. Without η, the frequencies are fixed by the normal mode equation (15).
   λ_{threshold} is set by the fact that device speed (set by η) and device accuracy (set by the measurement circuitry) exhibit some tradeoff; the exact value is driven by simulations of the overall oscillator system.
Set the target physical covariance matrix as Σ_{physical}=η⁻²Σ (for details, see section 3.5). Set the integration time τ=1/(4λₘᵢₙ) to be used for our modified HMC sampling process (for details on this choice, see section 3.6).
3. Set oscillator component values 1413 (analog device): Choose a setting Lᵢ of each tunable inductor F (say, all equal to 1/(2πηλₘₐₓ)). These values form the diagonal matrix L. Calculate the capacitance matrix, which is equal to C=Σ_{physical}. Set each coupling capacitor to the value Cᵢⱼ=−Cᵢⱼ. Set each i^{th} tunable oscillator capacitor E to Cᵢᵢ=Cᵢᵢ−Σ_{j≠i}Cᵢⱼ.
4. Initialize Markov chain 1414 (digital device): Initialize the Markov chain S on the digital device. The initial state is a vector of all zeros of length d, the dimension of the target normal distribution. This chain represents the voltage values.

### 5.0.2 Draw Samples

In the sampling stage 1420, the digital device (digital controller) and physical device (network of coupled analog unit cells) collaborate to advance a Markov chain on the voltage. The repetition part of the following procedure is our adaptation of the Hamiltonian Monte Carlo (HMC) process: we use the momentum instead of the position as our chain state, and the physical device does the integration through its natural dynamics rather than the digital device via numerical integration. The accept/reject step of the loop is a novel form of analog error correction, since it corrects for deviations of the physical device from the target distribution. Repeat the following steps N times:
1. Choose V 1421 (digital device): The most recent state in the Markov chain S is the next voltage value \vec{V} (the initial voltages at which to set each inter-oscillator coupling spike J).
2. Choose I 1422 (digital device): Draw from d uncorrelated unit normal distributions [symbol] (0, 1), yielding a length d vector \vec{x}. The initial value of the currents \vec{I} is computed as \vec{I}=\sqrt{L⁻¹}\vec{x}.
3. Set initial V, I 1423 (analog device): Open switch B and close switches A and C. Set the voltage sources D to \vec{V}, and set the current sources G to \vec{I}.
4. Activate system evolution 1424 (analog device): Flip the switches so that B is closed and A, C are open in each oscillator block; turn off the voltage and current sources. This allows the oscillators to begin evolving freely.
5. Measure final V, I 1425 (analog device) after time τ, measure the final trajectory values—use each volt meter X to measure the final voltages \vec{V}_{final} on the coupling spikes J; use each current meter Y to measure the final currents \vec{I}_{final} running through the oscillator inductors F.
6. Evaluate measured values 1426 (digital device): compute the initial value of the energy,

$${ℋ}_{initial} = \frac{1}{2} {\vec{V}}^{T} C \vec{V} + \frac{1}{2}$$

and the final value of the energy,

$${ℋ}_{final} = \frac{1}{2} {\vec{V}}_{final}^{T} C {\vec{V}}_{final} + \frac{1}{2} {\vec{I}}_{final}^{T} L {\vec{I}}_{final} .$$

Compute the acceptance rate α=exp( [symbol] ᵢₙᵢₜ− [symbol] _{final}). Sample a value u from a uniform distribution on the interval [0, 1]. If u<α, append −1.0*\vec{V}_{final} to the Markov chain S; else, append \vec{V}.

### 5.0.3 Exit Sequence

In the exit sequence stage 1430, we transform back from physical quantities to target distribution samples.
1. Exit 1431 (digital device): once N samples are drawn, stop appending values to the Markov chain.
2. Compute momentum 1432 (digital device): Change variables from electrical quantities (voltages) to algorithmic quantities (momenta). Do this by applying the transformation \vec{p}=LC\vec{V} for each \vec{V} in the Markov chain S.
3. Normalize Markov chain 1433 (digital device): Apply the transformation φ(\vec{p})=η\vec{p}′\vec{μ} to each momentum \vec{p}; return the result.

### 6 Inductive Coupling

6.1 Inductively Coupled harmonic oscillators for Sampling Multivariate Distributions

### 6.1.1 Circuit Lagrangian

Consider a set of N harmonic oscillators, each inductively coupled to all the others through mutual inductances Lᵢⱼ. Any pair i, j of oscillators can be represented by the following subcircuit:

The total inductive energy of the circuit is

$${E}_{L} = \frac{1}{2} {\sum }_{i = 1}^{N} [ {L}_{ii} {I}_{i}^{2} + {\sum }_{j \neq i}^{N} {L}_{ij} {I}_{i} {I}_{j} ]$$

and the total capacitive energy is

$${E}_{C} = \frac{1}{2} {\sum }_{i = 1} {C}_{i} {V}_{i}^{2} .$$

To simplify the subsequent calculus, define the inductance matrix L as

Lₖₗ=Lₖₗ.

Then we can rewrite the inductive energy as

$${E}_{L} = \frac{1}{2} {\sum }_{ij} {I}_{i} {L}_{ij} {I}_{j} .$$

Suppose we want to treat the voltages between the nodes of the circuit as our position coordinates. To write down a Lagrangian, we rewrite the currents in terms of the time derivatives of these position coordinates. For each current, we have the relation Iᵢ=Cᵢ\dot{V}ᵢ. Thus we can write the inductive energy as

$${E}_{L} = \frac{1}{2} {\sum }_{ij} {\dot{V}}_{i} {C}_{i} {L}_{ij} {C}_{j} {\dot{V}}_{j} .$$

Now the Lagrangian for the system can be written as

$$ℒ ( {\{ {V}_{i} , {\dot{V}}_{i} \}}_{1}^{N} ) = \frac{1}{2} {\sum }_{ij} {\dot{V}}_{i} {C}_{i} {L}_{ij} {C}_{j} {\dot{V}}_{j} - \frac{1}{2} {\sum }_{i = 1}^{N} {C}_{i} {V}_{i}^{2} .$$

### 6.1.2 Circuit Hamiltonian

Hamiltonians are defined in terms of N positions qᵢ, N momenta pᵢ, and Lagrangian [symbol] as

$$ℋ = {\sum }_{i} {p}_{i} {\dot{q}}_{i} - ℒ$$

where the momenta are defined as

$${p}_{i} = \frac{\partial ℒ ( {\{ {q}_{j} , {\dot{q}}_{j} \}}_{1}^{N} )}{\partial {\dot{q}}_{i}} .$$

In our case the momentum is

$$\begin{matrix}{p}_{k} & = \frac{\partial ℒ ( {\{ {V}_{j} , {\dot{V}}_{j} \}}_{1}^{N} )}{\partial {\dot{V}}_{k}} \\ & = \frac{1}{2} {\sum }_{ij} ( {δ}_{ik} {C}_{k} {L}_{kj} {C}_{j} {\dot{V}}_{j} + {δ}_{jk} {\dot{V}}_{i} {C}_{i} {L}_{ik} {C}_{k} ) \\ & = \frac{1}{2} {\sum }_{j} {C}_{k} {L}_{kj} {C}_{j} {\dot{V}}_{j} + {\sum }_{j} {\dot{V}}_{j} {C}_{j} {L}_{jk} {C}_{k} \\ & = {\sum }_{j} {C}_{k} {L}_{kj} {C}_{j} {\dot{V}}_{j}\end{matrix}$$

where, going line by line, we used: the definition of conjugate momentum; the product rule for derivatives; contraction of the Kronecker delta and relabeled indices; and the fact that L is a symmetric matrix. We can summarize this in a matrix equation:

\vec{p}=CLC\dot{\vec{V}}

implying

\dot{\vec{V}}=C⁻¹L⁻¹C⁻¹\vec{p}.

C⁻¹\vec{p}=LC\dot{\vec{V}}.

Then the Lagrangian can be rewritten as

$$\begin{matrix}ℒ ( {\{ {V}_{i} , {p}_{i} \}}_{1}^{N} ) & = \frac{1}{2} {\vec{\dot{V}}}^{T} CLC \vec{\dot{V}} - \frac{1}{2} {\vec{V}}^{T} C \vec{V} \\ & = \frac{1}{2} {\vec{p}}^{T} {C}^{- 1} {L}^{- 1} {C}^{- 1} {CLCC}^{- 1} {L}^{- 1} {C}^{- 1} \vec{p} - \frac{1}{2} {\vec{V}}^{T} C \vec{V} \\ & = \frac{1}{2} {\vec{p}}^{T} {C}^{- 1} {L}^{- 1} {C}^{- 1} \vec{p} - \frac{1}{2} {\vec{V}}^{T} C \vec{V}\end{matrix} .$$

This implies the Hamiltonian of the system is

$$ℋ = \frac{1}{2} {\vec{p}}^{T} {C}^{- 1} {L}^{- 1} {C}^{- 1} \vec{p} - \frac{1}{2} {\vec{V}}^{T} C \vec{V} .$$

### 6.1.3 Direct Inductive Coupling

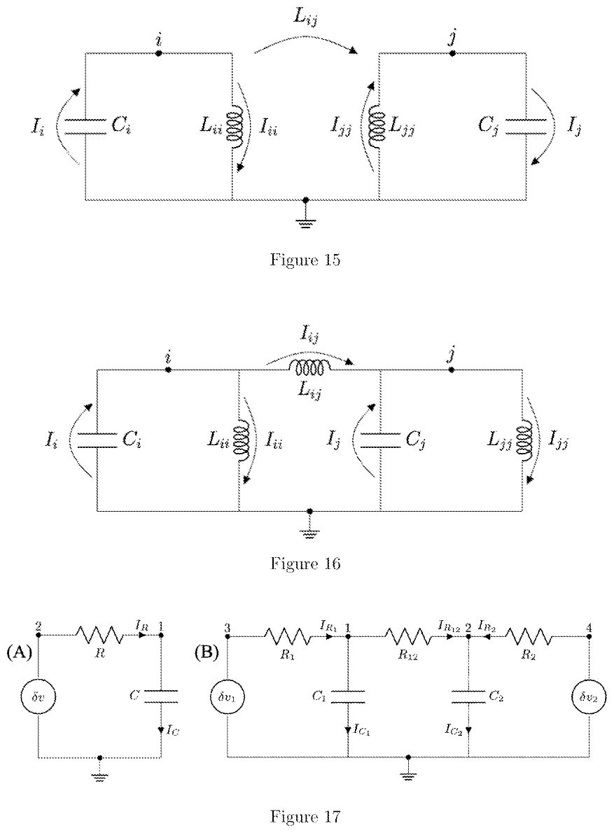

Consider a set of N harmonic oscillators, each having direct inductive coupling to all the others. Any pair i, j of oscillators can be represented by the subcircuit shown in FIG. 16.

The total inductive energy of the circuit is

$${E}_{L} = \frac{1}{2} {\sum }_{i = 1}^{N} [ {L}_{ii} {I}_{i}^{2} + {\sum }_{j = i + 1}^{N} {L}_{ij} {I}_{ij}^{2} ] ,$$

where the current in the coupling branch is

$${I}_{i j} = {I}_{i} - {I}_{i i} + {\sum }_{k \neq j} {I}_{i k} .$$

This means that the inductive energy does not couple the neighboring cells.

### 6.2 Combining Inductive and Capacitive Coupling

More generally, a multivariate normal probability distribution maps to a network of coupled harmonic oscillators, whether that coupling is inductive, capacitive, or inductive and capacitive. Again, the network includes one harmonic oscillator for each dimension of the multivariate normal probability distribution, and the mapping is based on the Lagrangian and Hamiltonian of the circuit.

For this general case of inductive and/or capacitive coupling, the derivation of the Lagrangian and Hamiltonian is conceptually similar to the derivations presented above. Similarly, the resulting Hamiltonian can be mapped to a multivariate normal probability distribution following the derivation presented above. Hence for simplicity we omit the derivation and remark that it is possible to combine inductive and capacitive coupling.

### 7 Resistive Coupling

An alternative means of coupling unit cells is using resistors. In this case, we can consider a unit cell involving a noisy resistor at non-zero temperature. FIG. 17(A) shows the typical equivalent noise model for a noisy resistor composed of a stochastic voltage noise source, δv(t), in series with an ideal (non-noisy) resistor of resistance R. The terminal capacitance, C, of the resistor is also added to the equivalent resistor model. The voltage on node 1 (labeled simply as v(t) here) is the state variable, whose dynamics obey:

−\dot{v}(t)=δv(t)+δv(t)/RC. (20)

This stochastic differential equation (SDE) comprises a drift term proportional to v(t) and a diffusion or stochastic term proportional to δv(t).

When building systems of many unit cells, one will wish to couple them to express correlations and geometric constraints. As an example, two unit cells could be coupled through a resistor, as pictured in FIG. 17(B). The coupled unit cells, represented by the voltage on nodes 1 and 2, are then coupled through their drift terms as

−\dot{v}=C⁻¹(Jv+R⁻¹δv), (21)

where

$$\dot{v} ≡ \frac{d}{d t} v and$$

$$v ≡ [ \begin{matrix}{υ}_{1} \\ {υ}_{2}\end{matrix} ] , C ≡ [ \begin{matrix}{C}_{1} & 0 \\ 0 & {C}_{2}\end{matrix} ] , R ≡ [ \begin{matrix}{R}_{1} & 0 \\ 0 & {R}_{2}\end{matrix} ] ,$$

$$J ≡ [ \begin{matrix}\frac{1}{{R}_{1}} + \frac{1}{{R}_{12}} & - \frac{1}{{R}_{12}} \\ - \frac{1}{{R}_{12}} & \frac{1}{{R}_{2}} + \frac{1}{{R}_{12}}\end{matrix} ] , δ v ≡ [ \begin{matrix}{δυ}_{1} \\ {δυ}_{2}\end{matrix} ] .$$

Here we introduced the self-resistance matrix R, the capacitance matrix C, and the conductance matrix J. One can then build up a system of many coupled unit cells using the basic building blocks shown in FIG. 17.

### 8 Tunable Constructions for Components

In order to be able to express an arbitrary Gaussian distribution, the components of the hardware should be changed or tuned for each distribution. The choice of components should be done with the trade-off of precision and range in mind.

### 8.1 Tunable Constructions for Capacitors

Two ways in which tunable capacitors can be implemented in the HMC hardware are: (1) with a switching capacitor bank and (2) with variable capacitor (varactor) diodes.

### 8.1.1 Switching Capacitor Bank

FIG. 18 illustrates a switching capacitor bank. A switching capacitor bank is made of several capacitors that can be connected in parallel in any combination to achieve a number of different values of capacitance. A digital signal is used to actuate the switches to connect or disconnect the capacitors. The device thus behaves effectively like a tunable capacitor, where the capacitance value is tuned by a digital voltage signal as shown in FIG. 18.

Since the device can include any number of capacitors of any value of capacitance, this device can theoretically have arbitrary range and precision, at the cost of large physical area, loss, and parasitic capacitors. Additionally, since this device is made up of regular capacitors, this device has generally good linearity and is well-behaved at a wide range of voltage amplitudes.

### 8.1.2 Varactor Diodes

A varicap diode is a semiconductor device that has a voltage-dependent capacitance value. This type of diode has a depletion layer that is particularly sensitive to its voltage bias. The capacitance value can thus be changed by varying the value of the voltage bias across the diode. These diodes are specifically designed for the desired range of tunability. The varicap has in general a smaller range of tunability than the switching bank of capacitors, but has continuous tunability.

Another consideration for these semiconductor devices is their non-linearity. This means that the device behaves as a linear capacitor for very small fluctuating voltages. At larger magnitude AC fields, the non-linear distortions become significant. Finally, these devices, since they are diodes, are polarized. That is, they only operate as a capacitor in one direction of the DC voltage bias.

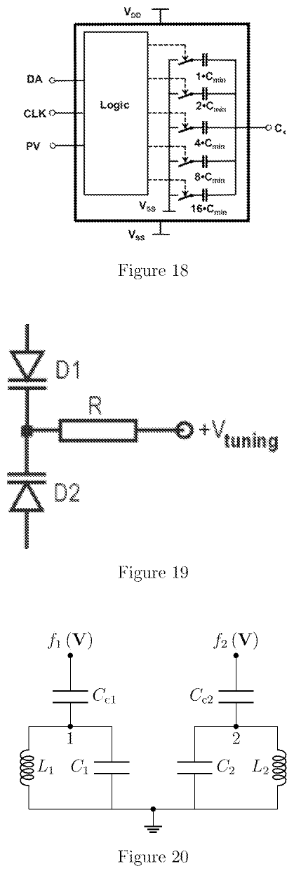

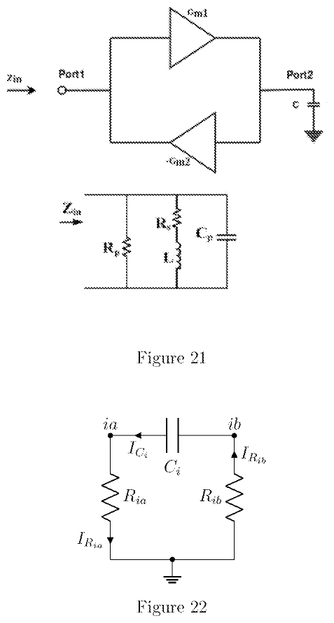

FIG. 19 shows a possible approach for constructing a tunable capacitor based on varicaps. Here, two varicaps are oriented in opposite directions, with an external source applying a voltage between the two varicaps. This approach can allow one to control the overall capacitance with an external voltage, such as a voltage signal from a digital device.

### 8.2 Constructions for Bipolar Coupling Capacitors

An arbitrary target covariance will have some elements that are negative, representing a negative correlation between variables. Bipolar (positive and negative) capacitive coupling enables expression of these elements in the hardware capacitance matrix.

### 8.2.1 Transformer Method

As discussed above with respect to FIG. 11, the negative coupling between elements can be implemented using a tunable capacitor connected to a transformer. The tunable capacitor sets the magnitude of the coupling while the transformer changes the sign. The transformer is wound such that it has the effect of negating the sign of the voltage from one side to the other, thus implementing effective negative capacitive coupling. In addition, a switch that can toggle between the transformer or a wire going to the neighboring cell, is placed between the capacitor and the transformer in order to turn the negative coupling on or off.

### 8.2.2 Hybrid Digital-Analog Method

An alternative method of achieving bipolar coupling is the hybrid digital-analog, pictured in FIG. 20. In this method, the hardware has uncoupled unit cells, each equipped with a way to measure their voltage and capacitively coupled to an arbitrary voltage source. This voltage source can be controlled to supply a voltage, ƒᵢ(V), on cell i that depends on the voltage of other unit cells, V=(v₁, v₂, . . . , v_{N-1}, v_{N}). This applied voltage can be negated digitally, thus effectively implementing negative coupling.

### 8.3 Tunable Constructions for Inductors

Real inductors have the drawback of taking up a large amount of space on-chip. Thus, having an alternative circuit element that behaves like inductor could be helpful, to reduce the area used on-chip.

Active inductors can be employed. For example, FIG. 21 shows a circuit diagram for an active inductor based on a gyrator. Here, two Gm cells and a capacitor provide a transfer function that mimics the behavior of inductors within a given frequency range. The overall inductance can be tuned by modifying the capacitance of the capacitor.

There are some limitations to this active inductor approach. This includes limited frequency range, low quality factor, increased power consumption, and nonlinearity. Nevertheless, this circuit can be useful for reducing the on-chip area for the inductor.

### 9 Strategies for Removing Inductors

### 9.1 Introduction

As mentioned above, our analog computational primitive for Gaussian sampling (and others) involves encoding variables of interest to an application onto the degrees of freedom of circuit unit cells. The correlations between the variables of interest can be encoded through capacitive coupling of the unit cells. However, as discussed above in section 8.2, simple capacitive coupling does not lend itself well to encoding both negative and positive, or bipolar, correlations.

One way to circumvent this problem is to use a transformer in series with the capacitor wired in such a way as to negate the voltage when one wants to have coupling of opposite sign to pure capacitive coupling. This solution, however has the downside of using two inductors per coupling element. Additionally, in an all-to-all connected graph of unit cells, the number of coupling elements grows as the number of unit cells, d, squared, d². This is a significant problem since inductors take up a large physical area when putting them on silicon chips, thus limiting the number of unit cells per chip.

To address the this problem, we use a unit-cell architecture based on an RCR circuit, with the degree of freedom of interest being the voltage difference across the capacitor. The bipolar coupling can then be done through a scheme of “parallel” and “cross” connections of a pair of coupling capacitors. This device can be used as a sampling processor following a Langevin Monte Carlo protocol (see Section 19 below).

### 9.2 Unit Cell

The proposal for a unit-cell circuit is shown in FIG. 22.

Doing an analysis of this circuit using the Kirchhoff current law leads to the following equations describing the currents in each branch:

I_{C}_{ᵢ}=I_{R}_{ᵢₐ}, (22)

I_{C}_{ᵢ}=I_{R}_{_{ib}}. (23)

Taking the sum of these equations gives

2I_{C}_{ᵢ}=I_{R}_{ᵢₐ}+I_{R}_{_{ib}}, (24)

and the difference gives

0=I_{R}_{ᵢₐ}−I_{R}_{_{ib}}. (25)

Equation 24 can be expanded in terms of the node voltages in the following way

$$2 {C}_{i} ( {\dot{V}}_{i b} - {\dot{V}}_{i a} ) = \frac{1}{{R}_{i a}} {V}_{ia} - \frac{1}{{R}_{i b}} {V}_{i b} , \qquad ( 26 )$$

and equation 25 can be similarly expanded as

$$0 = \frac{1}{{R}_{i a}} {V}_{ia} + \frac{1}{{R}_{i b}} {V}_{i b} . \qquad ( 27 )$$

To simplify the equations, we define a new set of variables

$${V}_{C i}^{-} = {V}_{i b} - {V}_{ia} , \qquad ( 28 )$$

$${V}_{C i}^{+} = {V}_{i b} + {V}_{ia} , \qquad ( 29 )$$

and their time derivatives. Now, equation 26 becomes

$$2 {C}_{i} {\dot{V}}_{C i}^{-} = \frac{1}{{R}_{i a}} ( {V}_{i b} - {V}_{C i}^{-} ) - \frac{1}{{R}_{i b}} ( {V}_{C i}^{-} + {V}_{ia} ) , \qquad ( 30 )$$

and equation 27 becomes

$$0 = \frac{1}{{R}_{i a}} ( {V}_{i b} - {V}_{Ci}^{-} ) + \frac{1}{{R}_{i b}} ( {V}_{Ci}^{-} + {V}_{ia} ) , \qquad ( 31 )$$

To characterize the asymmetry between the resistances in the unit cell, let us define the asymmetry parameter, αᵢ, as

$${α}_{i} ≡ \frac{{R}_{i a} - {R}_{i b}}{{R}_{i a} + {R}_{i b}} , \qquad ( 32 )$$

and the sum of unit-cell resistances as Rᵢ≡Rᵢₐ+R_{ib}. This asymmetry parameter is defined in the range on −1<αᵢ<1 and, in practice, can be kept as close to zero as possible.

Then, equation 30 becomes:

$${C}_{i} {\dot{V}}_{C i}^{-} = - \frac{1}{{R}_{i}} [ \frac{{V}_{Ci}^{-} + {α}_{i} ( {V}_{Ci}^{+} )}{1 - {α}_{i}^{2}} ] , \qquad ( 33 )$$

and equation 31 becomes

$${V}_{Ci}^{+} = - {α}_{i} {V}_{Ci}^{-} . \qquad ( 34 )$$

Finally, replacing Equation 34 in Equation 33 yields

$${C}_{i} {\dot{V}}_{Ci}^{-} = - \frac{{V}_{Ci}^{-}}{{R}_{i}} . \qquad ( 35 )$$

The dynamics of this unit cell can be simulated by one degree of freedom,

$${V}_{Ci}^{-} ,$$

and that these dynamics are insensitive to the asymmetry in the resistances, αᵢ.

### 9.3 Coupling-Cell

Bipolar capacitive coupling between unit cells of the type described in Section 9.2 is described below. This circuit contains two switches that are operated such that there are only two possible configurations, one for positive coupling and one for negative coupling.

### 9.3.1 Negative Coupling

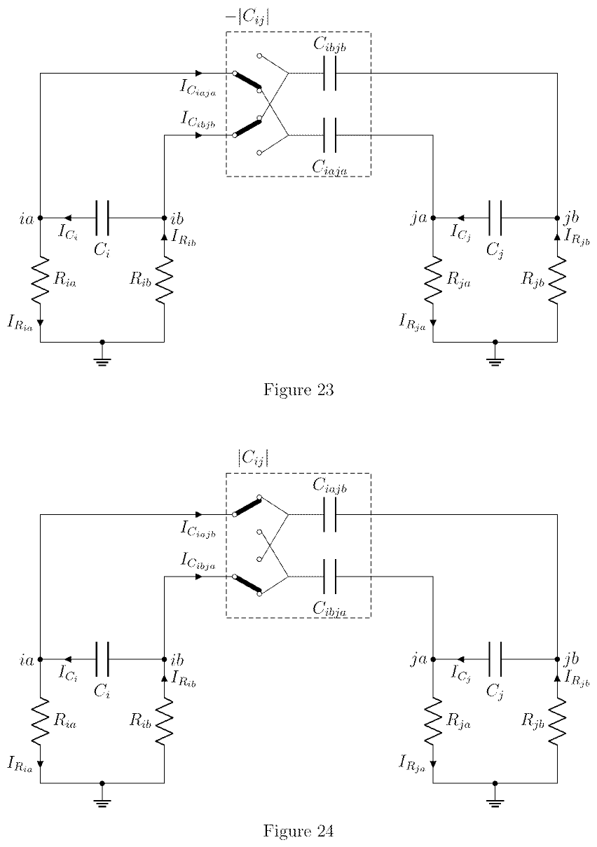

In the first case, consider when the effective coupling is negative and the capacitive coupling is between similar nodes of the unit cells, e.g., node ia to node ja, node ib to node jb. The circuit diagram is shown in FIG. 23. Doing an analysis of this circuit using the Kirchhoff current law leads to the following equations describing the currents in each branch for cell i:

I_{C}_{ᵢ}=I_{R}_{ᵢₐ}+I_{C}_{ᵢₐⱼₐ}, (36)

I_{C}_{ᵢ}=I_{R}_{_{ib}}−I_{C}_{_{ibjb}}, (37)

and for cell j

I_{C}_{ⱼ}=I_{R}_{ⱼₐ}−I_{C}_{ᵢₐⱼₐ}, (38)

I_{C}_{ⱼ}=I_{R}_{_{jb}}+I_{C}_{_{ibjb}}. (39)

Following the analysis from the unit cell, we take the sum and difference of the current equations for cell i

2I_{C}_{ᵢ}=I_{R}_{ᵢₐ}+I_{C}_{ᵢₐⱼₐ}+I_{R}_{_{ib}}−I_{C}_{_{ibjb}}, (40)

0=I_{R}_{ᵢₐ}+I_{C}_{ᵢₐⱼₐ}−I_{R}_{_{ib}}+I_{C}_{_{ibjb}}, (41)

and for cell j

2I_{C}_{ⱼ}=I_{R}_{ⱼₐ}−I_{C}_{ᵢₐⱼₐ}+I_{R}_{_{jb}}+I_{C}_{_{ibjb}}, (42)

0=I_{R}_{ⱼₐ}−I_{C}_{ᵢₐⱼₐ}−I_{R}_{_{jb}}−I_{C}_{_{ibjb}}. (43)

We can expand these equations in terms of voltages. For cell i, we get

$$2 {C}_{i} {\dot{V}}_{C i}^{-} = \frac{{C}_{i j}}{2} [ {\dot{V}}_{C j}^{-} - {\dot{V}}_{C i}^{-} + {β}_{i j} ( {\dot{V}}_{C i}^{+} - {\dot{V}}_{C j}^{+} ) ] - \frac{2}{{R}_{i} ( 1 - {α}_{i}^{2} )} ( {V}_{C i}^{-} + {α}_{i} {V}_{C i}^{+} ) , \qquad ( 44 )$$

$$0 = \frac{{C}_{i j}}{2} [ {\dot{V}}_{C i}^{+} - {\dot{V}}_{C j}^{+} + {β}_{i j} ( {\dot{V}}_{C j}^{-} - {\dot{V}}_{C i}^{-} ) ] + \frac{2}{{R}_{i} ( 1 - {α}_{i}^{2} )} ( {V}_{C i}^{+} + {α}_{i} {V}_{Ci}^{-} ) , \qquad ( 45 )$$

and for cell j we get

$$2 {C}_{j} {\dot{V}}_{Cj}^{-} = - \frac{{C}_{i j}}{2} [ {\dot{V}}_{C j}^{-} - {\dot{V}}_{C i}^{-} + {β}_{i j} ( {\dot{V}}_{C i}^{+} - {\dot{V}}_{C j}^{+} ) ] - \frac{2}{{R}_{j} ( 1 - {α}_{j}^{2} )} ( {V}_{C j}^{-} + {α}_{j} {V}_{C j}^{+} ) , \qquad ( 46 )$$

$$0 = - \frac{{C}_{i j}}{2} [ {\dot{V}}_{C i}^{+} - {\dot{V}}_{C j}^{+} + {β}_{i j} ( {\dot{V}}_{C j}^{-} - {\dot{V}}_{C i}^{-} ) ] + \frac{2}{{R}_{j} ( 1 - {α}^{2} )} ( {V}_{C j}^{+} + {α}_{j} {V}_{C j}^{-} ) . \qquad ( 47 )$$

In the above expansion, we have used the coordinates defined in 28 for each cell. We have also used the resistance asymmetry parameter from equation 32 and a new capacitance asymmetry parameter defined as

$${β}_{i j} ≡ \frac{{C}_{i a j a} - {C}_{i b j b}}{{C}_{i a j a} + {C}_{i b j b}} , \qquad ( 48 )$$

and the sum of the coupling capacitances as Cᵢⱼ=Cᵢₐⱼₐ+C_{ibjb}.

### 9.3.2 The Symmetric Case

In the symmetric case, where αᵢ=αⱼ=0 and β=0, we have the following set of equations for cell i

$$2 {C}_{i} {\dot{V}}_{Ci}^{-} = \frac{{C}_{i j}}{2} ( {\dot{V}}_{C j}^{-} - {\dot{V}}_{Ci}^{-} ) - \frac{2}{{R}_{i}} {V}_{C i}^{-} , \qquad ( 49 )$$

$$0 = \frac{{C}_{i j}}{2} ( {\dot{V}}_{C i}^{+} - {\dot{V}}_{C j}^{+} ) + \frac{2}{{R}_{i}} {V}_{C i}^{+} , \qquad ( 50 )$$

and for cell j

$$2 {C}_{j} {\dot{V}}_{Cj}^{-} = - \frac{{C}_{i j}}{2} ( {\dot{V}}_{C j}^{-} - {\dot{V}}_{Ci}^{-} ) - \frac{2}{{R}_{i}} {V}_{Cj}^{-} , \qquad ( 51 )$$

$$0 = - \frac{{C}_{i j}}{2} ( {\dot{V}}_{C i}^{+} - {\dot{V}}_{C j}^{+} ) + \frac{2}{{R}_{i}} {V}_{Cj}^{+} , \qquad ( 52 )$$

### 9.3.3 Positive Coupling

In the second case, consider when the effective coupling is positive and the capacitive coupling is between dissimilar nodes of the unit cells, e.g., node ia to node jb, node ib to node ja. The circuit diagram for this case is shown in FIG. 24. Following the analysis in section 9.3.1 yields the following equations for the sum and difference of the current equations in cell ¿

$$2 {C}_{i} {\dot{V}}_{C i}^{-} = \frac{{C}_{i j}}{2} [ - {\dot{V}}_{C j}^{-} - {\dot{V}}_{C i}^{-} + {β}_{i j} ( {\dot{V}}_{C i}^{+} - {\dot{V}}_{C j}^{+} ) ] - \frac{2}{{R}_{i} ( 1 - {α}_{i}^{2} )} ( {V}_{C i}^{-} + {α}_{i} {V}_{C i}^{+} ) , \qquad ( 53 )$$

$$0 = \frac{{C}_{i j}}{2} [ {\dot{V}}_{C i}^{+} - {\dot{V}}_{C j}^{+} + {β}_{i j} ( - {\dot{V}}_{C j}^{-} - {\dot{V}}_{Ci}^{-} ) ] + \frac{2}{{R}_{i} ( 1 - {α}_{i}^{2} )} ( {V}_{C i}^{+} + {α}_{i} {V}_{C i}^{-} ) , \qquad ( 54 )$$

and for cell j we get

$$2 {C}_{j} {\dot{V}}_{C i}^{-} = - \frac{{C}_{i j}}{2} [ - {\dot{V}}_{C j}^{-} - {\dot{V}}_{C i}^{-} + {β}_{i j} ( {\dot{V}}_{C i}^{+} - {\dot{V}}_{C j}^{+} ) ] - \frac{2}{{R}_{i} ( 1 - {α}_{i}^{2} )} ( {V}_{Cj}^{-} + {α}_{i} {V}_{Cj}^{+} ) , \qquad ( 55 )$$

$$0 = - \frac{{C}_{i j}}{2} [ {\dot{V}}_{C i}^{+} - {\dot{V}}_{C j}^{+} + {β}_{i j} ( - {\dot{V}}_{C j}^{-} - {\dot{V}}_{Ci}^{-} ) ] + \frac{2}{{R}_{i} ( 1 - {α}_{i}^{2} )} ( {V}_{Cj}^{+} + {α}_{i} {V}_{Cj}^{-} ) . \qquad ( 56 )$$

The equations are very similar to equations 44-47 with a change of sign in the coupling term between the degrees of freedom of interests,

$${V}_{C i}^{-} and {V}_{C j}^{-} .$$

### 9.3.4 The Symmetric Case

In the symmetric case, where αᵢ=αⱼ=0 and β=0, we have the following set of equations for cell

$$2 {C}_{i} {\dot{V}}_{C i}^{-} = \frac{{C}_{i j}}{2} ( - {\dot{V}}_{C j}^{-} - {\dot{V}}_{C i}^{-} ) - \frac{2}{{R}_{i}} {V}_{C i}^{-} , \qquad ( 57 )$$

$$0 = \frac{{C}_{i j}}{2} ( {\dot{V}}_{C i}^{+} - {\dot{V}}_{C j}^{+} ) + \frac{2}{{R}_{i}} {V}_{C i}^{+} , \qquad ( 58 )$$

$$2 {C}_{j} {\dot{V}}_{C j}^{-} = - \frac{{C}_{i j}}{2} ( - {\dot{V}}_{C j}^{-} - {\dot{V}}_{C i}^{-} ) - \frac{2}{{R}_{j}} {V}_{C j}^{-} , \qquad ( 59 )$$

$$0 = - \frac{{C}_{i j}}{2} ( {\dot{V}}_{C i}^{+} - {V}_{C j}^{+} ) + \frac{2}{{R}_{j}} {V}_{C j}^{+} . \qquad ( 60 )$$

### 9.4 Discussion

The derivations above show that this scheme does indeed offer bipolar capacitive coupling between two degrees of freedom,

$${V}_{C i}^{-} and {V}_{C j}^{-} ,$$

by changing the position of the switches in the coupling-cell. Additionally, in the case of ideal symmetry between the components of the circuit, we have complete decoupling of the unwanted degrees of freedom,

$${V}_{C i}^{+} and {V}_{Cj}^{+} .$$

### 10 Strategies for Hardware Connectivity

### 10.1 Local Connectivity Versus Global Connectivity

As discussed above, an inventive device can be used to sample from Gaussian probability distributions. Conveniently, the Gaussian is fully characterized by its first two moments, the mean and the covariance. As described in section 3.6, we can incorporate the mean as a constant offset to each oscillator variable in post-processing. However, the covariance matrix should be incorporated in the dynamics of the system, which is represented by the capacitance matrix in our physical device. Given a target Gaussian probability distribution of d variables, a d×d capacitance matrix can be used to fully express the target Gaussian probability distribution's covariance matrix, which represents the degree of correlation between any two variables. This matrix is composed of the d self-capacitances on the diagonal and all the two-oscillator coupling capacitances on the off-diagonals.

Building systems of coupled oscillators involves deciding on the degree of connectivity that is feasible to implement. The degree of connectivity means how many connections any oscillator in the system has to other oscillators. In the previous sections the system of coupled oscillators was assumed to be all-to-all connected. This is the highest degree of connectivity one can achieve for a given coupling scheme: all oscillators are connected to all other oscillators.

In this coupling scheme, the hardware has order d² connections between oscillators, (dimension of the problem). This can become a space bottleneck in larger systems. This problem cab be addressed by reducing the connectivity degree to have only local couplings between a set number of oscillators. The degree of connectivity can be defined by a given oscillator's maximum number of connections. For example, a simple connectivity scheme is a connectivity architecture of degree 2, where the oscillators are only coupled to two of their nearest neighbors.

However, with a connectivity less than all-to-all (full), one runs into the problem of a mismatch between the target covariance matrix and the physically implemented capacitance matrix. As an example, let us look at a system with d=5 units. The target covariance matrix for this example is:

$${Σ}_{target} = [ \begin{matrix}{σ}_{11} & {σ}_{12} & {σ}_{13} & {σ}_{14} & {σ}_{15} \\ {σ}_{12} & {σ}_{22} & {σ}_{23} & {σ}_{24} & {σ}_{25} \\ {σ}_{13} & {σ}_{23} & {σ}_{33} & {σ}_{34} & {σ}_{35} \\ {σ}_{14} & {σ}_{24} & {σ}_{34} & {σ}_{44} & {σ}_{45} \\ {σ}_{15} & {σ}_{25} & {σ}_{35} & {σ}_{45} & {σ}_{55}\end{matrix} ] . \qquad ( 61 )$$

If we use a device with all-to-all connectivity, we have the following capacitance matrix

$${C}_{Physical} = [ \begin{matrix}{C}_{11} & {C}_{12} & {C}_{13} & {C}_{14} & {C}_{15} \\ {C}_{12} & {C}_{22} & {C}_{23} & {C}_{24} & {C}_{25} \\ {C}_{13} & {C}_{23} & {C}_{33} & {C}_{34} & {C}_{35} \\ {C}_{14} & {C}_{24} & {C}_{43} & {C}_{44} & {C}_{45} \\ {C}_{15} & {C}_{25} & {C}_{35} & {C}_{45} & {C}_{55}\end{matrix} ] , \qquad ( 62 )$$

which fully describes the target covariance matrix. When a device with connectivity k=2 is used, however, the following capacitance matrix is obtained

$${C}_{Physical} = [ \begin{matrix}{C}_{11} & {C}_{12} & 0 & 0 & 0 \\ {C}_{12} & {C}_{22} & {C}_{23} & 0 & 0 \\ 0 & {C}_{23} & {C}_{33} & {C}_{34} & 0 \\ 0 & 0 & {C}_{43} & {C}_{44} & {C}_{45} \\ 0 & 0 & 0 & {C}_{45} & {C}_{55}\end{matrix} ] , \qquad ( 63 )$$

which does not fully describe the target covariance matrix. Let us define a useful quantity for further discussions on connectivity: the diagonal distance. The diagonal distance measures the distance between a matrix element and the main diagonal of the matrix and is defined as

$$k = \vert i - j \vert , \qquad ( 64 )$$

where i and j are the column and row index of the matrix element, respectively. In the above example of only nearest neighbor coupling, we have k=1. Extending this concept to arbitrary dimensions and connectivity is straightforward.

If hardware has limited connectivity, then the effect of the covariance mismatch on the behavior of the overall process should be quantified.

10.2 Hardware with Local Connectivity

### 10.2.1 Overview

If a specific application is targeted, then the properties of the corresponding covariance matrix can be directly mimicked by the hardware. For example, hardware with connectivity k can be designed for specific classes of applications that have banded covariance matrices. Additionally, the accept/reject step in the process can overcome some amount of mismatch between the target covariance connectivity and the hardware connectivity. For example, if the target covariance matrix is not quite banded, but the matrix elements decay exponentially with distance from the diagonal, the process run on banded k-local hardware should still be able to draw quality samples.

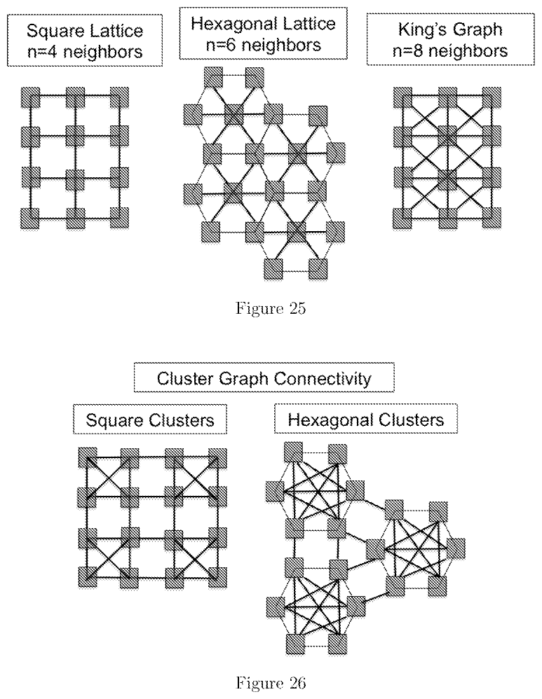

FIGS. 25 and 26 show several possible local connectivity hardware architectures that could be implemented for appropriate classes of distributions. Implementing these strategies in hardware enables great savings in terms of on-chip space and complexity, thus unlocking the possibility for larger scale systems, while efficiently sampling from a certain family of covariance matrix.

### 10.2.2 Uniform Lattices

FIG. 25 shows three different examples of uniform lattices: a square lattice, a hexagonal lattice, and a King's graph. For each unit cell, the number of nearest neighbors (i.e., the number of direct connections) is n=4, n=6, and n=8 respectively for these lattices.

### 10.2.3 Cluster Graphs

FIG. 26 shows an alternative method for achieving local connectivity based on the notion of cluster graphs. Here, the unit cells are grouped into clusters of some size, n_{c}. For example, n_{c}=4 for a square cluster and n_{c}=6 for a hexagonal cluster. Within a cluster, there is full connectivity, meaning that each unit cell is connected to every other unit cell within the cluster. Between different clusters there is only sparse connectivity as shown in FIG. 26. For square and hexagonal clusters, the number of nearest neighbors is respectively n=5 and n=7. Other types of clusters could be considered, such as octagonal or other shapes.

Cluster graph connectivity could have application, e.g., for image processing. This is because the covariance matrices for image processing often have a block circulant structure. The blocks in this block circulant structure could correspond to the clusters in the cluster graph connectivity. By identifying the fully connected blocks in the covariance matrix with the fully connected clusters in the hardware connectivity, one can match the hardware connectivity to the structure of the covariance matrix (e.g., for image processing).

10.3 Hardware with Semi-Local or Global Connectivity

The local connectivity described above has the property that the number of nearest neighbors n does not depend on the dimension D. Let us now consider connectivity structures where n grows with D.

### 10.3.1 Semi-Local Connectivity

At one extreme, global connectivity of the hardware is challenging to achieve in practice. At the other extreme, local connectivity can restrict the speedup achievable with analog hardware, relative to digital methods. An intermediate connectivity that is neither fully global nor fully local can be an attractive alternative.

We can refer to this intermediate connectivity to be semi-local, which means that the number of nearest neighbors n grows as some monotonic function of D, and yet the connectivity is not fully global.

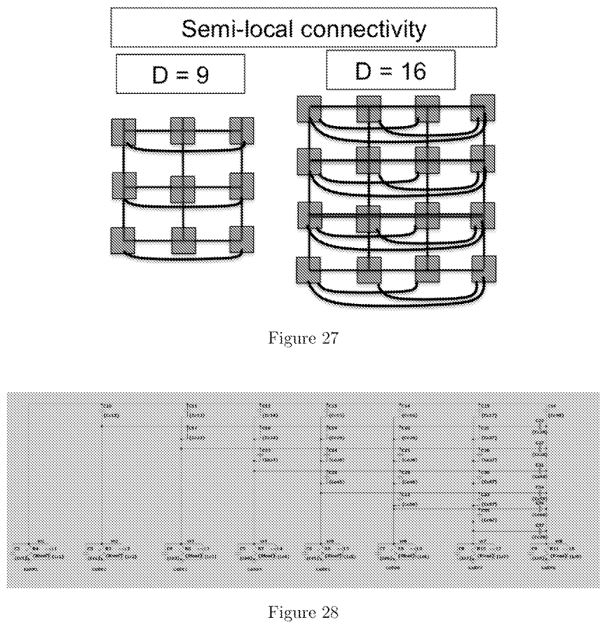

FIG. 27 shows a semi-local connectivity among unit cells organized on a square lattice. Each unit cell is fully connected to other unit cells in the same row, with sparse connections between the rows of unit cells. In this scheme, the total number of connections grows asymptotically as D\sqrt{D}, which is neither linear nor quadratic in D. The number of nearest neighbors n grows asymptotically as \sqrt{D}.

This strategy essentially corresponds to the cluster graph connectivity (discussed above) where each cluster is a row and the cluster size grows with \sqrt{D}. More generally, one could consider other geometries for the clusters, such as rectangular or square clusters, where the cluster size grows as some function of D (e.g., as \sqrt{D} or even linearly in D).

### 10.3.2 Full Connectivity

Finally, we consider the extreme case of global connectivity, also known as full connectivity. Here, the total number of connections grows asymptotically as D², with the number of nearest neighbors n growing as D.

Hardware with full connectivity can be designed for applications that have arbitrarily dense covariance matrices. FIG. 28 shows one possible layout of eight fully connected oscillators following the description in Section 4.

Full connectivity designs have the most expressibility, and also can allow for the largest possible speedups over digital hardware. However, they have a high cost in terms of physical space and complexity on-chip.

The method for achieving bipolar coupling outlined in section 8.2.2 can be used to effectively build fully connected hardware with only order D connections.

### 11 Dealing with Hardware Device Imperfections

### 11.1 Thermodynamic Error Correction

One of the advantages of using thermodynamic hardware to produce samples for HMC is the native error resilience of this approach. This is due to the presence of the Metropolis-Hastings (MH) step where the sample is accepted or rejected based on the energy difference of the proposed sample with the previous sample. The inclusion of this step in conjunction with analog hardware that proposes the sample can be thought of as thermodynamic error correction. The accept/reject step serves to filter out any erroneous samples that are proposed due to hardware limitations such as capacitor imprecision or connectivity constraints as will be discussed below. Therefore, this naturally occurring form of error correction is likely to make the thermodynamic approaches to HMC resilient to the presence of imperfections.

The MH step is typically performed on digital hardware in our methodology. This allows whatever errors that accumulated during the analog dynamics to be corrected. Thus, the combination of the analog-digital interface (during the MH step) leads to the correction of errors.

In some sense, the MH step serves to keep the analog dynamics on the right track. By this, we mean that the analog dynamics can stray away from the desired trajectory due to device imperfections (like imprecision and noise), but the MH step serves to push the position-momentum coordinates back towards the desired trajectory.

One consideration when investigating this approach to thermodynamic error correction is the behavior of the acceptance rate (also known as the success rate or acceptance probability), which reflects the quality of samples that are being proposed. The following subsections present some deeper investigations into this quantity highlighting its behavior with capacitor imprecision, tolerance, and range and the device connectivity constraints.

11.2 Dealing with Capacitor Imprecision, Tolerance, and Range

As discussed above, the accept/reject step in the process serves as a form of error correction for the hardware. If the distribution described by the physical hardware deviates from the target distribution, the samples drawn from this hardware distribution will be rejected and will not corrupt the quality of the samples overall. This leads to a trade-off between the overall time to draw the desired samples and the accuracy or precision of the hardware. This trade-off can be quantified by calculating the average acceptance rate of the process using imperfect hardware. This error correction means that the hardware can be constructed using a more conservative level of tunability and still be able to reliably represent useful Gaussian distributions.

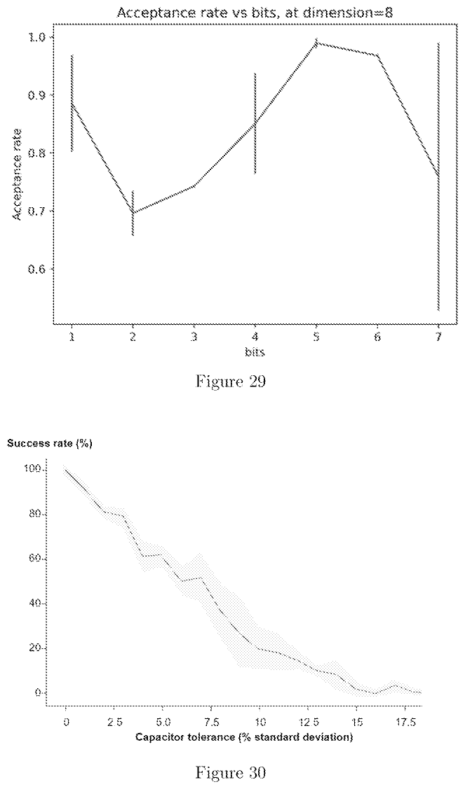

The device can then be designed with this concept in mind. The number of bits of precision as well as the range of tunability of capacitors and inductors can be chosen by optimizing the acceptance rate and the constraints of the hardware architecture. For example, FIG. 29 shows the effect of capacitor imprecision on the acceptance rate, based on numerical simulations. Because the acceptance rate is only a weak function of imprecision, one can use capacitors represented by a small number of bits (e.g., 2 or 3 bits) in the hardware, while still maintaining good performance.

An additional consideration during the design stage is the tolerances of the components. This refers to the possible deviation of the values of the components from their nominal values. These added deviations can also be corrected by the accept/reject step, see FIG. 30. However, these tolerances can be accounted for by a full characterization of the hardware before putting it into service.

11.3 Dealing with Limited Connectivity

Let us consider the case of restricted connectivity, such as the local connectivity discussed in Sec. 10.2. Limited connectivity in the device leads to several consequences when applying our hardware to HMC. In particular, as discussed below, the expected improvement over digital methods should be directly related to the connectivity of the device for some applications, such as producing samples from a multivariate Gaussian.

As discussed above the nature of the accept/reject step again acts to ensure that the samples that are accepted represent the desired distribution. One metric to consider is the acceptance probability and to be confident that this probability does not significantly decrease.

Another approach to mitigate the possible negative effects of limited hardware connectivity can be potentially mitigated by classical preprocessing, which is discussed below for the case of HMC for multivariate Gaussian sampling.

### 11.3.1 Classical Preprocessing for Local Connectivity Constraints

In order to increase the speedup that results from the hardware even with restricted connectivity we can develop methods that aim to increase the magnitude of the covariance values that are within a given bandwidth. We can use permutation matrices to reorder the coupled cells and search for an approximately optimal ordering that maximises weight for a given bandwidth.

One such method to achieve this permutation uses the absolute values of the covariance matrix to construct the Laplacian of a weighted graph. The second smallest eigenvector of the Laplacian defines the Fiedler vector. The ordering of the elements of this vector contains the approximate best order in which to label each of the unit cells.

Therefore, to obtain the best mapping of the covariance matrix values to the hardware, we calculate the second smallest eigenvector of the Laplacian constructed from the covariance matrix. The complexity of this operation depends on the properties of the matrix. In the worse case, this can be calculated up to error ϵ in the eigenvalue in ((d²) operations. For covariance matrices which are sparse, this calculation should be cheaper.

Another approach to achieve the same purpose is direct truncation, bringing the dense matrix to sparse form, followed by application of the Cuthill-Mckee process, which brings a sparse matrix to banded form. Direct truncation can be applied during the construction of the covariance matrix and setting some elements to 0 if they are smaller than some cutoff value. Therefore, this can be completed during the calculation of the matrix itself. The Cuthill-Mckee process then scales according to how many non-zero elements are left in the sparse matrix O(n_{nz}), which should be smaller than O(d²). The application of simple truncation followed by Cuthill-Mckee can therefore take a dense covariance matrix to a banded form in O(n_{nz}) steps. The number of non-zero elements will depend on the truncation, which is a parameter to be set by the user.

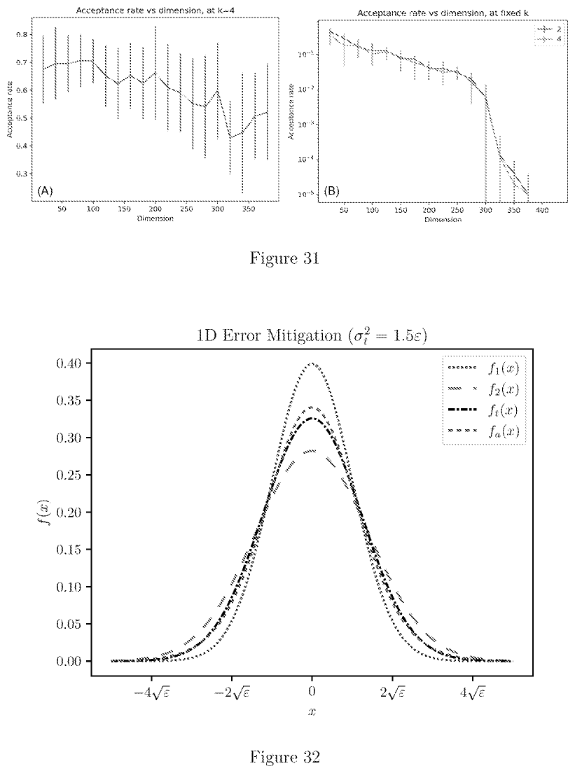

For the specific example of multivariate Gaussian sampling for a random covariance matrix, where the elements decay exponentially with distance from the diagonal, FIG. 31A shows that the acceptance ratio is roughly constant with increasing dimension. For the case where the covariance matrix is a dense random matrix, FIG. 31B shows an exponential decay of the acceptance probability with dimension when attempting to produce samples from an approximation of the true covariance matrix with bandwidth k. These two examples highlight the different expected performance for the hardware applied to different types of covariance matrices. Moreover, they also highlight the potential benefits of preprocessing the covariance matrix (as described above) in order to bring the larger elements closer to the diagonal and potentially avoid exponential scaling.

### 12 Thermodynamic Error Mitigation Method

Error mitigation can reduce the impact of errors associated with our thermodynamic sampling device. Specifically, this error mitigation method is targeting imprecision errors errors associated with the imprecision of analog hardware components. The acronym for our method is THERMIES (THermodynamic ERror Mitigation via Imprecise Ensemble Sampling).

### 12.1 Univariate Protocol

We begin with an example in the one-dimensional case in order to explain the essential concept, and then examine the more general case in a supporting document (see supporting document: Error Mitigation for Thermodynamic Sampling Hardware). Imagine a Gaussian sampling device which is capable of realizing a random variable X whose probability density function is

$${f}_{m} ( x ) = \frac{1}{\sqrt{2 π ε m}} exp ( - \frac{1}{2} \frac{{x}^{2}}{ε m} ) , m ∈ \{ 1 , 2 … \} . \qquad ( 65 )$$

That is, the device can sample a mean-zero normally distributed random variable whose variance is a multiple of ε. The mean-zero constraint is not restrictive because a bias may be added after sampling with little computational overhead, and the discretization of variance is a consequence of the digital encoding of parameters which tune the device.

In practice, the samples may be from a distribution having a variance which is not a multiple of ε. For example, suppose we would like to sample the normal distribution [symbol] [0, 1.5ε] (here and in what follows, [symbol] [a, b] denotes a normal distribution with mean a and (co) variance b). This distribution is illustrated in FIG. 32.

In order to (approximately) sample this distribution, we carry out the following procedure, which is the basis of the Thermies method:

Univariate Thermies Protocol

| | |
|---|---|
| 1. | Sample a Bernoulli random variable |
| | B ∈ {0, 1} with Pr(B = 0) = ½ and |
| | Pr(B = 1) = ½. |
| 2. | If the outcome is B = 0, sample the |
| | distribution [symbol] [0, ε], and if the outcome |
| | is B = 1, sample the distribution [symbol] [0, 2ε]. |
| 3. | Record the result as a realization of |
| | random variable X, without storing the |
| | outcome of the Bernoulli trial. |

The probability density function of the random variable X is then

$${f}_{a} ( x ) = \frac{1}{2} {f}_{1} ( x ) + \frac{1}{2} {f}_{2} ( x ) , \qquad ( 66 )$$

where the subscript a signifies that this distribution is an approximation to a target distribution ƒₜ. As the distributions ƒ₁ and ƒ₂ are both zero mean, ƒₐ is zero mean as well. Moreover, the variance of ƒₐ is

$$\begin{matrix}{σ}_{a}^{2} = {\int }_{- ∞}^{∞} d x {f}_{a} ( x ) {x}^{2} ( 67 ) \\ = \frac{1}{2} {\int }_{- ∞}^{∞} d x {f}_{1} ( x ) {x}^{2} + \frac{1}{2} {\int }_{- ∞}^{∞} d x {f}_{2} ( x ) {x}^{2} ( 68 ) \\ = \frac{1}{2} ( ε ) + \frac{1}{2} ( 2 ε ) = 1.5 ε ( 69 )\end{matrix} .$$

For this example, the ƒₐ distribution is plotted in FIG. 32 as the dashed line, which matches the target distribution better than either ƒ₁ and ƒ₂ do.

If we instead form a mixture ƒₐ=(1−w)ƒₘ+wƒₘ+1 with w∈[0, 1], the variance of ƒₐ is

$${σ}_{a}^{2} = ( m + w ) ε , \qquad ( 70 )$$

which means that we can choose w and m to obtain arbitrary

$${σ}_{a}^{2} \geq ε ,$$

so we can ensure that

$${σ}_{a}^{2} = {σ}_{t}^{2} ,$$

which we refer to as variance-matching. Obtaining an approximating distribution with

$${σ}_{a}^{2} < ε$$

is problematic, an issue revisited below.

In the univariate case, the imprecision problem could be avoided by rescaling the random variable to have a realizable variance. That is, we can define a new random variable Y∝X such that Y~ [symbol] [0, mε] for some m∈{1, 2, . . . }, so no error-mitigation is necessary. This may be challenging or impossible in the multivariate case, which is why the error-mitigation method is useful, and we now develop the multivariate generalization of the Thermies method.

### 12.2 Imprecision Dependence

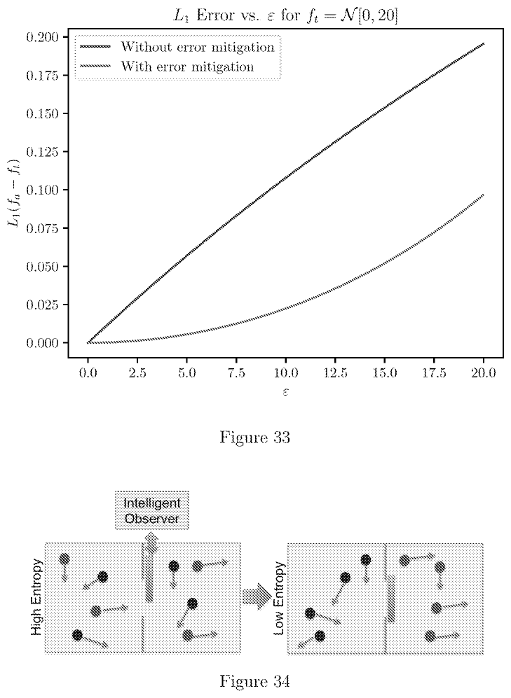

It is desirable for the quality of samples to be insensitive to the precision of the hardware implementation. Fortunately, the Thermies protocol eliminates the first order dependence of the approximate distribution on ε as ε goes to zero. FIG. 33 shows the L₁ distance between ƒₐ and ƒₜ with and without Thermies error mitigation. While in the error-mitigated case, the slope vanishes at ε=0, evidently the slope does not vanish at ε=0 in the unmitigated case. This numerical result provides evidence that Thermies (or a similar method) reduces or eliminates sensitivity of sample quality to hardware imprecision.

### 13 Extension to Non-Gaussian Distributions

### 13.1 General Strategy

Thusfar, we have described analog hardware for sampling from Gaussian distributions. However, there are many other distributions that could be of interest. Hence, we will now consider strategies for constructing analog hardware that could produce samples from non-Gaussian distributions.

The framework introduced in Section 2.1 applies to any continuous physical system with coordinates {x, p}, potential energy function U(x) and kinetic energy function K(p). For a Gaussian HMC sampler, the quadratic potential may be prescribed as a function of the position coordinate x. However, other potentials (beyond quadratic ones) can be realized, and this is the conceptual basis of extending beyond Gaussian sampling.

The stochastic dynamics of the HMC process ensure that in the long time limit, the position and momentum will be distributed according to a Boltzmann distribution, given in Eq. (2), which is true for any well-behaved choice of potential function U(x). Moreover, the distributions over x and p will be independent, with the marginal distribution over x being proportional to

$$exp ( - \frac{U ( x )}{{k}_{B} T} ) .$$

Thus, one can see that appropriately choosing the potential U(x) allows one to engineer the probability distribution that one draws samples from.

In the case of a quadratic potential, the Boltzmann distribution over position coordinates is a Gaussian distribution, and hence sampling the position x samples from a Gaussian~exp(−U(x)). As noted above, this quadratic potential is the natural physical potential associated with LC oscillator systems. If, however, we can modify the shape of the existing quadratic potential energy function U(x) provided by the LC oscillator circuit, then we can sample from distributions associated with non-quadratic potentials.

In what follows, we provide two approaches for modifying the shape of the potential function:
an approach based on the thermodynamic concept of Maxwell's demon; and
an approach based on many-body coupling of the LC oscillators.

### 13.2 Overview of Maxwell's Demon Approach

Section 14 describes in detail an approach to sampling from non-Gaussian distributions based on the concept of Maxwell's demon.

Consider a coupled LC oscillator system. The Maxwell's demon is a digital or analog device that applies a state-dependent physical force to the harmonic oscillator system. The force is state-dependent in the sense that it depends on the oscillators' state, e.g., it may depend on the voltage across the capacitor in each unit cell. In practice, the force physically corresponds to a voltage source (or a set of voltage sources) applied to each unit cell.

In short, the voltage source output by the Maxwell's demon device artificially creates a new potential energy function U(x) over the existing position coordinate x of the LC oscillator circuit. This allows the LC oscillator system to evolve according to a new Hamiltonian. As a result, it is possible to program the probability distribution being sampled by choosing U(x) appropriately.

### 13.3 Overview of Many-Body Coupling Approach

Section 16 describes in detail an approach to sampling from non-Gaussian distributions based on engineering a many-body coupling (such as a two-body coupling) of the unit cells.

A multivariate Gaussian distribution can be described by its first two moments, i.e., the mean vector and the covariance matrix. Therefore, distributions with non-trivial higher-order moments (such as third-order moments) are non-Gaussian. Hence, focusing on generating higher-order moments in the distribution makes it possible to move beyond Gaussians.

Within the HMC framework, this corresponds to generating higher-order coupling terms in the Hamiltonian. Two-body couplings are ubiquitous in physical systems, but higher-order couplings (e.g., third-order) are rarer. Hence, these couplings in physical systems should be generated thoughtfully.

At a high level, the reason we achieve two-body couplings in our design of the LC oscillator system is that we use a two-port device (e.g., a capacitor) to couple the unit cells. This suggests that we could replace the two-port device with a three-port device to achieve three-body coupling.

Indeed, we can couple three unit cells using a three-port device. For example, transistors have three ports including a source, drain, and gate. This generates a genuine three-body coupling in the Hamiltonian and hence could generate a third-order moment in the corresponding probability distribution being sampled. Varicaps (also known as varactors) provide an alternative to transistors for this purpose.

More generally, one can chain sets of three-port devices together to obtain an n-port device, where n≥3. This makes it possible to generate genuine n-body couplings between the unit cells, and hence to generate n-order moments in the corresponding probability distribution. This is discussed in detail in Section 16.

### 13.4 Additional Distributions of Interest

### 13.4.1 Univariate Distributions

Here we give some mathematical details about the kinds of probability distributions (beyond Gaussians) that can be sampled.

First, consider univariate distributions for simplicity. Some noteworthy examples include:
exponential distributions;
Gamma distributions;
Laplace distributions;
generalized normal distributions; and
exponential families.

Consider two distributions that are defined only over non-negative numbers, i.e., over the domain x∈[0, ∞), starting with the exponential distribution:

p(x)=β exp(−βx). (71)

Next consider the Gamma distribution, which is a generalization of the exponential distribution:

$$p ( x ) = \frac{{x}^{α - 1} exp ( - β x ) {β}^{α}}{Γ ( α )} . \qquad ( 72 )$$

Here, α>0 is called the shape parameter, β>0 the rate parameter, and Γ(.) the gamma function. The Gamma distribution reduces to the exponential distribution by setting α=1.

The Laplace distribution, unlike the Gamma distribution, has a support which is all of [symbol] . The distribution is given in terms of a “location” parameter μ∈ [symbol] and a scale parameter σ:

$$p ( x ) = \frac{1}{2 σ} exp ( - \frac{\vert x - μ \vert}{σ} ) . \qquad ( 73 )$$

Next, consider the generalized normal distribution, which has the following probability density:

$$p ( x ) = \frac{β}{2 σΓ ( 1 / β )} exp ( - {\vert \frac{x - μ}{σ} \vert}^{β} ) \qquad ( 74 )$$

Choosing β=2 corresponds to the standard Gaussian distribution. Also, choosing β=1 corresponds to the Laplace distribution. Hence, Eq. (74) includes the Gaussian and Laplace distributions as special cases.

These distributions are special cases of the exponential family of distributions. The exponential family can be written as:

p(x|θ)=h(x)exp(η(θ)T(x)−A(θ)) (75)

For example, for the exponential distribution, T(x)=x, η(θ)=−β, h(x)=1, and A(θ)=−log β. Similarly, the other distributions can be recovered from the general formula in Eq. (75).

### 13.4.2 Multivariate Distributions

In general, we can consider multivariate random variables whose higher-order cumulants impact the shape of its distribution in statistically significant ways. For example, if a multivariate random variable has nontrivial third-order cumulants, its probability distribution will be skewed; higher-order cumulants define other features of the distribution's shape. We discuss cumulants in more detail below.

The exponential family discussed above can be extended to the multivariate case as follows:

p(x|s)=h(x)exp(s·t(x)−A(s)) (76)

where h(x) is a scaling constant, s is a vector called the natural parameters, t(x) is called the sufficient statistics, and A(s) is the log partition function.

### 13.4.3 Cumulant Approach to Distributions

In Section 2.1, we discuss a circuit for sampling from a normal distribution. To make progress into sampling from non-Gaussians, we might consider the problem of sampling from distributions that are small perturbations away from Gaussians. What small parameter should we take this perturbative expansion over?

The cumulants of a distribution are defined as

$${κ}_{n} = ( \frac{{d}^{n}}{{dt}^{n}} log 𝔼 [ {e}^{tX} ] {\vert}_{t = 0} . \qquad ( 77 )$$

It turns out that these are closely related to the moments of the distribution. In fact, the cumulants are polynomial functions of the moments, with integer coefficients, and the first two cumulants are simply the mean and variance of the distribution. However, it turns out that cumulants are more useful than the moments of the distribution because normal distributions enjoy the special property that κₙ=0 for n≥3. Therefore, we have an answer for our perturbative expansion parameter: κ≥3.

The formalism for this expansion is known as the Gram-Charlier A series (closely related to the Edgeworth series), which says:

$$p ( x ) = exp [ {\sum }_{r = 3}^{∞} {k}_{r} \frac{{( - D )}^{r}}{r !} ] ϕ ( x ) ; \qquad ( 78 )$$

$$ϕ ( x ) = \frac{1}{\sqrt{2 {πσ}^{2}}} exp [ - \frac{{( x - μ )}^{2}}{2 {σ}^{2}} ] , \qquad ( 79 )$$

where μ and σ² are the mean and variance, respectively, of p(x), and D is the differential operator. For simplicity, assume μ=0 and σ=1. We then expand the exponential and collect like terms. Furthermore, we use the fact that the derivative of the normal distribution is again equal to the normal distribution multiplied by a Hermite polynomial Heₙ to find:

$$p ( x ) = ϕ ( x ) {\sum }_{n = 0}^{∞} \frac{1}{n !} {B}_{n} ( 0 , 0 , 0 , {k}_{3} , … , {k}_{n} ) {He}_{n} ( x ) ,$$

where Bₙ are the Bell polynomials, and Heₙ are the Hermite polynomials. Now, dropping additive constants, the log probability goes as

$$log p ( x ) = - \frac{{x}^{2}}{2} + log ( {\sum }_{n = 0}^{∞} \frac{1}{n !} {B}_{n} ( 0 , 0 , 0 , {k}_{3} , … , {k}_{n} ) {He}_{n} ( x ) ) .$$

To gain an understanding of what this might mean, let us include only the first two correction terms.

$$\begin{matrix}= - \frac{{x}^{2}}{2} + log ( 1 + \frac{{k}_{3}}{6} {He}_{3} ( x ) + \frac{{k}_{4}}{24} {He}_{4} ( x ) ) \\ = - \frac{{x}^{2}}{2} + log ( 1 + \frac{{k}_{3}}{6} ( {x}^{3} - 3 x ) + \frac{{k}_{4}}{24} ( {x}^{4} - 6 {x}^{2} + 3 ) ) .\end{matrix}$$

Here, keeping only the first two corrective terms clearly cannot be valid for all x, since it is possible that the expression inside the log goes negative. However, we are assuming that κ₃ and κ₄ are small anyways, so this x is far enough away that we can ignore this pathology. For a completely rigorous expansion, we might consider the Edgeworth series instead. However, we just proceed by doing a log(1+x)≈x expansion:

$$= - \frac{{x}^{2}}{2} + \frac{{k}_{3}}{6} ( {x}^{3} - 3 x ) + \frac{{k}_{4}}{24} ( {x}^{4} - 6 {x}^{2} + 3 ) ,$$

so we see that with the ability to add higher-order polynomials into our Hamiltonian, we can sample from non-Gaussians. This comes with the caveat that we should stay away from regions where our log(1+x) expansion (and truncation of our series expansion) become invalid. However, in practice, if κ₃ and κ₄ are small, the quadratic force x² should form enough of a potential barrier that the problematic regions should not be accessed.

### 14 Maxwell's Demon Approach to Sampling Non-Gaussians

### 14.1 Introduction to Maxwell's Demon

Sampling from non-Gaussian distributions involves altering the potential energy function of the system. For this purpose we introduce the notion of Maxwell's demon. FIG. 34 illustrates the basic idea of Maxwell's demon. Historically, James Clerk Maxwell considered an experiment where an intelligent observer monitors the gas particles in a box with two chambers and selectively opens the door for only fast moving particles, resulting in a separation of fast and slow particles over time. This reduces the entropy of the gas system over time, although it does not violate the second law of thermodynamics, since entropy is created elsewhere. The intelligent observer is dubbed Maxwell's demon.

As we elaborate below, the Maxwell's demon allows the HMC hardware to go beyond Gaussian distributions. There are various ways to physically construct a Maxwell's demon (MD), including digital and analog ways, as discussed below.

### 14.2 Maxwell's Demon in the Context of HMC

### 14.2.1 Altering the Potential Energy Landscape

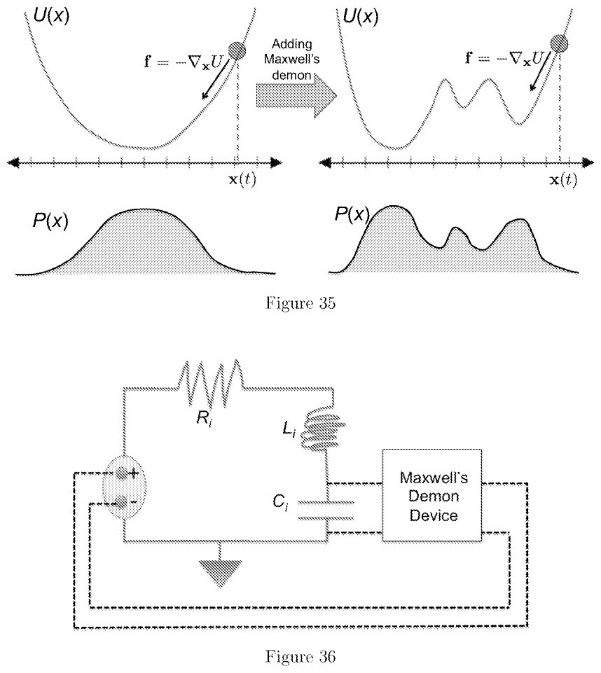

Performing HMC sampling for a variety of distributions involves altering the form of the potential energy U(x) function in our circuit Hamiltonian [symbol] . This is illustrated in FIG. 35.

In Gaussian sampling, this potential energy function U(x) is a quadratic form given in terms of a covariance matrix Σ, as shown in the left panel of FIG. 35. The coupled LC oscillator system (described above) is equipped with a quadratic potential of this sort, allowing one to sample from a Gaussian distribution P(x).

The introduction of a Maxwell demon device into the existing LC oscillator framework modifies the circuit Hamiltonian by changing the potential energy landscape over the circuit variables x. The “ideal” Maxwell demon would be able to apply forces to the existing HMC cells, according to any suitably smooth potential energy function U(x). The dynamical state x of the LC unit cells is passed to the Maxwell demon, which effectively evaluates f=−∇U(x) and passes the computation back to the LC cells as a force. This allows one to tailor the probability distribution P(x) being sampled with HMC. The probability distribution is the exponential of the potential energy, up to normalization:

P(x)~exp(−U(x)). (80)

### 14.2.2 MD as a Voltage-Controlled Voltage Source

FIG. 36 shows that the Maxwell's demon device can be viewed as a voltage-controlled voltage source (VCVS). In this case, the diagram is shown for a single unit cell, although the concept can be generalized to multiple unit cells.

As shown, the voltage xx across the capacitor in the ith unit cell is fed to the Maxwell's demon (MD) device, which could be a digital or analog device. The MD device processes this input by applying some function ƒ to it. The output ƒ(xᵢ) is sent back as a voltage source, which gets applied as a voltage inside the original unit cell. Hence, the MD device acts as a VCVS, since the voltage output is controlled by the voltage across the capacitor.

### 14.2.3 Modified Potential for One Unit Cell

A mathematical analysis for how the MD device modifies the potential energy function begins with considering the case of a single unit cell, which is shown in FIG. 36.

Assume that the MD device does not draw any electrical current from the unit cell. Making this assumption simplifies the analysis, although this assumption could be relaxed with a slightly more complicated derivation.

Under this assumption, we can apply Kirchhoff's voltage law to the circuit in FIG. 36 to obtain the following equation:

$${L}_{i} \frac{{dI}_{i}}{dt} + {I}_{i} {R}_{i} + {V}_{i} = {g}_{i} ( {V}_{i} ) . \qquad ( 81 )$$

### Here,

$${I}_{i} = \frac{{dQ}_{i}}{dt}$$

is the current through the circuit,

$${V}_{i} = \frac{{Q}_{i}}{{C}_{i}}$$

is the voltage across the capacitor, and gᵢ(Vᵢ) is the voltage output from the Maxwell's demon device.

We can re-write this equation in terms of the notation of Newtonian physics. Namely, we set xᵢ=Vᵢ to be the position, we set pᵢ=Iᵢ(mᵢ/Cᵢ) to be the momentum with mᵢ the mass, and we write the force as ƒᵢ(xᵢ). This gives the following equations:

$$\frac{{dp}_{i}}{dt} = - \frac{{R}_{i}}{{L}_{i}} {p}_{i} + {f}_{i} ( {x}_{i} ) , \frac{{dx}_{i}}{dt} = \frac{{p}_{i}}{{m}_{i}} , {f}_{i} ( {x}_{i} ) = \frac{{m}_{i}}{{L}_{i} {C}_{i}} ( - {x}_{i} + {g}_{i} ( {x}_{i} ) ) . \qquad ( 82 )$$

We can then obtain the potential energy function by taking the indefinite integral of the force:

$$U ( {x}_{i} ) = - \int {f}_{i} ( {x}_{i} ) {dx}_{i} = \frac{{m}_{i}}{{L}_{i} {C}_{i}} ( \frac{{x}_{i}^{2}}{2} - \int {g}_{i} ( {x}_{i} ) {dx}_{i} ) ) . \qquad ( 83 )$$

From this equation, we see that we can obtain any desired potential energy function U(xᵢ), because we are free to choose any function for gᵢ(xᵢ). Specifically, we can choose gᵢ(xᵢ)=xᵢ−[LᵢCᵢ/mᵢhᵢ(xᵢ)] where hᵢ(xᵢ) is some arbitrary function. Then we arrive at:

U(xᵢ)=/hᵢ(xᵢ)dxᵢ. (84)

Thus, we can engineer the potential energy function to be essentially any desired function by appropriately choosing the output gᵢ(xᵢ) of the Maxwell's demon device.

### 14.2.4 Modified Potential for Multiple Uncoupled Unit Cells

The extension of the above analysis to multiple unit cells can be done in two steps. First, let us consider the case where the capacitive coupling between the unit cells is ignored, and then we will include this coupling in the next subsection.

With multiple unit cells, we can imagine that the MD device takes as its input the entire state vector x={x₁, x₂, . . . , x_{d}}. Then it outputs a voltage vector g(x). g can act on the entire state vector x, and hence it can effectively couple the unit cells (even when there is no direct capacitive coupling).

In this case, we obtain equations similar to those described above for the evolution of each unit cell:

$$\frac{{dp}_{i}}{dt} = - \frac{{R}_{i}}{{L}_{i}} {p}_{i} + {f}_{i} ( {x}_{i} ) , \frac{{dx}_{i}}{dt} = \frac{{p}_{i}}{{m}_{i}} , {f}_{i} ( x ) = \frac{{m}_{i}}{{L}_{i} {C}_{i}} ( - {x}_{i} + {g}_{i} ( x ) ) . \qquad ( 85 )$$

We can write the overall force as a vector:

f(x)=F(−x+g(x)), (86)

where

$$F = diag {\{ \frac{{m}_{i}}{{L}_{i} {C}_{i}} \}}_{i = 1}^{d}$$

is a diagonal matrix with elements

$$\frac{{m}_{i}}{{L}_{i} {C}_{i}}$$

We call when compute the potential energy as the (component-wise) indefinite integral of f(x) over x. The potential energy is then given by:

$$U ( x ) = - {\sum }_{i} \int {f}_{i} ( x ) {dx}_{i} = \frac{1}{2} {x}^{T} Fx - {\sum }_{i} \int {F}_{ii} {g}_{i} ( x ) {dx}_{i} . \qquad ( 87 )$$

Hence, by appropriately choosing g(x), we can set up essentially any desired potential energy function U(x).

For example, we can choose g(x)=x−F⁻¹h(x). This leads to a potential energy given by:

$$U ( x ) = {\sum }_{i} \int {h}_{i} ( x ) {dx}_{i} , \qquad ( 88 )$$

and hence appropriately choosing h(x) allows one to engineer the U(x) function. In turn, from the equation P(x)=exp(−U(x)), this implies that we can engineer the probability distribution that we sample from.

### 14.2.5 Modified Potential for Multiple Coupled Unit Cells

For multiple coupled unit cells, the analysis is more complicated. Nevertheless, there is not much difference from the uncoupled case, at the conceptual level. The derivation given above for the uncoupled case provides the essential intuition for how the coupled case behaves. Hence, for simplicity, we omit the derivation of how the potential is modified in the coupled case.

### 14.3 Digital Maxwell's Demon

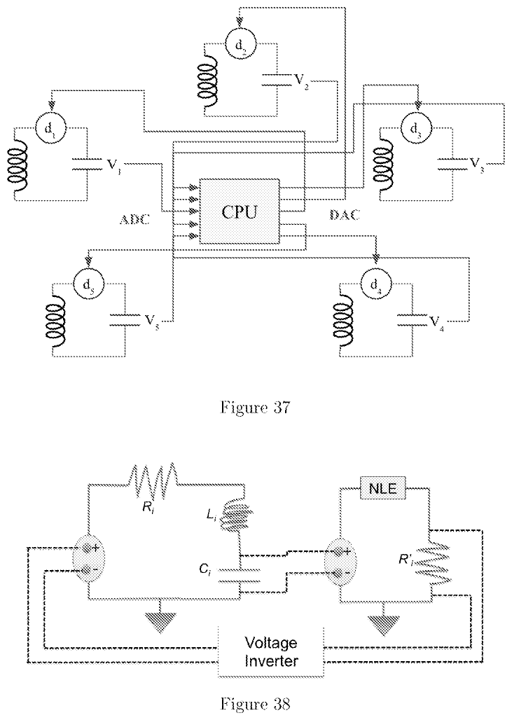

FIG. 37 illustrates how a digital Maxwell's demon device would interact with the analog LC oscillator system. This fits into the paradigm shown in FIG. 36, where the MD device is viewed as a voltage-controlled voltage source.

The digital MD device could be stored and processed either on a CPU or an FPGA. ADCs and DACs are employed to interconvert between analog and digital signals. Specifically, the voltages across the capacitors in the unit cells (denoted x) can be converted to digital signals and fed to the digital MD device. The digital MD device then outputs a digital signal, which is then converted to an analog voltage vector g(x), and the components of this vector are applied as voltage sources in the appropriate unit cells.

The main benefit of the digital approach to the MD device is flexibility and programmability. Digital devices provide one with the flexibility to choose essentially any function g(x) for the output. In this sense, the digital approach to the MD device is programmable and flexible, allowing one to sample from a wide range of probability distributions P(x).

The main drawback of the digital approach to the MD device is that it does not fully exploit the potential speedups that one could get from analog hardware. Digital devices can compute the gradient of the potential energy function, which can be challenging for complex potential energy functions. In contrast, with an analog approach to the MD device, the gradient of the potential energy function corresponds to a physical force, and this physical force naturally gets applied to the system of LC oscillators without any computation involved. (This is discussed in more detail below.) Hence, there is the potential for a larger computational speedup with an analog MD device.

### 14.4 Motivation for Analog Maxwell's Demon

The Maxwell's demon (MD) device provides an opportunity to significantly accelerate the computation, if it is constructed in an analog fashion. This is because an analog MD device can apply a force to the LC oscillator system without having to perform a computation to calculate the force. This is in contrast to a digital MD device, which computes the force from the potential energy function. This computation can, in general, be expensive and have non-trivial scaling with the problem dimension, such as linear or quadratic scaling. Hence, avoiding having to compute the gradient of the potential energy function is an advantage of the analog MD approach.

### 14.5 Non-Correlating Approach to Analog Maxwell's Demon

### 14.5.1 Overview

Next, we consider an approach to constructing the MD device that does not correlate the primary unit cells before introducing an alternative approach that does correlate them in Sec. 14.6 below. Each LC oscillator in the HMC hardware, discussed above, is called a primary unit cell. In what follows, we introduce an additional circuit called an auxiliary unit cell.

Our non-correlating strategy for constructing an analog Maxwell's demon includes several building blocks, which are shown in FIG. 38, and described as follows:
1. A voltage measurement on the primary unit cell capacitor, which then gets applied as a voltage source to drive current through an auxiliary unit cell.
2. A non-linear circuit element in the auxiliary unit cell to allow for a complicated I-V relationship.
3. A voltage measurement across a resistor in the auxiliary unit cell (to read off the current in this cell), which then gets inverted in sign and then applied as a voltage source in the primary unit cell.

FIG. 38 illustrates these components in a single unit cell. In practice, the same construction can be copied d times for d unit cells, possibly with different hyperparameters (e.g., different non-linear elements) for each copy.

The voltage outputted by the auxiliary unit cell is inverted in sign before it is applied to the primary unit cell. This is because the system should have negative feedback (instead of positive feedback) in order to remain stable. Negative feedback provides a restoring force, analogous in physics to how a spring acts to pull a mass backwards towards the equilibrium point. In summary, the voltage inversion helps to maintain the stability of the system.

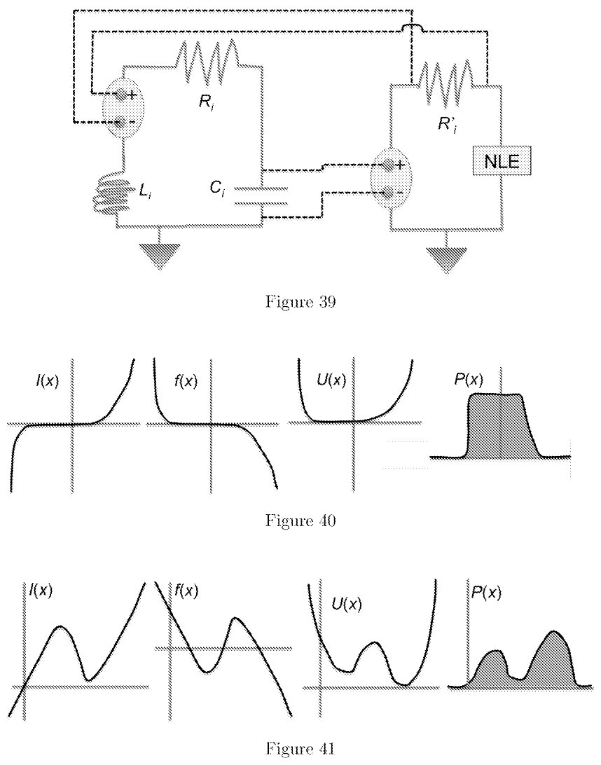

However, FIG. 39 shows that a voltage inverter can be avoided by ungrounding the resistor in the auxiliary unit cell. This allows one to physically invert (or swap) the wires that carry the voltage difference across this resistor, as shown in FIG. 39.

There are several additional elements that could be inserted into the circuit to add flexibility. These optional additional elements include:
an amplifier with tunable gain inserted into the coupling between the two unit cells. For example, an amplifier could amplify the voltage reading on the capacitor of the primary unit cell to boost the voltage source that is applied to the auxiliary unit cell. Alternatively, an amplifier could amplify the voltage reading on the resistor of the auxiliary unit cell to boost the voltage source that is applied to the primary unit cell.
an additional voltage source inserted into the primary unit cell, which would be constant (independent of the state variable) but tunable. This adds flexibility by providing a constant offset to the voltage outputted by the Maxwell's demon, which leads to a constant offset to the force applied to the primary unit cell.

### 14.5.2 Auxiliary Unit Cell

As shown in FIGS. 38 and 39, the basic components of the auxiliary unit cell are a voltage source (coming from the primary unit cell), a non-linear element, and a resistor. One strategy is to use the I-V characteristic of the non-linear element (NLE) as the function generator. We wish to generate a complex functional relationship between the input Vᵢ and the output gᵢ(Vᵢ), as noted for example in the discussion around Eq. (81). The I-V characteristic of the NLE provides one way to engineer this complex functional relationship. Thus, the problem of generating a desired function gᵢ(Vᵢ) is transformed into a problem of engineering a desired I-V characteristic for a NLE.

In what follows, we discuss explicit strategies for constructing the NLE, either based on individual circuit elements or based on combining multiple elements.

### 14.5.3 Non-Linear Elements for Unimodal Distributions

Non-linear elements (NLEs) can be used for sampling from unimodal distributions. It turns out that NLEs with monotonic I-V characteristics mathematically give rise to unimodal probability distributions. Hence, we restrict our attention here to NLEs with monotonic I-V characteristics.

Let us write Iᵢ(Vᵢ) for the current through the ith NLE, as a function of the voltage from the ith primary unit cell. The output of the Maxwell's Demon is denoted gᵢ(Vᵢ), which for simplicity we can set equal to the force ƒᵢ(Vᵢ) acting on the ith primary unit cell. This assumption can be justified by assuming that gᵢ(Vᵢ) is large compared to Vᵢ, as shown in Eq. (82) (where xᵢ was used in place of Vᵢ). The resulting potential energy Uᵢ(Vᵢ) and is then minus the integral of the force ƒᵢ(Vᵢ), and then the associated local probability distribution Pᵢ(Vᵢ) is minus the exponential of the potential energy. For notational simplicity, we can just write the current, force, potential energy, and probability distribution as I(x), ƒ(x), U(x), and P(x) respectively.

FIG. 40 shows a schematic diagram of these four functions for the special case where the NLE is a forward biased diode. Diodes are nonlinear devices that carry current in approximately one direction, with the current growing exponentially with the forward bias voltage. However, they do have a breakdown voltage that allows for current flow in the opposite direction. This gives rise to a somewhat asymmetric I-V characteristic as shown in the first panel of FIG. 40. The second panel shows the force ƒ(x), which is just the negative of I(x) (due to the voltage inverter shown in FIG. 38). The third panel shows U(x), and the fourth shows P(x). P(x) is non-Gaussian since it is asymmetric, and it has a sharper drop-off than a Gaussian.

Instead of considering a single diode, consider two diodes in parallel oriented in opposite directions. Choosing these two diodes in parallel as the NLE leads to a symmetric distribution P(x), since the circuit element is symmetric with respect to positive and negative voltage. This choice of NLE makes it possible to engineer a symmetric version of the probability distribution shown in FIG. 40.

Transistors also provide a nonlinear I-V characteristic. For example, for the common base configuration, the input characteristic is a convex nonlinear function, while the output characteristic is a concave nonlinear function that saturates for large voltages. The former case (input characteristic) gives rise to a distribution P(x) similar to that of a diode, while the latter case (output characteristic) gives rise to a distribution P(x) that has a long slowly decaying tail. Hence, employing the latter enables a non-Gaussian distribution with a long tail. Once again, it is possible to symmetrize these distributions about zero voltage by placing two transistors in parallel oriented in opposite directions. Other configurations (e.g., common emitter) are also possible for transistors.

### 14.5.4 Non-Linear Elements for Multi-Modal Distributions

Let us now discuss NLEs for sampling from multi-modal distributions. To obtain multiple modes, the potential energy should have multiple minima (e.g., local and global minima). This implies that potential energy's derivative, the force, should change sign more than once. If the force changes sign multiple times, then it should be a non-monotonic function. Hence, the I-V characteristic of the NLE should be a non-monotonic function (since it is the negative of the force). Thus, let us discuss NLEs with non-monotonic I-V characteristics.

First consider a tunnel diode as the NLE. In this case, FIG. 41 shows the associated curves for the current, force, potential energy, and probability distribution. The current looks somewhat like a cubic function and clearly is non-monotonic, with a local maximum and local minimum in the first quadrant. We can then obtain a force ƒ(x) that switches sign multiple times, provided that we shift the force by a constant negative amount. This can be accomplished by subtracting a constant voltage from the output of the Maxwell's demon, which physically corresponds to having a constant, negative voltage source applied to the primary unit cell. The resulting ƒ(x) curve is shown in the second panel of FIG. 41. This gives rise to a potential energy U(x) with two minima, and in turn, a probability distribution P(x) that is multi-modal with two modes. As an alternative to the tunnel diode, let us also consider a Gunn diode as a candidate for the NLE. The Gunn diode also has a non-monotonic I-V characteristic under forward bias, with a local maximum and a local minimum in the first quadrant. In addition, it has a non-monotonic I-V characteristic under reverse bias. Hence the curve is non-monotonic for both positive and negative voltage. This can give rise to a more complicated probability distribution P(x) than the case of the tunnel diode. In particular, for the Gunn diode, P(x) can have multiple modes both in the positive voltage region and the negative voltage region.

Other NLEs could be considered, such as a memristor. In addition, we can produce complex I-V characteristics by combining various non-linear elements in series or in parallel. For example, when NLEs are combined in series, the overall I-V curve is a composition of the individual I-V curves. As such, complex I-V curves can be engineered by combining various circuit elements to form the overall NLE block.

### 14.6 Correlating Approach to Analog Maxwell's Demon

### 14.6.1 Overview

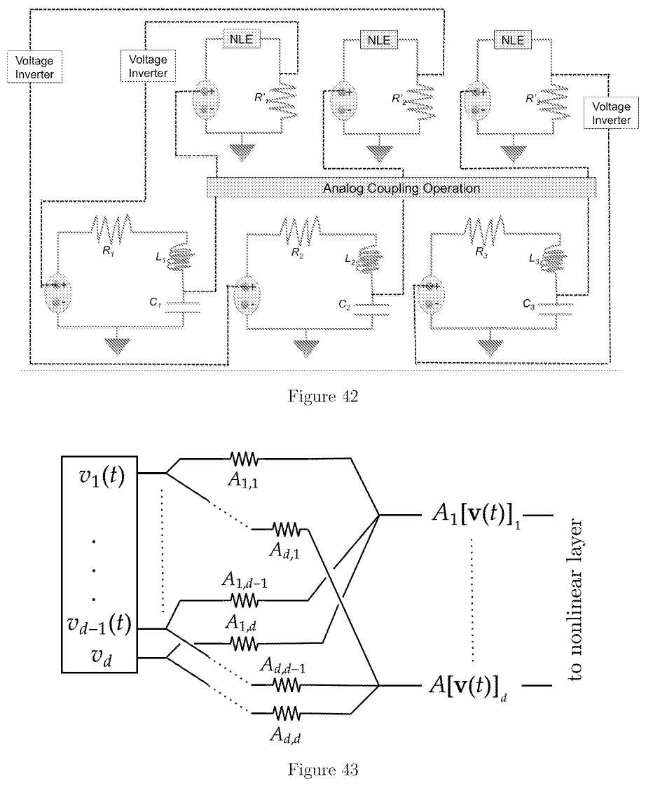

Let us now consider an approach to constructing an analog Maxwell's demon that involves correlating multiple unit cells. An overview of this strategy is depicted in FIG. 42 and includes the following building blocks:
1. A voltage measurement on each primary unit cell capacitor, the collection of which forms a voltage vector v.
2. An analog coupling operation whereby the elements of the voltage vector v are coupled together, with the output of the coupling operation being another vector h(v). This coupling could correspond to an affine transformation h(v)=Av+b, or it could correspond to a higher-order tensor such as a quadratic form or cubic form.
3. A non-linear operation acting on each component of the vector h(v). This can involve using the voltage components of h(v) to drive current through a non-linear circuit element and then reading off the current through this non-linear element (NLE) by picking off the voltage of a resistor in series with the NLE. See Sections 14.5.3 and 14.5.4 for examples of NLEs including various types of diodes and transistors. We write the resulting voltage vector as n(h(v)), with n corresponding to the non-linear operation.
4. The previous two steps may be iterated multiple times such that there are multiple layers of coupling and non-linear operations. If there are L layers, then the final output vector has the form:

vₒᵤₜ=(n_{L}∘h_{L}∘ . . . n₁∘h₁)(v) (89)
where the symbol “∘” indicates that the operations are composed together sequentially. Here, hⱼ and nⱼ are respectively the coupling and non-linear transformations for the jth layer.
5. The components of vₒᵤₜ are inverted in sign to achieve negative feedback for the reasons discussed in Sec. 14.5.1. This can be done either with a voltage inverter or by ungrounding the resistor in the auxiliary unit cell and swapping the wires associated with the voltage difference across this resistor.
6. After inverting the sign of the elements of vₒᵤₜ, these elements are applied as voltage sources inside the corresponding primary unit cells.

In what follows we consider different ways of constructing the analog coupling operation that appears in FIG. 42.

### 14.6.2 Analog Affine Transformation

The analog coupling operation that is mentioned above could take a variety of forms, including, for example, an affine transformation. FIG. 43 provides an analog circuit to implement an affine transformation on the vector v. Suppose we wish to implement the transformation Av for some matrix A. Each row of A multiples v, and this multiplication can be accomplished with a layer of resistors as shown in FIG. 43. Assuming that A is a dense matrix, this involves d² resistors, since there are d resistors associated with each row of A and there are d rows of A. Fewer resistors could be employed if A is not dense. As an optional feature, adding a voltage vector b to the output yields the generic affine transformation Av+b.

### 14.6.3 Higher-Order Coupling Operation

The analog affine transformation mentioned above can be viewed as a first-order coupling operation, since it results in a weighted sum of terms that are linear in the components of v.

Alternatively, one could consider an analog coupling operation that involves higher-order terms, such as terms that are quadratic or cubic in the components of v. One benefit of such an approach is that it enables representation of more complicated probability distributions P(x), including distributions that would be difficult to sample from with standard digital methods.

One way to achieve higher-order terms is to replace each resistor in FIG. 43 with a different circuit element, such as an n-port device with n>2 to achieve higher-order couplings.

For example, let us consider transistors, which are three-port devices. FIG. 44 shows one way of generating higher-order couplings using transistors. Here, one can use the voltage element vⱼ as the gate voltage for a transistor that is on the kth arm of the circuit, where k≠j. In this sense, vⱼ controls the resistance that voltage vₖ sees, leading to the higher-order coupling.

More generally, one can use other multi-port devices, including chains of multiple transistors, to generate other higher-order couplings.

### 14.7 Maxwell's Demon Approach for Distributions Represented by Neural Networks

In many applications, the log-probability being sampled is proportional to the output of a work. In this case, the probabilities can be expressed as:

−U(\vec{x})=log p(\vec{x})∝ƒ_{θ}(\vec{x}). (90)

To be specific, in Bayesian inference being sampled the posterior distribution

p(\vec{y}( [symbol] )∝p(\vec{y})p( [symbol] |\vec{y}) (91)

that is defined as the product of the prior distribution p(\vec{y}) and the likelihood p( [symbol] |\vec{y}), with p(\vec{y}| [symbol] ) the probability of observing y conditioned on observations in a set [symbol] . In this case, the prior distribution and/or the likelihood may be parameterized by a neural network. Here, the runtime of digital HMC may be limited by the computation of the gradient which is typically calculated using automatic differentiation. The runtime of a gradient computation of a neural network depends on the number of parameters of the network as well as the number of layers. For example, for a dense feed forward neural network with the same number of neurons in each layer m, the runtime of calculating the gradient with automatic differentiation is O(dm²). In many cases m may be chosen to scale with the input size, hence a runtime of O(d³) for neural networks employed in modern applications.

In such a case, provided the model ƒ_{θ}(\vec{x}) can be compiled in analog(using an analog neural network, for instance, as described above) and that its gradient can be estimated, this bottleneck can be eliminated by using analog hardware. Such a device is called a “gradient calculator” (4114) below. The gradient calculator 4114 is an analog device whose input is a voltage vector corresponding to the output of the analog neural network device, and whose output is a voltage vector corresponding to the negative gradient −∇ƒ_{θ}(\vec{x}). One possible implementation for the gradient calculator 4114 comprises analog adders and subtracters, in order to estimate the gradient using finite-differences. Solving Hamilton's equations may be performed in hardware by feeding in the output voltage vector −V ƒ_{θ}(\vec{x}) (the negative gradient) of the gradient calculator into a device comprised of d integrators. This way, the voltages obtained at the output of the integrator represent the momentum variables (the momentum integrator device), and this integration step corresponds to the Hamilton equation for momentum:

\vec{\dot{V}}_{\vec{p}}=−∇_{\vec{x}}ƒ_{θ}(\vec{x}). (92)

Therefore after some time T, we have

$${\vec{V}}_{\vec{p}} ( t ) = - ( 1 / {R}_{\vec{p}} {C}_{\vec{p}} ) {\int }_{0}^{t} {∇}_{x} {f}_{θ} ( \vec{x} ( τ ) ) d τ \qquad ( 93 )$$

where we have made the time-dependence of position explicit, and R_{\vec{p}} and C_{\vec{p}} are the resistor and the capacitor characterizing the momentum integrator device. The position is then given by the integral of momentum, which can be performed by feeding in the voltage vector \vec{V}_{\vec{p}}(T) into a second integrator device (the position integrator device):

$${\vec{V}}_{\vec{x}} ( t ) = {M}^{- 1} ( 1 / {R}_{\vec{x}} {C}_{\vec{x}} ) {\int }_{0}^{t} {\vec{V}}_{\vec{p}} ( τ ) d τ . \qquad ( 94 )$$

The voltage vector multiplied by the inverse mass matrix M\vec{V}ₓ after a time increment T is fed to the gradient calculator. In most cases, the mass matrix is diagonal, hence this amounts to multiplying the voltage vector by a constant value and can be performed in analog by using an affine layer comprised of d resistors, as depicted in FIG. 43. There can also be 1/RC terms to rescale the output with to obtain the correct position. We can take every value of R and C to be the same here. If the components are analog, with no latency between the gradient calculator, the momentum integrator device and the position integrator device, the integration of Hamilton's equations will be exact (up to noise sources such as Johnson-Nyquist noise discussed above).

FIG. 45 shows a scheme of a Maxwell's demon device 4110 for sampling from distributions represented by neural networks. A user 41 first compiles the model ƒ_{θ} onto a hardware analog neural network (ANN) 4112 (as well as its gradient if a closed form exists for it). Then, the output of the gradient is fed into the momentum integrator device 4120, whose output is then fed into the position integrator device 4130. The momentum integrator device 4120 is a device comprised of d analog integrators, which outputs a voltage that represents the momentum, as shown in FIG. 45. The position integrator device 4130 also comprises d analog integrators and represents the position variables. The voltage vector \vec{V}ₓ corresponding to the position can be fed to an affine layer, which multiplies the voltage vector by M⁻¹. If M is arbitrarily dense, its inversion may cost O(d³) steps. The matrix inverter block 4140 is an affine layer as shown in Fig., where the elements of the matrix A are the elements of M⁻¹.

### 14.7.1 Calculating the Gradient

Calculating the gradient in analog is challenging. A simpler way to estimate the gradient of a function is to perform finite differences. This may introduce noise in the gradient calculation. In the case of HMC, since there is a Metropolis-Hastings step, this noise should not degrade performance, as it will be another source of uncorrelated noise, as discussed below with respect to stochastic gradient HMC. Specifically, the finite difference gradient can be written as the exact gradient with some added Gaussian noise with zero mean and variance V:

\tilde{∇}_{\vec{x}}ƒ_{θ}(\vec{x})=∇_{\vec{x}}ƒ_{θ}(\vec{x})+ [symbol] (0,V). (95)

As such, the gradient may induce errors in the dynamics. These errors can be considered an added source of noise on top of noise coming from the hardware.

### 15 Hardware for Gaussian Sampling Via the Precision Matrix

The device depicted in FIG. 45 may be slightly modified to perform Gaussian sampling. One difference is that the gradient calculator feeds a voltage Σ⁻¹\vec{x}, corresponding to −∇ log p(\vec{x}), the negative gradient of the multivariate Gaussian distribution. In some example applications such as Bayesian regression, one is directly provided with the matrix Σ⁻¹=Q, known as the precision matrix, as it takes part in the process. In fact a multivariate Gaussian can be defined by its mean and its precision matrix in general.

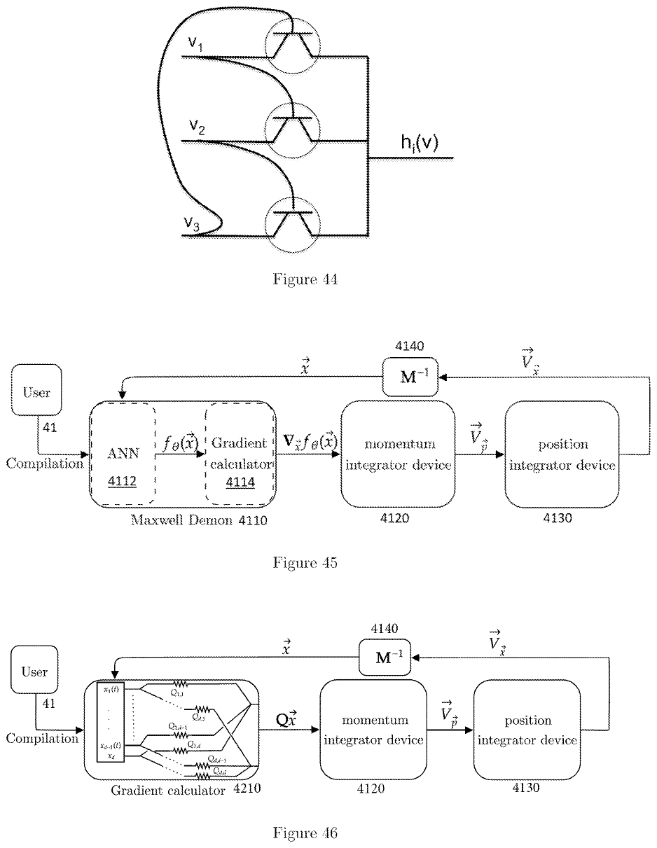

FIG. 46 shows an alternative device sampling a multivariate Gaussian with a given mean and precision matrix. The gradient calculator may be replaced by a resistive layer 4210 whose resistances correspond to the elements of the matrix Q. For this to be practical, it is possible to add op-amps for each output port of the resistive layer, so that values do not vanish. Then, the voltage corresponding to the negative gradient Q\vec{x} can be fed into parallel integrators, forming the momentum integrator device 4120, whose output corresponds to the momentum. As above, we have

$${\vec{V}}_{\vec{p}} ( t ) = ( 1 / {R}_{\overline{p}} {C}_{\vec{p}} ) {\int }_{0}^{t} Q \vec{x} ( t ) d τ \qquad ( 96 )$$

$$and$$

$${\vec{V}}_{\vec{x}} ( t ) = {M}^{- 1} ( 1 / {R}_{\vec{x}} {C}_{\vec{x}} ) {\int }_{0}^{t} {\vec{V}}_{\vec{p}} ( τ ) d τ . \qquad ( 97 )$$

with quantities defined in section 14.7. As before, the outputs should be rescaled by 1/RC terms for both the momentum integrator device 4120 and position integrator device 4130. These devices are fully parallel; they are not coupled. If everything is in analog, with no latency between the gradient calculator 4210, the momentum integrator device 4120 and the position integrator device 4130, the integration of Hamilton's equations should be exact (up to noise sources such as Johnson-Nyquist noise discussed above). Advantages of such an approach include its lack of inductors and hence its scalability. It is not limited by the same connectivity constraints as for the coupled LC resonator device disclosed above. Indeed, the hardware can treat dense covariance or precision matrices without all-to-all coupling.

### 16 Many-Body Coupling Approach to Sampling Non-Gaussians

### 16.1 Motivation and Overview

### 16.1.1 Moving Beyond Two-Body Coupling

The previous section describes one method for extending beyond Gaussian distributions, based on employing a Maxwell's demon (MD). This approach assumed that the direct coupling between unit cells is a two-body coupling, such as the capacitive coupling discussed above.

In this section, we describe an alternative approach to going beyond Gaussian distributions that involves changing the direct coupling between unit cells. Specifically, this approach engineers the direct coupling between unit cells to be many-body, such as three-body or more generally n-body.

This approach leads to n-body terms in the potential energy function U(x), which in turn leads to higher-order cumulants (such as κ₃ or κ₄ discussed in Sec. 13.4.3) in the probability distribution p(x). There is a mathematical connection between introducing many-body coupling and introducing higher-order cumulants into the distribution p(x), as discussed above in Sec. 13.4.3.

To construct three-body couplings, we use electrical devices that have three ports (instead of the two ports associated with capacitive coupling). More generally, to construct n-body couplings for some integer n>2, we use electrical devices that have n ports. The voltages associated with n different unit cells (i.e., n different LC oscillators from the HMC hardware) are fed into the n ports of the electrical device that is responsible for the coupling. This n-port device is called a coupling device.

Below we elaborate on particular physical circuit elements that can be used to construct the n-port coupling device. For example, networks of transistors or networks of varicaps (also known as varactors) could be employed for this purpose, as elaborated below.

This n-body coupling approach can be either used independently from, or together with, a Maxwell's demon approach. In addition, this approach can be either used independently from, or together with, the two-body capacitive coupling discussed in previous sections.

Altering the direct coupling between unit cells has a benefit of being difficult to simulate digitally, as we elaborate below.

### 16.1.2 Digital Simulation of Effective Many-Body Coupling

In principle, many-body couplings could be difficult to simulate with standard digital computers. One way of understanding this is that a generic k-th order coupling is mathematically represented by a k-th order tensor with d^{k} elements. Hence, computing the coupling at a given instant of time can involve d^{k} multiplication operators. For example, a third-order coupling would involve d³ operations for a digital computer to compute. Thus, many-body couplings like this can be challenging for digital computers to simulate.

However, there is a situation where a digital device can efficiently simulate such couplings. Namely, consider the case where the many-body coupling is generated by a series of two-body couplings. In this case, the many-body coupling is effective, rather than genuine, by which we mean that the many-body can be efficiently represented by a small number of two-body couplings. (In contrast, genuine many-body coupling refers to such coupling that cannot be efficiently represent as a small number of two-body couplings.)

The Maxwell's Demon approach described in Sec. 14 largely corresponds to the case of an effective many-body coupling, rather than a genuine many-body coupling. One exception is the approach described in Sec. 14.6.3, which actually involves transistors to generate higher-order couplings that are genuine.

If we ignore this exception and instead consider the analog affine transformation in Sec. 14.6.2, then we would expect a digital computer to be able to simulate the analog Maxwell's demon with a complexity that scales as d², since the matrix-vector multiplication in an affine transformation involves d² operations. This d² complexity holds even though the analog Maxwell's demon generates many body couplings via the non-linear circuit element. This is because this version of the analog Maxwell's demon involves effective, rather than genuine, many-body couplings.

When aiming to design an analog system that is difficult to simulate digitally, it is helpful to use genuine many-body couplings, rather than effective many-body couplings. Here, when we say “difficult to simulate digitally”, we mean the case where the complexity of employing the digital computer involves a scaling that is greater than d² (for example, d³ scaling).

### 16.1.3 Genuine Many-Body Coupling

Let us briefly clarify what is meant by a genuine many-body coupling. A genuine many-body coupling can be viewed as a many-body coupling of the circuit elements involved. This is in contrast to a many-body coupling that is built from circuit elements that have few-body couplings (e.g., two-body couplings).

From a computational perspective, one can think of genuine many-body coupling as the case where building the many-body coupling does not involve additional computational resources. For example, one can use several two-body coupling combined with auxiliary system to generate one three-body coupling, but this involves using additional resources (e.g., the auxiliary system) so it would not be considered genuine three-body coupling. In contrast, with a single transistor and no additional auxiliary system, it is possible to generate a three-body coupling that is considered genuine.

### 16.1.4 Capacitive Versus Resistive Many-Body Coupling

As noted above, making a many-body coupling device involves employing a circuit element that has many input and/or output ports.

One goal is to engineer the probability distribution P(x) that we sample from. This corresponds to engineering the potential energy function U(x), since we have the relationship P(x)∝exp(−U(x).

In terms of physical circuit elements, the potential energy is associated with the capacitive elements of the circuit, since capacitors can store energy. On the other hand, resistive elements in the circuit are associated with damping or friction, which technically does not directly contribute to the potential energy function.

Thus, for the purpose of engineering P(x), we are more interested in capacitive elements than resistive elements. Circuit elements that are purely resistive are not as useful for engineering the probability distribution P(x).

Hence, in addition to wanting n-port devices, we also want those devices to have some capacitance. In particular, we would like the value of that capacitance to be voltage controlled, i.e., controlled by the other input ports to the device. In this sense, we are essentially interested in n-port devices that act as voltage-controlled capacitors.

### 16.1.5 Elements Acting as Voltage-Controlled Capacitors

Various different approaches could be employed to construct voltage-controlled capacitors.

Transistors do have some capacitance that could be affected to some degree by the gate voltage. Thus, transistors are one option for voltage-controlled capacitors. None of the three terminals of the transistor would be grounded, and as a result one should consider a strategy to avoid taking up too much space on-chip. Fortunately, transistor technology based on Fully Depleted Silicon on Insulator (FDSOI) provides a way to keep the on-chip area small in this case.

Varicaps (also known as a varactors) provide another option. While each varicap is a two-port device, one can place two varicaps in opposite directions in a back-to-back configuration, as illustrated in FIG. 19. By inserting a voltage line in between the two varicaps, one can tune the overall capacitance of the system. The device shown in FIG. 19 then acts as a voltage-controlled capacitor with a total of three ports. Thus, it has the desired features for our purposes. We refer to this as a three-port varicap device.

Another strategy is to use the switching capacitor bank shown in FIG. 18. An external voltage signal controls the capacitance of this capacitor bank, and hence it can be viewed as a voltage-controlled capacitor. One drawback of this approach is that could lead to energy dissipation (i.e., damping) during the HMC process since it would involve real-time switching on and off of the circuit elements in FIG. 18.

The transistor, the three-port varicap device, and the switching capacitor bank can all be viewed as voltage-controlled capacitors. Each of these voltage-controlled capacitors can serve as building blocks for higher-order couplings. Namely, we can construct n-port devices by chaining together sets of these three-port devices. These n-port devices then enable engineering of n-body couplings.

### 16.1.6 Adding Tunability or Switches to the Coupling

Adding tunability to the three-body or n-body coupling would allow the hardware device to express a wide variety of probability distributions that have n-body terms.

While adding tunability to n-body couplers may be challenging, a simpler approach is adding switches to the coupler. The switches either turn off or turn on the n-body coupling. The user can specify the probability distribution by choosing an orientation for these switches. This provides a coarse-grained degree of tunability that is relatively easy to implement.

### 16.2 Three Coupled Unit Cells

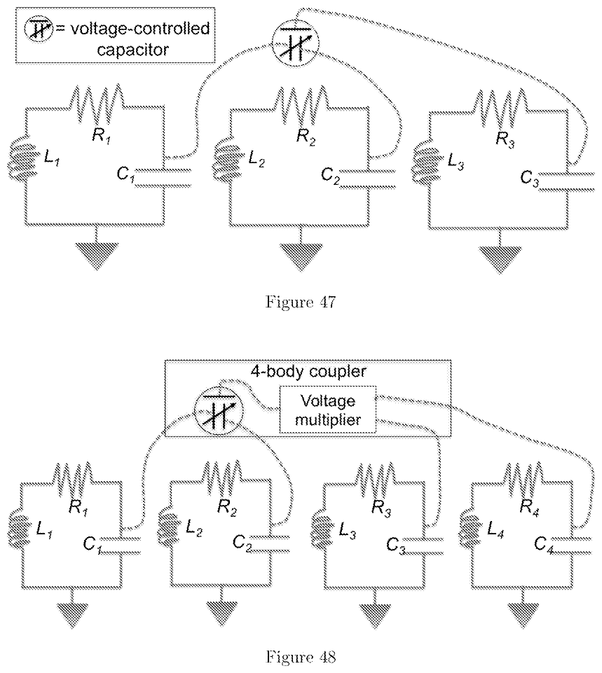

FIG. 47 shows a schematic diagram of three-body coupling mediated by a voltage-controlled capacitor.

Here, we pick off the voltages associated with each capacitor (relative to ground) in each of the three unit cells. These three voltages are fed as inputs into the three ports of a three-body coupler. For example, if the three-body coupler is a transistor, then one voltage is fed into the gate, one is fed into the source, and one is fed into the drain of the transistor. We write the three-body coupler as a voltage-controlled capacitor (VCC), with the assumption that various physical implementations are possible for this VCC (as discussed above).

In the next subsection, we analyze how this coupling affects the probability distribution being sampled.

### 16.2.1 Mathematical Descriptions of Three Coupled Cells

For two capacitively coupled unit cells, a contribution to the potential energy takes the form U=V₁V₂C₁₂. Now suppose that C₁₂ is a function of the voltage V₃ of a third unit cell, which is the case depicted in FIG. 47. The contribution to the potential energy is then U=V₁V₂C₁₂(V₃) where C₁₂(V₃) is some function that is determined by the physical nature of the voltage-controlled capacitor.

For example, suppose that this is a linear function, which is often true over a small range of voltages. In this case, we have

$${C}_{12} ( {V}_{3} ) = {V}_{3} {C}_{123} + {C}_{12}^{( 0 )} .$$

Then the contribution to the potential energy is

$$U = {V}_{1} {V}_{2} {V}_{3} {C}_{123} + {V}_{1} {V}_{2} {C}_{12}^{( 0 )} \qquad ( 98 )$$

Thus, in this case, we arrive at two terms in potential energy: (1) A three-body term proportional to C123 and (2) A two-body term proportional to

$${C}_{12}^{( 0 )} .$$

In Sec. 13.4.3, we established a mathematical connection between three-body terms in the potential energy and third-order cumulants (denoted κ₃) in the corresponding probability distribution P(x). Thus, Eq. (98) results in a probability distribution P(x) that is non-Gaussian, with a third-order cumulant. Hence, we can engineer the probability distribution P(x) to be non-Gaussian using the approach of three-body couplings.

### 16.3 Coupling Four or More Unit Cells

FIG. 48 shows a circuit diagram for how four unit cells can be coupled with a four-body coupler. The voltages on the third and fourth unit cells, V₃ and V₄, are fed into a voltage multiplier whose output is the product V=V₃V₄. The voltage multiplier can either be analog or digital, as elaborated below. This voltage V is then applied to the gate of a voltage-controlled capacitor, leading to a capacitance C₁₂ (V₃V₄) between unit cells 1 and 2.

While C₁₂(V₃V₄) can be a complicated function, suppose that it is a linear function over some regime, of the form

$${C}_{12} ( {V}_{3} {V}_{4} ) = {C}_{1234} {V}_{3} {V}_{4} + {C}_{12}^{( 0 )} .$$

In this case, we obtain a contribution to the potential energy of the form:

$$U = {V}_{1} {V}_{2} {V}_{3} {V}_{4} {C}_{1234} + {V}_{1} {V}_{2} {C}_{12}^{( 0 )} \qquad ( 99 )$$

Thus, we obtain both a four-body coupling and a two-body coupling with this implementation.

In Sec. 13.4.3, we established a mathematical connection between four-body terms in the potential energy and fourth-order cumulants (denoted κ₄) in the corresponding probability distribution P(x). Hence, using this approach, we obtain a probability distribution P(x) that is non-Gaussian, with a fourth-order cumulant.

The approach shown in FIG. 48 can be extended in a direct manner to couple more than four cells (n>4). This involves feeding additional inputs into the voltage multiplier, so that n−2 voltages are multiplied together to obtain the voltage that is ultimately applied to the gate of the voltage-controlled capacitor in the n-body coupler. Because of the mathematical connection between n-body couplings in the potential energy and n-th order cumulants in the probability distribution P(x), the resulting distribution is non-Gaussian with an n-th order cumulant (among other possible lower-order cumulants).

### 16.4 Analog Versus Digital-Analog Approach to Many-Body Coupling

### 16.4.1 Fully Analog Approach

In principle, the components shown in FIGS. 47 and 48 could be analog devices, since both voltage-controlled capacitors and voltage multipliers can be constructed from analog components. This has the benefit of low latency because it does not involve communicating with a digital device. Furthermore, it could lead to larger speedups, since multiplying voltages has some computational overhead on a digital device (but not on an analog device).

However, the fully analog approach has more circuit elements than the two-body coupling case. For example, in the three-body case, these circuit elements include the infrastructure associated with wiring a third unit cell into the input of the capacitor of two other unit cells. In the four-body case, there is also the infrastructure associated with the voltage multiplier. Hence, the fully analog approach can add more circuit complexity.

### 16.4.2 Digital-Analog Approach

A convenient approach to many-body coupling is to use the existing infrastructure that is already in place for implementing the HMC hardware with two-body coupling. Namely, Section 8 discloses using voltage-controlled capacitors in the two-body case, where the digital hardware is used to set the capacitance value.

For three-body coupling, the voltage measurement V₃ can be taken from a third unit cell and sent to the digital hardware as an input, and have the digital hardware output a voltage proportional to V₃ and apply this voltage to the capacitor connecting unit cells 1 and 2. Hence, the digital hardware acts as the intermediary between unit cell 3 and the capacitor between unit cells 1 and 2.

For four-body coupling, one can take the same approach, except the digital hardware computes the product of the voltages V₃ and V₄. The digital hardware outputs a voltage proportional to V₃V₄ and applies this voltage to the capacitor connecting unit cells 1 and 2.

Once again, one benefit of this approach is that it leverages the infrastructure that is already in place for implementing HMC with two-body coupling.

### 16.5 Strategies for Local Connectivity

In principle, the hardware can be designed to allow for full connectivity (global connectivity). The number of connections grows rapidly in this case, since n-body coupling leads to dⁿ scaling for the total number of connections. There is a trade-off to consider with hardware complexity and the speedup, with more connections leading to greater speedup possibilities but more complex hardware.

Due to this trade-off, it may be desirable to consider local connectivity. One approach to local connectivity is to leverage the existing infrastructure used for two-body coupling. Namely, one can employ the digital-analog approach to many-body coupling (discussed immediately above), and use whatever connectivity structure is already in place for the two-body coupling as the same structure as for n-body coupling. In this case, the connectivity structure for the n-body coupling will match that of the two-body coupling. So if the two body coupling is local, then so will be the n-body coupling.

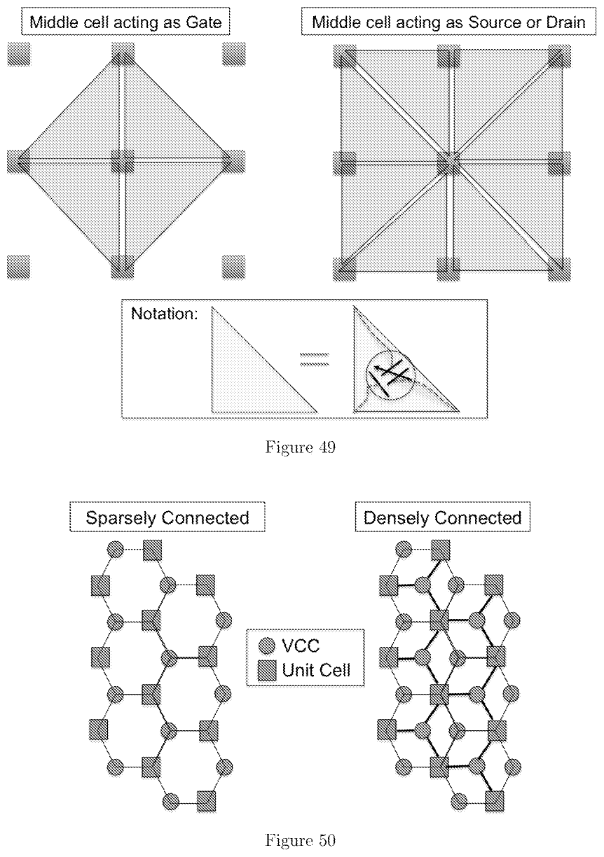

An alternative approach is to design the n-body connectivity structure from scratch, i.e., without leveraging the two-body connectivity structure. Here we give a few strategies for this approach, as shown in FIGS. 49 and 50, for the special case of three-body coupling. FIG. 49 shows how one can fit the three-body coupling onto a square lattice, and FIG. 50 shows how one can fit the three-body coupling onto a hexagonal lattice.

### 17 Analysis of Speedups

### 17.1 Runtime Analysis of Digital HMC

An analysis of the computational complexity of the HMC process can be found in Neal et al., “MCMC using Hamiltonian dynamics,” in Handbook of Markov Chain Monte Carlo, 2.11 (2011), which is incorporated herein by reference in its entirety for all purposes. As mentioned, the system integrates Hamilton's equations to perform HMC:

$$\frac{d \vec{p}}{d t} = ∇ log p ( \vec{x} ) \qquad ( 100 )$$

$$\frac{d \vec{x}}{d t} = {M}^{- 1} \vec{p} . \qquad ( 101 )$$

These are vectorial differential equations, hence there are d equations to solve with \vec{x} and \vec{x} d-dimensional vectors.

Numerically, a common integration method is the leapfrog integrator, which gives the updates on position and momentum as:

$$\vec{p} ( t + ϵ / 2 ) = \vec{p} ( t ) - ( ϵ / 2 ) ∇ log p ( \vec{x} ( t ) ) , \qquad ( 102 )$$

$$\vec{x} ( t + ϵ ) = \vec{x} ( t ) + ϵ {M}^{- 1} \vec{p} ( t + ϵ / 2 ) , \qquad ( 103 )$$

$$\vec{p} ( t + ϵ ) = \vec{p} ( t + ϵ / 2 ) - ( ϵ / 2 ) ∇ log p ( \vec{x} ( t + ϵ ) ) . \qquad ( 104 )$$

In the optimal case, the numerical complexity of integrating such equations is given by O(dnₜ), with nₜ the number of time steps. However, computing the right-hand side of each equation in order to perform numerical integration may be more costly. Indeed, computing the log probability depends on the form of the probability distribution being sampled. The mass matrix M is in the general case a d×d matrix, hence the cost of its inversion scales in d³ steps. However, in most implementations M is taken to be diagonal, reducing its cost to d.

Without being bound to any particular theory, for the numerical integration error to stay low enough, the time step size ϵ used in the numerical integration should scale as d^{1/4}. We thus arrive to the numerical scaling in d^{5/4} with the assumptions that the gradient of the log probability is obtained efficiently and that the mass matrix M is diagonal, hence its inversion is computed in d steps. (In practice, if the probability distribution is represented by a neural network, the complexity of evaluating the gradient will grow polynomially with the number of parameters of the model as well as the input size.)

In this sense, the d^{5/4} scaling is the optimal scaling for digital implementations of HMC. In cases where the sparsity structure of M is unknown, dense matrix inversion, such as Cholesky factorization that costs O(d³) steps, can be used. In the next sections we examine the specific speedups that can be obtained by using our hardware.

### 17.2 Runtime for Analog HMC

In the general case, the speedup obtained from implementing a differential equation in an analog system will stem from two major areas: (i) there is no need to discretize the equations, hence no step size, which means that numerical errors coming from the step size disappear. (In electrical hardware, there will be additional sources of noise which may also affect performance such as thermal noise and shot noise.) (ii) To numerically solve a differential equation, one computes terms of the update such as with the leapfrog integration scheme. In analog, the system naturally obeys the differential equation. Hence matrix multiplications and inversions do not need to be performed, greatly reducing the number of operations.

An additional subtlety is the computation of the gradient. Depending on the form of the probability distribution, this may affect the speedup obtained by an analog HMC device. This is discussed further in section 14.7 above.

In the ideal case, the number of digital operations for implementing an analog SDE solver for d-dimensional objects is therefore O(1). However, one should communicate digitally with the analog solver to set the inputs and to measure the outputs for instance. For small enough data (of the order of the tens of megabytes), the data may be loaded to the analog system in O(1) steps. However, as the data size increases, a linear scaling with dimension d will appear. Therefore, we consider the best-case scenario scaling of an analog solver to be O(1).

### 17.3 Speedups for Gaussian Sampling

If the probability distribution being sampled is a multivariate Gaussian, as presented above, the form of the gradient can be calculated analytically. Recall that the probability distribution is defined as:

$$p ( \vec{x} ) = \frac{1}{\sqrt{{( 2 π )}^{N} \vert Σ \vert}} exp ( - \frac{1}{2} {\vec{x}}^{T} {Σ}^{- 1} \vec{x} ) . \qquad ( 105 )$$

The gradient of the log-probability can be expressed in an affine form:

∇ log p(\vec{x})=−\vec{x}^{T}Σ⁻¹. (106)

Therefore, calculating the gradient amounts to performing a vector-matrix multiplication, where the involved matrix is the inverse of the covariance matrix. This indicates a runtime in O(d³) for digital HMC for Gaussian distributions.

However, if the distribution is a multivariate Gaussian, there is a more efficient way of sampling, known as Cholesky sampling. The trick in Cholesky sampling is to parameterize the random variables as \vec{x}=L\vec{u} (recall the random variables \vec{x} have 0 mean), with \vec{u}=(u₁, u₂, . . . , u_{d})^{T}, uᵢ~ [symbol] (0, I). The covariance matrix can be written as

Σ= [symbol] [(\vec{u}−\vec{μ})(\vec{u}−\vec{μ})^{T}]=L [symbol] [\vec{u}\vec{u}^{T}]L^{T}=LL^{T} (107)

where the Cholesky decomposition is identified as the last term. Therefore, one can randomly sample directly from \vec{u} (as the uᵢ are independent) and from there sample from \vec{x} by multiplying by the Cholesky factor L. Therefore, Cholesky sampling is at least as efficient as computing the full inverse of the covariance matrix in the general case. This largely depends on the structure of the covariance matrix.

### 17.3.1 Speedups for Dense Covariance Matrix

In the case of a dense covariance matrix, the Cholesky decomposition is performed in O(d³) steps. In many applications, such as Gaussian processes, the covariance matrix is updated and resampled many times, thus the structure of the covariance matrix changes. This means that in many applications, the covariance matrix is assumed to be dense. In this case, one can obtain a speedup of O(d³), in the case where the analog system is close to fully connected, i.e. with the connectivity k scaling as d. If this is not the case, when updating the capacitance values such that the capacitance matrix matches the covariance matrix, most values of the covariance matrix will be suppressed because of limited connectivity, hence the acceptance rate of HMC proposals may scale unfavorably. In the case in which the covariance matrix is dense but where the difference between the largest and the smallest element is many orders of magnitude, the dense covariance matrix can be made sparse by a preprocessing step. This step takes O(d²) operations to be performed, and enables us to obtain a sparse matrix and potentially banded matrices. This step may be done for digital as well as analog approaches, and may become the bottleneck. Hence, for connectivity k~O(1), there may not be any speedup obtained by using analog HMC for Gaussian sampling.

### 17.3.2 Speedups for Diagonal and Sparse Covariance Matrices

If the covariance matrix is diagonal, or equivalently if the random variables \vec{x} are uncorrelated, the cost of the inversion is simply O(d), since the covariance matrix is equivalent to a d-dimensional vector. Sampling from this distribution is the same as sampling from d independent Gaussian distributions and therefore the cost is O(d). We therefore expect a speedup of O(d) by using analog hardware, where the capacitance matrix is diagonal (so the cells are uncoupled).

If the covariance matrix is sparse, the most efficient strategy is to convert the sparse matrix to a banded matrix, which have the main diagonal as well as the k central diagonals being nonzero (if k=1, the matrix is tridiagonal). By sorting the n_{nz} non-zero elements of the sparse matrix, one may obtain a banded matrix in a linear runtime using the Cuthill-McKee process.

This leads to the special case where the sparse matrices are already banded matrices, which have the main diagonal as well as the k central diagonals being nonzero (if k=1, the matrix is tridiagonal). In this case, the Cholesky factorization may be performed in O(k²d) steps. The Cholesky decomposition preserves the band structure of the matrix, hence the final matrix vector product used in Cholesky sampling is O(kd). Due to the connectivity of the HMC analog device, covariance matrices which are banded appear as those most natural to implement. Therefore, in this case we expect a speedup given by analog HMC of O(k²d).

17.4 Speedups for Distributions with Higher-Order Correlation Tensors

We now consider the potential speedups in the context of perturbed distributions with nontrivial higher-order cumulants (beyond second-order); for this, we focus on d-dimensional distributions represented through the Gram-Charlier A series introduced in Eq. (78). Taking the logarithm of such a distribution, the potential energy function is a polynomial in d-variables. Every kth order cumulant included in the perturbative expansion introduces a homogeneous polynomial of degree K to the potential energy function. The coefficients of this polynomial are represented through a k-th order tensor; as such, if the highest nontrivial cumulant is order K, the potential energy function is a polynomial of leading order K.

The potential speedups that result from higher-order cumulants are expected to result from that fact that these are introduced by higher-order coupling or equivalently higher-order tensor interactions. Computations involving these higher-order tensors can be used to calculate the gradient of the log probability for HMC.

In analog hardware, a generic k-th order cumulant is introduced by a k-th order coupling, represented by a k-th order tensor. Therefore, to digitally calculate the gradient of the log probability, the number of operators scales as O(d^{k}). In contrast, in analog hardware the dynamics these introduced by these interactions would occur naturally in O(1). This results in a potential speedup of O(d^{k}). This analysis applies to the case where there are genuine many-body coupling, as discussed above.

In the case where the many-body coupling is introduced by chaining two-body couplings, the operations to simulate these dynamics digitally would go as O(d²). Once again, in the analog case, the physical dynamics may be realised in O(1), leading to an expected O(d²) speedup.

### 17.4.1 Speedups for Distributions Represented by a Neural Networks

A certain number of speedups stem from this approach, discussed in section 10:
A d^{1/4} speedup stems from the absence of the need to discretize time, as is done in digital HMC, leading to an adjustment of the number of time steps as a function of dimensionality.
Calculating the gradient, which can cost up to O(d³) steps for dense neural networks (if the number of neurons per layer m scale with the input dimension d), is here performed in analog by finite-differencing. Here the error introduced by finite-differencing is not as detrimental as in other applications thanks to the Metropolis-Hasting step.
Finally, computing the accept/reject step and uploading/downloading the data may be performed all in analog, suppressing a number of operations O(d) as discussed in section 16.2.
   Overall, we therefore expect a speedup of d^{13/4} for analog HMC with a probability distribution represented by a neural network.

### 18 Running Alternative Monte Carlo Processes on the Hardware

18.1 Realistic Analysis of Hardware with Damping

The protocol for HMC sampling we have presented so far utilizes trajectories of analog circuit dynamics that are assumed to be conservative; these trajectories are borrowed in a computational protocol that yields samples from a target probability distribution. We shall now provide a more realistic analysis of the physical circuits, and present alternative processes that can be utilized when the actual circuit dynamics deviate far from the intended Hamiltonian dynamics.

Consider the LC oscillator cell in FIG. 3, used for one-dimensional Gaussian sampling. As a first approximation to the realistic dynamics of this circuit, a resistor is attached in series to both the capacitor and inductor. If these resistors have resistance R_{C} and R_{L}, the circuit will behave as a series RLC circuit with effective resistance R=R_{C}+R_{L}. In addition, assume that a voltage signal V(t) is applied to the circuit, with V(0)=0.

Let the charge q on the capacitor C act as the position coordinate of the system, while the magnetic flux LI through the inductor will be the conjugate momentum coordinate.

The time derivative of the circuit's momentum LI(t) is specified by a differential equation:

$$L \frac{d I ( t )}{d t} = - R I ( t ) - \frac{1}{C} {\int }_{0}^{t} I ( τ ) d τ + V ( t ) . \qquad ( 108 )$$

The integration of I(τ) up to time t is equal to the charge q(t) stored on the capacitor at this time. As such, the ODE can be re-written as:

$$L \frac{d I ( t )}{d t} = - \frac{q ( t )}{C} - R I ( t ) + V ( t ) \qquad ( 109 )$$

From the this relation between the integral in (108) and the charge on the capacitor, we know that the time derivative of q(t) is I(t):

$$\frac{d q ( t )}{d t} = I ( t ) . \qquad ( 110 )$$

Collecting the coupled dynamical equations (109) and (110), we arrive at:

$$\frac{d q ( t )}{d t} = I ( t ) \qquad ( 111 )$$

$$L \frac{d I ( t )}{d t} = - \frac{q ( t )}{C} - R I ( t ) + V ( t ) . \qquad ( 112 )$$

If we label the momentum p=LI and utilize dot notation, the coupled equation above reduces to:

$$\dot{q} = \frac{p}{L} \qquad ( 113 )$$

$$p = - \frac{q ( t )}{C} - \frac{R}{L} p + V ( t ) . \qquad ( 114 )$$

The term −Rp represents a dissipative force, linear in momentum, that does not exist in conservative systems.

We will now elaborate on the nature of the voltage source V(t). While this source signal may be a deterministic signal provided by a user, we concentrate on stochastic voltage signals that are applied to the system via an underlying noise process. As a first approximation to a realistic noise model for RLC cell dynamics, V(t) originates from Johnson thermal noise; this noise arises from the thermal agitation of a macroscopic collection of electrons through the effective resistor with resistance R, held at some temperature T.

Our Johnson noise can be aptly modeled with a one-dimensional Brownian motion W(t) and diffusion constant D. That is, V(t)~ [symbol] (0, Ddt)=DdW via a slight abuse of notation. When we introduce this into equation (113), we see that the RLC dynamics are modeled by a coupled stochastic differential equation (SDE):

$$\dot{q} = \frac{p}{L} \qquad ( 115 )$$

$$\dot{p} = - \frac{q}{C} - R p + DdW . \qquad ( 116 )$$

What remains is the derivation of the diffusion constant D; for this, apply the fluctuation dissipation theorem. According to the fluctuation dissipation theorem followed by our circuit system, the diffusion constant D of Johnson noise is related to the coefficient R of the dissipative force (which is just the effective resistance), the inductance L, and the temperature of the resistor. In fact, D is given as:

$$D = \frac{R}{L} k T , \qquad ( 117 )$$

where k is Boltzmann's constant. With this relation, we finally arrive at a realistic dynamical depiction of our circuit, given as an underdamped Langevin SDE;

$$d q = \frac{p}{L} dt \qquad ( 118 )$$

$$dp = - ( \frac{q}{C} + R p ) d t + \frac{k T R}{L} dW . \qquad ( 119 )$$

The circuit dynamics are hence a stochastic process, not a deterministic one, as assumed above. Moreover, the stochastic dynamics converge to an equilibrium. Suppose the circuit is initialized with any position q₀ and any momentum p₀ at time t=0; by converging to equilibrium, we mean that position and momentum coordinates a long time after this initialization (t>>0) will be distributed according to the stationary distribution π(q, p) of the SDE (118). This distribution is solvable as:

$$π ( q , p ) ∼ exp ( \frac{- 1}{2 k T} [ \frac{{p}^{2}}{L} + \frac{{q}^{2}}{C} ] ) . \qquad ( 120 )$$

If we marginalize over the momentum coordinate p, the equilibrium distribution of the position coordinate (charge on capacitor), is given as the Boltzmann distribution:

$$π ( q ) ∼ exp ( \frac{- 1}{2 k T} [ \frac{{q}^{2}}{C} ] ) . \qquad ( 121 )$$

The Boltzmann distribution of the RLC system is a univariate Gaussian with mean 0 and variance kTC; if we allow a dynamical trajectory to converge to equilibrium, repeatedly measuring the position coordinate of the circuit (charge on the capacitor) amounts to sampling from this univariate distribution.

We now present a protocol for sampling from an arbitrary multivariate Gaussian using the stochastic circuit dynamics used above.

### 18.2 Protocol for Univariate Gaussian Sampling

Recall that the RLC system converges to equilibrium regardless of the initial values of position and momentum. The equilibrium of the system is characterized by the stationary distribution π(q, p) over phase space. We would like to prepare the RLC circuit in this equilibrium state, which amounts to letting the circuit sit in contact with a thermal bath for a sufficiently long time. When the equilibrium state of the circuit has been prepared, repeated measurements of the position q and momentum p of the circuit (charge on the capacitor and magnetic flux through the inductor, respectively) are distributed according to π(q, p). Measuring only the position effectively marginalizes over momentum and the sample from the Boltzmann distribution of the system, which is a zero mean Gaussian with variance kTC. Tuning the value of the capacitance C changes the variance of the Bolztmann distribution we sample from; if we set

$$C = \frac{{σ}^{2}}{kT}$$

for arbitrary σ²>0, the sampled distribution will then have variance σ². As a system in equilibrium remains in equilibrium unless externally acted upon, we can draw infinitely many samples from the Boltzmann distribution through repeated measurement of the position of the circuit (charge on capacitor).

While we can tune the variance of the sampled Boltzmann distribution, the mean of this distribution will remain zero. If we set

$$C = \frac{{σ}^{2}}{kT} ,$$

we can sample nom the univariate normal [symbol] (μ, σ) by adding the fixed mean value μ to each position sample; this can be implemented in an analog manner by applying a constant voltage bias of value μ to the RLC circuit, but can also be performed digitally. With this, we have a protocol to sample from arbitrary univariate distributions.

### 18.3 Extension to Multivariate Gaussian Sampling

While the realistic analysis provided in 18.1 was performed for one RLC cell, a similar analysis follows for a network of capacitively coupled RLC cells. Suppose N RLC cells are pairwise coupled via coupling capacitive bridges, the system can be specified by an N-dimensional position vector \vec{q} and an N-dimensional momentum vector \vec{p}. We then define the matrices C and L as the capacitance and inductance matrices, respectively, of the lossless coupled oscillator of section 3 (That is, like we did for the coupled LC circuit without resistors).

Just as the coordinates (q, p) of the single unit cell follow an underdamped Langevin dynamics over a two-dimensional phase space, the system of coordinates (\vec{q}, \vec{p}) follows an underdamped Langevin dynamics over a 2N-dimensional phase space. We suppose the dynamics are given as a coupled stochastic differential equation:

$$d \vec{q} = {L}^{- 1} \vec{p} dt \qquad ( 122 )$$

$$d \vec{q} = - ( {C}^{- 1} \vec{q} + {RL}^{- 1} \vec{p} ) dt + DdW \qquad ( 123 )$$

where R is a drag matrix that depends on the resistances in the network and D a diffusion matrix multiplying an N-dimensional Brownian motion W(t). Just as the friction coefficient is related to the diffusion constant in the single cell case, the drag matrix is related to the diffusion matrix in the coupled case; this is because the fluctuation-dissipation remains applicable.

Fortunately, we do not need to know the explicit form of the drag and diffusion matrices to know that the dynamics of coupled RLC network converges equilibrium regardless. Just as the equilibrium distribution (120) of the single cell does not depend on the friction and diffusion constants, the equilibrium distribution of the dynamics (122) does not depend on the drag or diffusion matrices. If each resistor in the RLC network is held at temperature T, the equilibrium distribution over phase space is defined as:

$$π ( \vec{q} , \vec{p} ) ∼ exp ( ‐ \frac{1}{2 kT} [ \vec{p} {L}^{- 1} \vec{p} + {\vec{q}}^{T} {C}^{- 1} \vec{q} ] ) \qquad ( 124 )$$

If we marginalize over the momentum coordinate, we see that the resulting Boltzmann distribution over N-dimensional position space is given as:

$$π ( \vec{q} ) ∼ exp ( \frac{1}{2 kT} {\vec{q}}^{T} {C}^{- 1} \vec{q} ) \qquad ( 125 )$$

This distribution is a multivariate Gaussian of zero mean and covariance matrix

$$\frac{1}{kT} C .$$

AS such, repeatedly sampling the position vector \vec{q} of an equilibrated RLC networks amounts to sampling from a multivariate normal distribution

$$𝒩 ( \vec{0} , \frac{1}{kT} C ) .$$

A protocol for sampling from an arbitrary multivariate Gaussian [symbol] (\vec{μ}, Σ) can then be performed similarly to the protocol in Section 18.2, where instead of tuning a single capacitor, we tune the values of the capacitance matrix C. If the capacitance matrix is set such that such that C=(1/kT)Σ, the sampled Boltzmann distribution will have mean zero and covariance Σ. Like the univariate protocol, we change the mean of the sampled distribution to vector \vec{μ} by applying a constant voltage bias μᵢ to each of the i cells throughout the dynamics. Taking a sample without a voltage bias and digitally adding to it the vector \vec{μ} will also have the same effect. As such, the stochastic dynamics of the coupled RLC network can be used to sample from arbitrary multivariate Gaussian distributions.

### 18.4 Stochastic Gradient Hamiltonian Monte Carlo

We have presented a realistic analysis of the single-cell oscillator cell used in the HMC protocol, and showed this circuit dynamics undergoes underdamped Langevin dynamics as opposed to Hamiltonian dynamics. We present a process that utilizes digitally simulated underdamped Langevin dynamics. A similar sampling protocol can be performed using the underdamped circuit dynamics presented in Section 18.1.

HMC involves directly computing or having access to the gradient of the potential energy function in order to digitally simulate the Hamiltonian dynamics of the system. For the case of analog hardware, access to the exact gradient may also be restricted, depending on whether the user has a digital or analog neural network representing the probability distribution p(x).

Stochastic Gradient HMC (SGHMC) addresses these challenges and improves the scalability of HMC. SGHMC introduces the use of a stochastic gradient calculation that can be performed with less than the entire data set. However, as a result, the dynamics introduced are no longer those induced by the desired distribution. Therefore, an additional friction term is included which counteracts the effect of the noise injected by the stochastic gradient.

Explicitly, in SGHMC the gradient is calculated using a minibatch of the whole data set [symbol] , such that [symbol] ∈ [symbol] . The data points \vec{x}ᵢ∈ [symbol] are uniformly sampled and used to calculate

$$∇ U ( \vec{x} ) = - \frac{\vert 𝒟 \vert}{\vert \tilde{𝒟} \vert} {\sum }_{{x}_{i} ∈ \tilde{𝒟}} ∇ log π ( {x}_{i} \vert \vec{x} ) - ∇ log p ( \vec{x} ) . \qquad ( 126 )$$

Assuming that the observations of \vec{x} are independent we can apply the central limit theorem to arrive at the expression:

∇Ũ(\vec{x})≈∇U(T)+ [symbol] (0,V(\vec{x})), (127)

where V is the covariance of the stochastic gradient noise, which comes from the stochastic gradient approximation. As mentioned above, in order to counter act the appearance of this term one can include a friction term. This leads to the following dynamical equations, which define SGHMC with friction:

d\vec{x}=M⁻¹\vec{p}dt (128)

d\vec{p}=−[∇U(\vec{x})+BM⁻¹\vec{p}|dt+\sqrt{2}Bd\vec{w} (129)

where M is the mass matrix, B=V(\vec{x})/2 is the diffusion matrix, ∇U(\vec{x})=ƒ(\vec{x}) is the force and \vec{w} is the Wiener process. Due to the inclusion of the friction term the effect of the stochastic noise is reduced. This in turn leads to the stationary distribution for \vec{x} obtained at long times corresponding to the target probability distribution π(\vec{x})=exp(−U(\vec{x})).

### 18.4.1 Our Approach to SGHMC

Consider performing Gaussian process regression where the posterior distribution is learned from a minibatch of training data as opposed to the entire training set. If we map the logarithm of this minibatched posterior distribution to the potential energy function of the realistic oscillator circuit, we will have a noisy version of the true potential energy function. As the potential energy function of the oscillator circuit is a quadratic form defined by the inverse capacitance matrix C⁻¹, the noise will manifest as a misspecification of capacitance values that determine this matrix. When the size of the training set is large, the central limit theorem suggests that the misspecification of any one capacitance value is approximately Gaussian distributed around the true value.

To damp out effect of this misspecification noise and converge to the true target distribution, the friction (resistance) cannot be tuned out of a realistic oscillator circuit to match the noise profile as is done in digital SGHMC. While we can tune the friction, the fluctuation-dissipation relations says this will proportionally tune the thermal noise of the system; while this need not be true of digital dynamics, it may be unavoidable in circuit dynamics. As such, the friction term of the physical oscillator should damp out the effects of thermal noise as well as misspecification noise, yet can only damp the contributions from thermal noise.

To avoid this issue, we can operate in a regime of high friction/resistance. When this happens, we will have a high amount of thermal fluctuation, which will dominate compared to the fluctuations induced by misspecification noise. As such, the noise profile describing both the thermal and misspecification noise will approximately satisfy the fluctuation dissipation with the friction term because it is mainly thermal. As this relation is approximately satisfied, equilibrium is reached. Because the noisy part of the potential was absorbed into the noise term, the Boltzmann distribution is the negative exponential of the true, non minibatched potential, i.e., the true posterior distribution. We then use the protocol defined in Section 18.3 in the high resistance limit to sample the true multivariate posterior.

### 19 Hardware for Langevin Monte Carlo

There is a variant of HMC wherein the number of leapfrog steps is set to L=1. This is known as Langevin Monte Carlo, and is defined by

xₖ₊₁=xₖ+τ∇ log p(xₖ)+\sqrt{2τ}ηₖ, (130)

where τ>0 is a fixed time step and ηₖ~ [symbol] (0, 1). This is a discretization of the stochastic differential equation

dx=∇ log p(x)dt+\sqrt{2}dw, (131)

where W is a standard Brownian motion. In the limit as t→∞, x approaches a stationary distribution, which is exactly equal to the distribution defined by p(x). This is a remarkably simple way to sample from a distribution p(\vec{x}): we can use the gradient. In fact, this idea motivated a component of diffusion models known as noise conditional score networks, as these networks allow us to do generative modeling simply by learning the gradient of the data's underlying density function. Indeed, Langevin dynamics is increasingly popular for applications where \vec{x} is in a high dimensional vector space (e.g., the parameters of a deep neural network).

### 19.1 Unit Cell for LMC Hardware

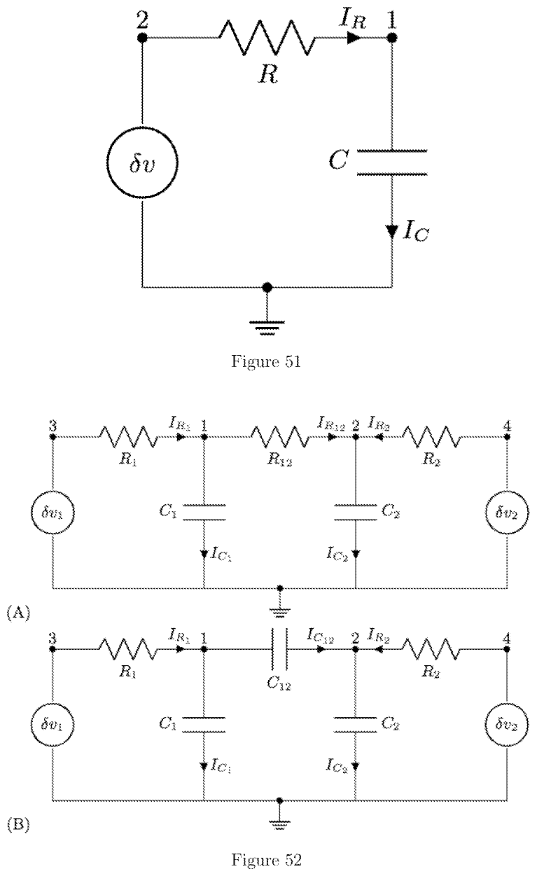

The unit cell (i.e., the building block) for the LMC hardware is shown in FIG. 51.

This is different from the unit cell used for HMC, since it can operate without an inductor. Since inductors are challenging to implement on-chip (e.g., taking up significant area on the chip), avoiding inductors is a useful feature of the LMC hardware.

On the other hand, the unit cell for LMC has a stochastic noise source. This corresponds to a voltage source whose voltage output is Gaussian white noise. There are various ways to implement a stochastic noise source for this purpose, such as the following possible methods:
1. Analog thermal noise (also known as Johnson-Nyquist noise) from a resistor.
2. Analog shot noise from a diode, such as a Zener diode.
3. Digital pseudo-random noise generated from a field-programmable gate array (FPGA) with analog filtering.
   Each of these possible noise sources could act to generate the du voltage source that is shown in FIG. 51. Both analog thermal noise and analog shot noise can be amplified with an amplifier to increase the magnitude of the associated voltage fluctuations.

Each unit cell could also include a constant voltage source (although this voltage source is not explicitly shown in FIG. 51). This can be useful to displace the mean vector u associated with the probability distribution p(x) away from the value μ=0.

### 19.2 Coupling Unit Cells for LMC Hardware

We consider two alternatives for coupling the unit cells. One approach is to use a resistive bridge, as shown in FIG. 52A. Another approach is to use a capacitive bridge, as shown in FIG. 52B.

For resistive coupling, the equations of motion for the voltage vector v for two coupled cells are as follows:

$$- \dot{v} = {C}^{- 1} ( Jv + {R}^{- 1} δ v ) , \qquad ( 132 )$$

$$where$$

$$v ≡ [ \begin{matrix}{υ}_{1} \\ {υ}_{2}\end{matrix} ] , C ≡ [ \begin{matrix}{C}_{1} & 0 \\ 0 & {C}_{2}\end{matrix} ] , J ≡ [ \begin{matrix}\frac{1}{{R}_{1}} + \frac{1}{{R}_{12}} & - \frac{1}{{R}_{12}} \\ - \frac{1}{{R}_{12}} & \frac{1}{{R}_{2}} + \frac{1}{{R}_{12}}\end{matrix} ] , R ≡ [ \begin{matrix}{R}_{1} & 0 \\ 0 & {R}_{2}\end{matrix} ] , δ v ≡ [ \begin{matrix}δ {υ}_{1} \\ δ {υ}_{2}\end{matrix} ] .$$

Here we have introduced the self-resistance matrix R, the capacitance matrix C, and the conductance matrix J.

For capacitive coupling, the equations of motion are as follows:

−\dot{v}=C⁻¹R⁻¹(v+δv), (133)

where the capacitance matrix is

$$C ≡ [ \begin{matrix}{C}_{1} + {C}_{12} & - {C}_{12} \\ - {C}_{12} & {C}_{2} + {C}_{12}\end{matrix} ] .$$

### 19.3 Accepting or Rejecting Samples

Similar to the HMC case, we can add a Metropolis-Hastings (MH) step to the LMC process. This involves the following steps:
Measure the voltages across each of the capacitors in the unit cells of the LMC hardware.
Feed this voltage vector v to the digital processor.
Quantify the energy associated with this voltage vector on the digital processor. Based on this energy value, apply the accept/reject step of the MH process to this sample.

This allows one to either accept or reject the proposed sample, using a digital processor as a judge of the sample quality (via the MH condition).

19.4 Sampling Gaussian Distributions with LMC Hardware

For a Gaussian distribution, the gradient of the logarithm of the probability distribution is given by an affine function. Specifically, it is given by:

∇ log p(x)=−Σ⁻¹(x−μ), (134)

where μ is the mean vector is Σ is the covariance matrix.

Using this formula, we can rewrite Eq. (131) for the special case of a Gaussian as follows:

dx=−Σ⁻¹(x−μ)dt+\sqrt{2}dw, (135)

One can compare this equation to Eqs. (132) and (133), which are the differential equations for the LMC hardware with resistive and capacitive coupling, respectively. Indeed, Eq. (135) has a similar form to these equations. Specifically, we can use these equations to solve for the relationship between the distribution parameters and the circuit parameters. Namely, we can establish a relationship as follows

(Σ,μ)↔(R,J,C) (136)

in the resistive coupling case, and a relationship

(Σ,μ)↔(R,C), (137)

in the capacitive coupling case. These relationships allow the user to translate the distribution parameters into the circuit parameters of the LMC hardware. For the case of resistive coupling, we provide the precise relationship below.

Eqs. (132) and (133) assume that the mean vector is zero, μ=0. However, one can allow for non-zero u by adding in constant voltage sources into each unit cell of the LMC hardware.

19.4.1 Encoding the Covariance Matrix into Resistive Coupling

For the special case of resistive coupling, we now provide the analysis for how to encode the covariance matrix into the coupling.

For additional tuning flexibility, we add an additional resistive branch in parallel with each unit cell, as shown in FIG. 53.

Let us now analyze the circuit in FIG. 53. Consider the voltage vector v={vᵢ, v_{i′}}^{T} where vᵢ is the voltage across the ith capacitor. We arrive at the following differential equation for v.

$$\frac{dv}{dt} = {C}^{- 1} ( - Jv + {R}^{- 1} δ v ) , \qquad ( 132 )$$

$$where$$

$$C ≡ [ \begin{matrix}{C}_{i} & 0 \\ 0 & {C}_{{i}^{′}}\end{matrix} ] , J ≡ [ \begin{matrix}\frac{1}{{R}_{i}} + \frac{1}{{R}_{i}^{′}} + \frac{1}{{R}_{{ii}^{′}}} & - \frac{1}{{R}_{{ii}^{′}}} \\ - \frac{1}{{R}_{{ii}^{′}}} & \frac{1}{{R}_{{i}^{′}}} + \frac{1}{{R}_{{i}^{′}}^{′}} + \frac{1}{{R}_{{ii}^{′}}}\end{matrix} ] , R ≡ [ \begin{matrix}{R}_{i} & 0 \\ 0 & {R}_{{i}^{′}}\end{matrix} ] , δ v ≡ [ \begin{matrix}δ {υ}_{1} \\ δ {υ}_{2}\end{matrix} ] .$$

Let us consider the special case where R=RI and C=CI are proportional to the identity I, and let us define the vector w such that

$$w = \frac{1}{\sqrt{2} RC} δ v .$$

Then we can rewrite the dynamics in Eq. (138) as:

$$dv = - \frac{1}{C} Jvdt + \sqrt{2} dw \qquad ( 139 )$$

where dw=wdt. When we compare this equation with Eq. (135) we see that:

$$\frac{1}{C} J = {\sum }^{- 1} . \qquad ( 140 )$$

Thus we can encode the covariance matrix Σ into the J matrix using the above equation. This provides a recipe for how to store the covariance matrix in the parameters of the electrical circuit.

The above analysis generalizes from two units cells to d unit cells. This essentially involves generalizing the J matrix to the following formula for its matrix elements:

$${J}_{ii} = \frac{1}{{R}_{i}} + \frac{1}{{R}_{i}^{′}} + {\sum }_{{i}^{′} \neq i} \frac{1}{{R}_{{ii}^{′}}} and {J}_{{ii}^{′}} = - \frac{1}{{R}_{{ii}^{′}}} for {i}^{′} \neq i . \qquad ( 141 )$$

19.5 Sampling Non-Gaussian Distributions with LMC Hardware

The techniques developed for HMC for going beyond Gaussian sampling, discussed in Sections 14 and 16, also apply to LMC.

### 19.5.1 Maxwell's Demon Approach

The Maxwell's demon approach that was discussed in Sec. 14 can be applied to the LMC hardware to allow for sampling non-Gaussian distributions.

Specifically, the Maxwell's demon can be viewed as a voltage-controlled voltage source that acts on the unit cell of the LMC hardware. One can use the same circuit structure as that shown for example in FIGS. 36, 38 and 42, provided that one replaces the HMC unit cell with the LMC unit cell. (This essentially involves removing the inductor and adding a stochastic noise source to the unit cell, as discussed above.)

### 19.5.2 Many-Body Coupling Approach

The many-body coupling approach that was discussed in Sec. 16 can also applied to the LMC hardware to allow for sampling non-Gaussian distributions.

Specifically, one can use either a voltage-controlled capacitor (VCC) or a voltage-controlled resistor (VCR) as the coupling device between unit cells. The discussion in Sec. 16 for HMC can be directly applied to the LMC hardware, provided one replaces the HMC unit cell with the LMC unit cell. This includes the discussion for how to engineer three-body, four-body, or n-body couplings using voltage-controlled capacitors. In addition, the discussion of using either analog or digital-analog methods for the many-body coupling in Sec. 16 are relevant to the LMC hardware as well.

### 19.6 Alternative LMC Hardware Based on Integrators

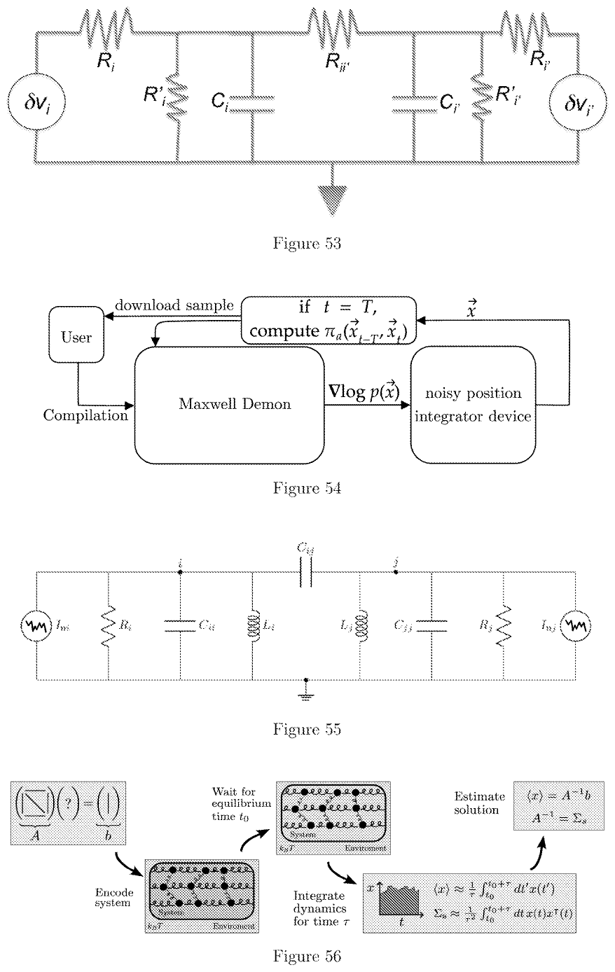

Here, an alternative device for the LMC hardware can be used as follows. Specifically, this alternative device employs integrators instead of unit cells, as shown in FIG. 54.

The analog device for LMC in FIG. 54 can be used to sample arbitrary probability distributions, including those parametrized by a neural network as described in Section 14.7. To do so, the user should compile their representation of the probability to hardware. For a neural network, this amounts to compiling the network to analog hardware, and then computing its gradient. Alternatively, if one has a formula to estimate the gradient, one may compile this to analog and the Maxwell demon, if fed with the input \vec{x}, will output the gradient of the log-probability.

### 20 Boosting the Effective Temperature with Noise Injection

One question regarding the feasibility of the Gaussian sampling device is whether the damping (caused by realistic electrical components) will be so large relative to thermal noise that the measured voltage will be very small. While the measured values could always be amplified, there is a concern that adding an analog amplifier would increase the complexity of the device, and large amplification achieved by digital post-processing could cause a loss of precision. A physically motivated method of overcoming this issue would simply be to increase the operating temperature of the device until the thermal fluctuations are large enough that amplification is unnecessary; this approach brings its own problems though, for example, the time to reach the desired temperature as well as the additional energy cost.

Raising the effective temperature of the device through noise injection can be done by generating white noise with a digital pseudo-random number generator (coming from an FPGA for example) and adding noise to each cell independently. A key question is whether this approach has the same effect as raising the physical temperature, particularly if we inject noise which is uncorrelated at each cell.

FIG. 55 shows a circuit diagram with noise injection, for two unit cells. Assuming uncorrelated noise injection, our circuit equations take the form

dI=L⁻¹Vdt (142)

dV=−C⁻¹R⁻¹Vdt− [symbol] ⁻¹Idt+\sqrt{2κ₀} [symbol] ⁻¹dW, (143)

where dW~ [symbol] (0, [symbol] dt) and [symbol] is the Maxwell matrix. The injected noise amplitude is controlled by the parameter ko, which seemingly should have dimensions of charge²·time⁻¹ to make the units work, but we leave the dimensions ambiguous for now.

The effective temperature can indeed be increased using uncorrelated noise at each cell. This means that we can use the circuits discussed in previous sections of this document to get samples without additional amplifiers or temperature control. If we assume uncorrelated white noise injection at each cell with the same amplitude, the resulting covariance matrices for voltage and current are

Σ_{V}=κ₀R [symbol] ⁻¹,Σ_{I}=κ₀RL⁻¹, (144)

where [symbol] is the Maxwell capacitance matrix, L the inductance matrix, R the resistance matrix (which is proportional to an identity matrix), and κ₀ is a number which scales with the injected noise amplitude, and also determines the effective temperature.

In this formalism, the Maxwell capacitance matrix encodes the inverse of the covariance matrix rather than the covariance matrix itself, so it is most amenable to applications where the precision matrix is specified as opposed to the covariance matrix. However it is still possible to use this method for cases where we are given the covariance matrix, which could be inverted numerically for example. In trying to make the capacitance matrix directly scale with the covariance matrix there are some subtleties, but here we address the case where the capacitance matrix scales with the precision matrix.

### 21 Thermodynamic System for Solving Linear Algebraic Primitives

Here we show that the same thermodynamic hardware described above can also be used to accelerate key primitives in linear algebra. We exploit the fact that the mathematics of harmonic oscillator systems is affine (i.e., linear), and hence we can map linear algebraic primitives onto such systems. We show that by sampling from the thermal equilibrium distribution of coupled harmonic oscillators, one can solve a variety of linear algebra problems. Specifically we develop thermodynamic algorithms for the following linear algebraic primitives: (i) solving a linear system Ax=b, (ii) estimating a matrix inverse A⁻¹, (iii) solving Lyapunov equations of the form AΣ+ΣA^{T}=I and (iv) estimating the determinant of a symmetric positive definite matrix A. We show that if implemented on thermodynamic hardware, these methods scale favorably with problem size compared to digital algorithms.

### 21.1 Solving Linear Systems of Equations

The celebrated linear systems problem is to find x∈ [symbol] ^{d} such that

Ax=b, (145)

given some invertible matrix A∈ [symbol] ^{d×d} and nonzero b∈ [symbol] ^{d}. We may assume without loss of generality that the matrix A in Eq. (145) is symmetric and positive definite (SPD). To see this, suppose that A is not SPD. Then we may define A′=A^{T}A and b′=A^{T}b, and solve the equation

A′x′=b′. (146)

The transpose of an invertible matrix is invertible, which implies A′ is invertible and b′ is nonzero, so Eq. (146) is a nonsingular linear system. The matrix A′ is SPD by construction, so if a method is available to solve symmetric linear systems then x′ satisfying Eq. (146) can be found. Then, left-multiplying both sides of Eq. (146) by (A^{T})⁻¹ gives Ax′=b, meaning x′ is a solution to the original linear system. This may affect the total runtime, but still allows for asymptotic scaling improvements with respect to digital methods (constructing an SPD system from a generic one in this way results in the squaring of the condition number, which influences performance). In what follows, we therefore assume that A is SPD.

Now let us connect this problem to thermodynamics. We consider a macroscopic device with d degrees of freedom, described by classical physics. Suppose the device has potential energy function:

$$V ( x ) = \frac{1}{2} {x}^{T} A x - {b}^{T} x , \qquad ( 147 )$$

where A∈SPD_{d}( [symbol] ). This is a quadratic potential that can be physically realized with a system of harmonic oscillators, where the coupling between the oscillators is determined by the matrix A, and the b vector describes a constant force on each individual oscillator.

Suppose that we allow this device to come to thermal equilibrium with its environment, whose inverse temperature is β=1/k_{B}T. At thermal equilibrium, the Boltzmann distribution describes the probability for the oscillators to have a given spatial coordinate: p(x)∝exp(−βV(x). Because V(x) is a quadratic form, then p(x) corresponds to a multivariate Gaussian distribution. Thus at thermal equilibrium, the spatial coordinate x is a Gaussian random variable

x~ [symbol] [A⁻¹b,βA⁻¹]. (148)

The unique minimum of V(x) occurs where Ax−b=0, which also corresponds to the unique maximum of p(x). For a Gaussian distribution, the maximum of p(x) is also the first moment [symbol] x [symbol] . Thus, we have that, at thermal equilibrium, the first moment is the solution to the linear system of equations:

[symbol]

x [symbol] =A⁻¹b. (149)

From this analysis, we can construct a thermodynamic protocol for solving linear systems, which is depicted in FIG. 56. Namely, the protocol involves realizing the potential in Eq. (147), waiting for the system to come to equilibrium, and then sampling x to estimate the mean [symbol] x [symbol] of the distribution. This mean can be approximated using a time-average, defined as

$$〈 x 〉 \approx \overline{x} ( τ ) = \frac{1}{τ} {\int }_{{t}_{0}}^{{t}_{0} + τ} {dt}^{′} x ( {t}^{′} ) , \qquad ( 150 )$$

where t₀ should be large enough to allow for equilibration and τ should be large enough for the average to converge to a desired degree of precision. The eventual convergence of this time average to the mean is the content of the ergodic hypothesis, which is often assumed for quite generic thermodynamic systems. The mean could also be approximated as the average of a sequence of samples; however, the integration approach can be implemented conveniently in a completely analog way (for example, using an integrator circuit), which obviates the need for transferring data from the device until the end of the protocol.

The overall protocol can be summarized as follows.
1. Given a linear system Ax=b, set the potential of the device to

$$V ( x ) = \frac{1}{2} {x}^{T} A x - {b}^{T} x \qquad ( 151 )$$

at time t=0.
2. Choose equilibration tolerance parameters δ_{μ0}, δ_{Σ0}∈ [symbol] ⁺, and choose the equilibration time

t₀≥\hat{t}₀, (152)
where \hat{t}₀ is computed from the system's physical properties, Eq. (155) or (152). Allow the system to evolve under its dynamics until t=t₀, ensuring that ∥ [symbol] x [symbol] −A⁻¹b∥≤δ_{μ} and ∥Σ−βA⁻¹b∥≤δ_{Σ}.
3. Choose error tolerance parameter δ_{z} and success probability P_{δ}, and choose the integration time

τ≥\vec{τ}, (153)
where \hat{τ} is computed from the system's physical properties, Eq. (155) or (152). Use an analog integrator to measure the time average

$$\overline{x} = \frac{1}{τ} {\int }_{{t}_{0}}^{{t}_{0} + τ} dt x ( t ) , \qquad ( 154 )$$

which satisfies ∥x̅−A⁻¹b∥≤δ_{z} with probability at least P_{δ}.

In order to implement the protocol above, the desired values of \hat{t}₀ and \hat{τ} should be identified, which involves a more quantitative description of equilibration and ergodicity. To obtain such a description, a model of the system's microscopic dynamics may be introduced. Given that the system under consideration is composed of harmonic oscillators in contact with a heat bath, then it is natural to allow for damping (i.e., energy exchange with the bath) and stochastic thermal noise, which always accompanies damping due to the fluctuation-dissipation theorem. The Langevin equation accounts for these effects, and specifically we consider two common formulations, the overdamped Langevin (ODL) equation and the underdamped Langevin (UDL) equations.

For the overdamped case, we arrive at the following formulas, which can be used in the above protocol:

$$\hat{{t}_{0}} = max \{ \frac{γ κ}{‖ A ‖} ln ( \frac{‖ 〈 x ( 0 ) 〉 - {A}^{- 1} b ‖}{{δ}_{μ}} ) , \frac{γ κ}{2 ‖ A ‖} ln ( \frac{‖ {\sum }_{0} - {β}^{- 1} {A}^{- 1} ‖ + κ / β ‖ A ‖}{{δ}_{\sum }} ) \} , \qquad ( 155 )$$

$$\hat{τ} = \frac{2 γ {κ}^{2} d}{β {‖ A ‖}^{2} ( 1 - {P}_{δ} ) {δ}_{x}^{2}} ,$$

For the underdamped case, we find somewhat different formulas for the parameters:

$$\hat{{t}_{0}} = max \{ \frac{1}{ξ} ln ( \frac{\sqrt{2 β κ} {E}_{0} X}{\sqrt{‖ A ‖} {δ}_{μ}} ) , \frac{1}{2 ξ} ln ( \frac{M \sqrt{κ} {X}^{2} ( {‖ {\sum }_{0} - {\sum }_{s} ‖}_{E} + 2 )}{{γ}^{2} β {δ}_{\sum }} ) \} , \qquad ( 156 )$$

$$\hat{τ} = \frac{4 {M}^{2} ( \sqrt{κ} Xd {‖ {\sum }_{s} ‖}_{E}}{{γ}^{3} β ( 1 - {P}_{δ} ) {δ}_{x}^{2}} .$$

### 21.1.1 Hardware Implementation

Here we describe an electronic device comprised of d coupled RC cells that maps to the overdamped Langevin process and can be used to implement the thermodynamic linear systems algorithm described above.

One potential approach for this hardware implementation is to use the building blocks shown in FIG. 17, which employs RC unit cells and resistive coupling between the cells. The equation of motion for voltages v=(v₁, v₂, . . . , v_{d}) across the capacitor of each cell is:

dv=C⁻¹(−Jvdt+R⁻¹dw) (157)

where C=diag(C₁, C₂, . . . , C_{d}), R=diag(R₁, R₂, . . . , R_{d}), w is uncorrelated Brownian motion and the elements of J are given by

$$\{ \begin{matrix}{J}_{ij} = - \frac{1}{{R}_{ij}} & if i \neq j \\ {J}_{ij} = \frac{1}{{R}_{i}} + \frac{1}{{R}_{i}^{′}} + \frac{1}{{R}_{ij}} & if i = j\end{matrix} . \qquad ( 158 )$$

Hence there are two in-cell resistors, allowing for freedom on the diagonal elements of the J matrix independently of the R matrix, and one resistor coupling each cell. One can set [symbol] =JR, and γ=1/RC as R, C are diagonal matrices. By denoting x=v and choosing [symbol] =A, this leads to:

$$dx = \frac{1}{γ} ( - Axdt + dw ) \qquad ( 159 )$$

which reduces to overdamped dynamics of the linear systems solver provided the mean of the noise is γb, and its variance is 2γ/β. Note that to implement this in hardware the values of the in-cell and out-of-cell resistors must be computed based on the A matrix, therefore this incurs a cost of O(d²) operations at the initialization. For electrical hardware, the effective temperature is related to Johnson-Nyquist noise as

$$\overline{{v}_{n}^{2}} = \sqrt{4 {k}_{B} TR Δ f} ,$$

with Δƒ the bandwidth of the system. For a bandwidth of 1 MHz, we obtain

$$\overline{{v}_{n}^{2}} = 0.1 μ V$$

### for T=300K.

### 21.2 Estimating the Inverse of a Matrix

The results of the previous section rely on estimating the mean of x and make no use of the fluctuations in x at equilibrium. By using the second moments of the equilibrium distribution, we can go beyond solving linear systems. For example, it is possible to find the inverse of a symmetric positive definite matrix A. As mentioned, the stationary distribution of x is [symbol] [A⁻¹b, β⁻¹A⁻¹], meaning the inverse of A can be obtained by evaluating the covariance matrix of x. This can be accomplished in an entirely analog way, using a combination of analog multipliers, and integrators. By setting b=0 for this protocol, we ensure that [symbol] x [symbol] =0, so the stationary covariance matrix is, by definition

$${\sum }_{s} = {lim}_{t \to ∞} 〈 x ( t ) {x}^{T} ( t ) 〉 . \qquad ( 160 )$$

In order to estimate this, we again perform time averages after allowing the system to come to equilibrium

$${\sum }_{s} \approx \overline{{xx}^{T}} = \frac{1}{{τ}^{2}} {\int }_{{t}_{0}}^{{t}_{0} + τ} dt x ( t ) {x}^{T} ( t ) . \qquad ( 161 )$$

Analog component can evaluates the product xᵢ(t)xⱼ(t) for each pair (i, j), resulting in d² analog multiplier components. Each of these products is then fed into an analog integrator component, which computes one element of the time-averaged covariance matrix

$${\sum }_{s , ij} \approx \frac{1}{{τ}^{2}} {\int }_{{t}_{0}}^{{t}_{0} + τ} dt {x}_{i} ( t ) {x}_{j} ( t ) . \qquad ( 162 )$$

While the equilibration time is the same as for the linear system protocol, the integration time is different, because in general the covariance matrix is slower to converge than the mean. We now give a detailed description of the inverse estimation protocol, assuming ODL dynamics.
1. Given a positive definite matrix A, set the potential of the device to

$$V ( x ) = \frac{1}{2} {x}^{T} Ax \qquad ( 163 )$$

at time t=0.
2. Choose equilibration tolerance parameters δ_{μ0}, δ_{Σ0}, and evaluate the equilibration time

$${t}_{0} = max \{ \frac{γ κ}{‖ A ‖} ln ( \frac{‖ 〈 x ( 0 ) 〉 - {A}^{- 1} b ‖}{{δ}_{μ0}} ) , \frac{γ κ}{2 ‖ A ‖} ln ( \frac{‖ {\sum }_{0} - {β}^{- 1} {A}^{- 1} ‖ + κ / β ‖ A ‖}{{δ}_{\sum 0}} ) \} , \qquad ( 164 )$$

Allow the system to evolve under its dynamics until t=t₀, ensuring that | [symbol] x [symbol] −A⁻¹b∥≤δ_{μ0} and ∥Σ−βA⁻¹∥≤δ_{Σ0}.
3. Choose error tolerance parameter δ_{Σ} and success probability P_{δ}, and evaluate the integration time

$$τ = \frac{d {γκ}^{3}}{{‖ A ‖}^{3} {δ}_{A}^{2} ( 1 - {P}_{δ} )} \qquad ( 165 )$$

Use analog multipliers and integrators to measure the time averages

$$\overline{{x}_{i} {x}_{j}} = \frac{1}{{τ}^{2}} {\int }_{{t}_{0}}^{τ} dt {x}_{i} ( t ) {x}_{j} ( t ) , \qquad ( 166 )$$

which satisfies

$$\vert β \overline{{x}_{i} {x}_{j}} - {A}_{i j}^{- 1} \vert \leq {δ}_{A}$$

with probability at least P_{δ}.

### 21.3 Solving the Lyapunov Equation

This section concerns a device with a controllable noise source such that the covariance matrix of the noise term may be chosen to be an arbitrary symmetric positive definite matrix. We do not include the linear b^{T}x term in the potential, and therefore obtain the following overdamped Langevin equation

$$d x = - \frac{1}{γ} A x dt + 𝒩 [ 0 , \frac{1}{γ} R dt ] , \qquad ( 167 )$$

where R is symmetric and positive definite. In this case, the stationary distribution has mean zero and covariance matrix Σₛ, which is a solution to the Lyapunov equation

AΣ+ΣA^{T}=R. (168)
1. Given two symmetric positive definite matrices A and R, set the potential of the device to

$$V ( x ) = \frac{1}{2} {x}^{T} A x , \qquad ( 169 )$$

and the noise term in the overdamped Langevin equation to

$$𝒩 [ 0 , \frac{1}{γ} R d t ]$$

at time t=0. That is, the system evolves under the dynamics of Eq. (167).
2. Choose equilibration tolerance parameters δ_{μ0}, δ_{Σ0}, and evaluate the equilibration time

$${t}_{0} \geq max \{ \frac{γ κ}{‖ A ‖} ln ( \frac{‖ 〈 x ( 0 ) 〉 ‖}{{δ}_{μ}} ) , \frac{γ κ}{2 ‖ A ‖} ln ( \frac{‖ {\sum }_{0} - {\sum }_{s} ‖ + γκ ‖ {BB}^{T} ‖ / ‖ A ‖}{{δ}_{\sum }} ) \} . \qquad ( 170 )$$

Allow the system to evolve under the dynamics of Eq. (167) until t=t₀, ensuring that ∥ [symbol] x [symbol] ∥≤δ_{μ0} and ∥Σ−Σₛ∥≤δ_{Σ0}.
3. Choose error tolerance parameter δ_{Σ} and success probability P_{δ}, and evaluate the integration time

$$τ = \frac{d γ {κ}^{3}}{‖ A {‖}^{3} {δ}_{A}^{2} ( 1 - {P}_{δ} )} \qquad ( 171 )$$

Use analog multipliers and integrators to measure the time averages

$$\overline{{x}_{i} {x}_{j}} = \frac{1}{{τ}^{2}} {\int }_{{t}_{0}}^{τ} dt {x}_{i} ( t ) {x}_{j} ( t ) , \qquad ( 172 )$$

which satisfies |x̅ᵢ̅x̅ⱼ̅−Σ_{s,ij}|≤δ_{Σ} with probability at least P_{δ}.

### 21.4 Estimating the Determinant of a Matrix

The determinant of the covariance matrix appears in the normalization factor of a multivariate normal distribution, whose density function is

$${f}_{μ ; \sum } ( x ) = {( 2 π )}^{- d / 2} {\vert \sum \vert}^{- 1 / 2} exp ( - \frac{1}{2} {x}^{T} {\sum }^{- 1} x ) . \qquad ( 173 )$$

Hardware that can prepare a Gaussian distribution can estimate the determinant of a matrix because this problem is equivalent to the estimation of free energy differences, an application of stochastic thermodynamics. Recall that the difference in free energy between equilibrium states of potentials V₁ and V₂ is

$$Δ F = {F}_{2} - {F}_{1} = - {β}^{- 1} ln ( \frac{\int dx {e}^{- β {V}_{2} ( x )}}{\int dx {e}^{- β {V}_{1} ( x )}} ) . \qquad ( 174 )$$

Suppose the potentials are quadratic, with V₁(x)=x^{T}A₁x and V₂(x)=x^{T}A₂x. Then each integral simplifies to the inverse of a Gaussian normalization factor,

$$\int dx {e}^{- β {V}_{j} ( x )} = {( 2 π )}^{d / 2} \sqrt{{β}^{- 1} \vert {A}_{j}^{- 1} \vert} , \qquad ( 175 )$$

so

$$Δ F = - {β}^{- 1} ln ( \sqrt{\frac{\vert {A}_{2}^{- 1} \vert}{\vert {A}_{1}^{- 1} \vert}} ) = - {β}^{- 1} ln ( \sqrt{\frac{\vert {A}_{1} \vert}{\vert {A}_{2} \vert}} ) . \qquad ( 176 )$$

This suggests that the determinant of a matrix A₁ can found by comparing the free energies of the equilibrium states with potentials V₁ and V₂ (where A₂ has known determinant), and then computing

|A₁|=e^{-2βΔF}|A₂|. (177)

Fortunately, the free energy difference ΔF can be found, assuming we have the ability to measure the work which is done on the system as the potential V(x) is changed from V₁ to V₂. According to the Jarzynski equality, the free energy difference between the (equilibrium) states in the initial and final potential is

e^{-βΔF}= [symbol] e^{-βW} [symbol] , (178)

where [symbol] · [symbol] denotes an average over all possible trajectories of the system between time t=0 and time t=τ, weighed by their respective probabilities. This may be approximated by

TABLE 1
Comparison of asymptotic complexities of linear algebra algorithms.

| | Digital | Overdamped | Underdamped |
|---|---|---|---|
| Problem | SOTA | TA | TA |
| Linear System | O(min{d^{ω}, | O(dκ²ε⁻²) | O(d\sqrt{κε}⁻²) |
| | d² \sqrt{κ}}) | | |
| Matrix Inverse | O (d^{ω}) | O(d² κε⁻²) | O(d² κε⁻²) |
| Lyapunov | O(d³) | O(d² κε⁻²) | O(d² κε⁻²) |
| Equation | | | |
| Matrix | O(d³) | O(dκln(κ)3ε⁻²) | O(dln(κ)³ε⁻²) |
| Determinant | | | |

Here, d is the matrix dimension, κ is the condition number, and ε is the error. For our thermodynamic algorithms (TAs), the complexity depends on the dynamical regime, i.e., whether the dynamics are overdamped and underdamped. For the digital SOTA case, the complexity of solving symmetric, positive definite linear systems, matrix inverse, Lyapunov equation, and matrix determinant problems are respectively for algorithms based on: conjugate gradient method, fast matrix multiplication/inverse, Bartels-Stewart algorithm, and Cholesky decomposition. ω ≈ 2.3 denotes the matrix multiplication constant.

an average over N repeated trials,

$${e}^{- βΔ F} \approx \overline{{e}^{- β W}} ≡ \frac{1}{N} {\sum }_{j = 1}^{N} {e}^{- β {W}_{j}} . \qquad ( 179 )$$

In summary, the determinant of A₁ is approximated by

|A₁|≈(e̅^̅{̅-̅β̅W̅}̅)²|A₂|. (180)

In practice we may be interested in the log determinant to avoid computational overflow. This is

ln(|A₁|)≈2 ln(e̅^̅{̅-̅β̅W̅}̅)+ln(|A₂|). (181)

In order to estimate the log determinant to within error δ_{det} with probability at least P_{δ}, the wait time is

$$τ = \frac{d γκ {ln ( κ )}^{2}}{2 ln ( 2 ) {β}^{2} ‖ {A}_{1} ‖ {δ}_{J}^{2} ( 1 - {P}_{δ} )} ln ( \frac{( κ + 1 ) / β ‖ {A}_{1} ‖}{{δ}_{Σ}} ) . \qquad ( 182 )$$

### 21.5 Runtime Analysis

Table 1 summarizes the different results we obtained as compared to the best state-of-the-art digital methods for dense symmetric positive-definite matrices. These results are based on bounds obtained for correlation times, burn-in time, as well as physical wait time when approaches with integrators and multipliers are employed that ensure convergence of our methods.

### 22 Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components may optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one embodiment, to A only (optionally including components other than B); in another embodiment, to B only (optionally including components other than A); in yet another embodiment, to both A and B (optionally including other components); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components may optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including components other than B); in another embodiment, to at least one, optionally including more than one, B, with no A present (and optionally including components other than A); in yet another embodiment, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, § 2111.03.

1. A system for sampling a multivariate distribution, the system comprising:
a network of analog electrical circuits to sample the multivariate distribution, each analog electrical circuit in the network of analog electrical circuits comprising at least one tunable passive electrical component; and
a digital controller, operably coupled to the network of analog electrical circuits, to tune the tunable passive electrical components according to parameters of the multivariate distribution and to sample voltages at points within the network of analog electrical circuits.

2. The system of claim 1, wherein the at least one tunable passive electrical component comprises at least one of a tunable capacitor or a tunable resistor.

3. The system of claim 1, wherein the at least one tunable passive electrical component comprises a tunable inductor.

4. The system of claim 1, further comprising:
a voltage-controlled voltage source, operably coupled to the network of analog electrical circuits, to modify the multivariate distribution.

5. The system of claim 4, wherein the voltage-controlled voltage source employs an artificial neural network to relate an input voltage to the voltage-controlled voltage source to an output voltage of the voltage-controlled voltage source.

6. The system of claim 5, wherein the input voltage is based on the voltages sampled by the digital controller and the voltage-controlled voltage source is configured to apply the output voltage to the network of analog electrical circuits so as to change a distribution of potential energy across the network of analog electrical circuits.

7. The system of claim 1, wherein the multivariate distribution has a nonzero cumulant of at least third order, and further comprising:
a multi-port device, operably coupled to at least three of the analog electrical circuits in the network of analog electrical circuits, to generate a k-body term in a potential energy distribution over the network of analog electrical circuits, where k is an integer greater than or equal to 3.

8. The system of claim 7, wherein the multi-port device comprises at least one of a transistor or a voltage-controlled capacitor.

9. The system of claim 1, wherein each analog electrical circuit further comprises a stochastic noise source.

10. The system of claim 9, where the stochastic noise source is one of a thermal noise source, a shot noise source, or a digital pseudo-random noise source.

11. The system of claim 1, wherein the analog electrical circuits in the network of analog electrical circuits are coupled to each other via capacitive and/or resistive coupling.

12. The system of claim 1, where the system is configured to generate samples from the multivariate distribution via a Langevin Monte Carlo Algorithm and/or a Metropolis Adjusted Langevin Algorithm.

13. The system of claim 1, where the multivariate distribution is a Gaussian distribution whose covariance matrix is encoded in at least some of the parameters of the network of analog electrical circuits.

14. A system for sampling a multivariate distribution, the system comprising:
a network of coupled analog unit cells characterized by a total energy function that maps to the multivariate distribution, each coupled analog unit cell in the network of coupled analog unit cells comprising a digitally tunable capacitor and a digitally tunable voltage source and/or a digitally tunable current source; and
a digital controller, operably coupled to the network of coupled analog unit cells, to:
initialize the digitally tunable capacitors and the digitally tunable voltage sources and/or the digitally tunable current sources;
iteratively read voltages and currents at nodes in the network of coupled analog unit cells and update the digitally tunable voltage sources and/or the digitally tunable current sources, the voltages and the currents corresponding to positions and momenta of the total energy function; and
translate the voltages and the currents into samples of the multivariate distribution.

15. The system of claim 14, wherein the total energy function is a Hamiltonian and the network of coupled analog unit cells have dynamics used to run a Hamiltonian Monte Carlo protocol.

16. The system of claim 14, wherein the network of coupled analog unit cells have dynamics used to run a Langevin Monte Carlo protocol.

17. The system of claim 14, wherein the network of coupled analog unit cells comprises one analog unit cell for each dimension of the multivariate distribution.

18. The system of claim 14, wherein each analog unit cell in the network of coupled analog unit cells comprises a digitally tunable inductor.

19. The system of claim 14, wherein analog unit cells in the network of coupled analog unit cells are capacitively coupled to each other.

20. The system of claim 14, wherein analog unit cells in the network of coupled analog unit cells are resistively coupled to each other.

21. The system of claim 14, wherein analog unit cells in the network of analog unit cells are inductively coupled to each other.

22. The system of claim 14, wherein the multivariate distribution is a multivariate Gaussian distribution.

23. The system of claim 14, wherein the multivariate distribution has a non-zero cumulant higher than second order.

24. (canceled)

25. (canceled)

26. (canceled)

27. (canceled)

28. (canceled)

29. (canceled)

30. (canceled)

31. (canceled)

32. (canceled)
